(19) United States
(12) Patent Application Publication
(10) Pub. No.: US 2025/0056782 A1
(43) Pub. Date: Feb. 13, 2025

(54) SEMICONDUCTOR STRUCTURE AND MANUFACTURING METHOD THEREOF

(71) Applicants: TAIWAN SEMICONDUCTOR MANUFACTURING COMPANY, LTD., Hsinchu (TW); National Yang Ming Chiao Tung University, Hsinchu City (TW)

(72) Inventors: Tao CHOU, New Taipei City (TW); Hsin-Cheng LIN, Taipei City (TW); Ching-Wang YAO, New Taipei City (TW); Li-Kai WANG, New Taipei City (TW); Chee-Wee LIU, Taipei City (TW); Chenming HU, Oakland, CA (US)

(73) Assignees: TAIWAN SEMICONDUCTOR MANUFACTURING COMPANY, LTD., Hsinchu (TW); National Yang Ming Chiao Tung University, Hsinchu City (TW)

(21) Appl. No.: 18/447,544

(22) Filed: Aug. 10, 2023

(51) Int. Cl. H10B 10/00; H01L 21/8238; H01L 27/092; H01L 29/06; H01L 29/423; H01L 29/66; H01L 29/775; H01L 29/786

(52) U.S. Cl. CPC H10B 10/12; H01L 21/823828; H01L 21/823871; H01L 27/092; H01L 29/0673; H01L 29/42392; H01L 29/66439; H01L 29/66545; H01L 29/775; H01L 29/78696

(57) ABSTRACT

A method includes forming a first pull-up transistor and a first pass-gate transistor over a substrate at a first level height, the first pull-up and first pass-gate transistors being of a dual port static random access memory (SRAM) cell; forming a first pull-down transistor and a second pass-gate transistor of the dual port SRAM cell over the substrate at a second level height; forming a second pull-down transistor and a third pass-gate transistor of the dual port SRAM cell over the substrate at a third level height; forming a second pull-up transistor and a fourth pass-gate transistor of the dual port SRAM cell over the substrate at a fourth level height.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a circuit diagram in accordance with some embodiments of the present disclosure.

FIG. 2 illustrates a perspective view a semiconductor structure in accordance with some embodiments of the present disclosure.

FIGS. 3A-3C illustrate cross-sectional views of intermediate stages in the formation of the semiconductor structure obtained from reference cross-section 3C-3C′ in FIG. 2.

FIGS. 4A-4J illustrate cross-sectional views of obtained from reference cross-sections A-A′, B-B′, C-C′, D-D′, E-E′, F-F′, G-G′, H-H′, I-I′, and J-J′ in FIG. 3C.

FIG. 5 illustrates a local enlarged view of region Cl in FIG. 2.

FIGS. 6A-63 illustrate cross-sectional views of intermediate stages in the formation of a semiconductor structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

Throughout the evolution of integrated circuits (ICs), there has been a general trend of increasing functional density, which refers to the number of interconnected devices per chip area, while reducing the geometry size, representing the smallest component or line that can be created using the fabrication process. In order to enhance the functional density of IC structures, a proposed approach involves the use of complementary field-effect transistors (CFETs), where a p-type FET and an n-type FET are vertically stacked. However, the conventional dual port SRAM bitcell, which originally consisted of 8 transistors and utilized a monolithic process, encountered routing issues. Specifically, when the dual port SRAM bitcell is configured in the CFET arrangement, the presence of metal routing above the transistors results in significant routing congestion within the bitcell. This congestion poses challenges and negatively impacts the efficiency and performance of the bitcell.

Therefore, the present disclosure in various embodiments provides a 4-layer structure for the dual port SRAM bitcell, which incorporates a total of 8 transistors. This approach enables us to achieve the same functionality with a significantly reduced footprint, requiring only 2 transistors. By employing a sequential process or a monolithic process, we stack the transistors in a specific configuration, such as placing pull-down transistor on top of pull-up transistor. To address the routing challenges, we introduce an inter-metal dielectric layer (e.g. middle end of line, MEOL), above the bottom-tier transistors in the dual port SRAM bitcell. This MEOL layer provides a platform for the placement of power lines and cross coupling lines between the bottom-tier transistors and the top tier transistors. Moreover, buried metal lines, including the complementary bit lines, are formed beneath the bottom-tier transistors to mitigate routing congestion. Hence, by reducing the footprint of the dual port SRAM bitcell from 12 transistors to only 2 transistors, we greatly enhance space efficiency and enable more compact designs. This reduction in footprint allows for higher device density, potentially leading to lower production costs. In addition, the introduction of the inter-metal dielectric layer and buried metal lines effectively addresses routing congestion, thereby improving the overall performance and efficiency of the SRAM bitcell.

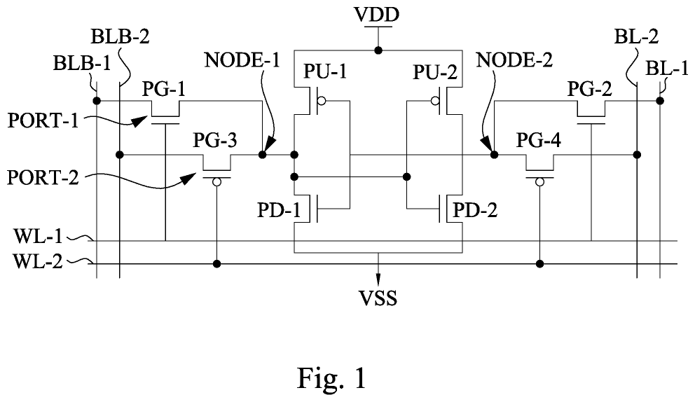

Reference is made to FIG. 1. FIG. 1 illustrates a circuit diagram of a dual port eight transistor (8T)-SRAM cell in accordance with some embodiments of the present disclosure. The dual port 8T SRAM cell can include pass-gate transistors PG-1, PG-2, PG-3, and PG-4, pull-up transistors PU-1 and PU-2, and pull-down transistors PD-1 and PD-2. Drains of the pull-up transistors PU-1 and PU-2 can be electrically coupled to a voltage source line VDD. The sources of the pull-down transistors PD-1 and PD-2 can be electrically coupled to a ground line VSS. The dual port 8T SRAM cell can form two complementary nodes NODE-1 and NODE-2 in FIG. 1. Because the complementary node NODE-1 is tied to the gate of the pull-up transistor PU-1 and the complementary node NODE-2 is tied to the gate of the pull-up transistor PU-2, the values stored in each node will remain complementary to each other. For example, when the complementary node NODE-1 is high, the pull-up transistor PU-2 can prevent the current from the voltage source line VDD from flowing to the complementary node NODE-2. In parallel, the gate of the pull-down transistor PD-2 is activated, allowing any charge that may be in the complementary node NODE-2 to go to ground. Furthermore, when the complementary node NODE-2 is low, the pull-up transistor PU-1 can allow current to flow from the voltage source line VDD to the complementary node NODE-1, and the gate of the pull-down transistor PD-1 is de-activated, preventing the charge in the complementary node NODE-1 from going to ground. In some embodiments, the pull-up transistors PU-1 and PU-2 can be PMOS transistors, and the pull-down transistors PD-1 and PD-2 can be NMOS transistors. In some embodiments, the pull-up transistors PU-1 and PU-2 can be NMOS transistors, and the pull-down transistors PD-1 and PD-2 can be PMOS transistors.

The dual port 8T SRAM cell can include two ports PORT-1 and PORT-2. The port PORT-1 can include the pass-gate transistor PG-1, the pass-gate transistor PG-2, the bit line BL-1, the complementary bit line BLB-1, and the word line WL-1. The port PORT-2 includes the pass-gate transistor PG-3, the pass-gate transistor PG-4, the bit line BL-2, the complementary bit line BLB-2, and the word line WL-2. In some embodiments, the pass-gate transistors PG-1 and PG-2 can be NMOS transistors, and the pass-gate transistors PG-1 and PG-2 can be PMOS transistors. In some embodiments, the pass-gate transistors PG-1 and PG-2 can be PMOS transistors, and the pass-gate transistors PG-1 and PG-2 can be NMOS transistors. The two bit lines (i.e., bit line BL-1 and bit line BL-2), and the two complementary bit lines (i.e., complementary bit line BLB-1 and complementary bit line BLB-2) provide data lines to read data from and write data to the 8T-SRAM cell. The two word lines (i.e., word line WL-1 and word line WL-2) control the pass-gate transistors PG-1, PG-2, PG-3, and PG-4 to control the reading and writing. In the port PORT-1, the bit line BL-1 can be electrically connected to the source of the pass-gate device PG-1 and the complementary bit line BLB-1 can be electrically connected to the source of the pass-gate device PG-2. In the port PORT-2, the bit line BL-2 can be electrically connected to the source of the pass-gate device PG-3 and the source of the complementary bit line BLB-2 can be electrically connected to the source of the pass-gate device PG-4. The bit lines BL-1 and BL-2 and the complementary bit lines BLB-1 and BLB-2 are for data input and output, and are herein collectively referred to as the 8T dual port bit lines.

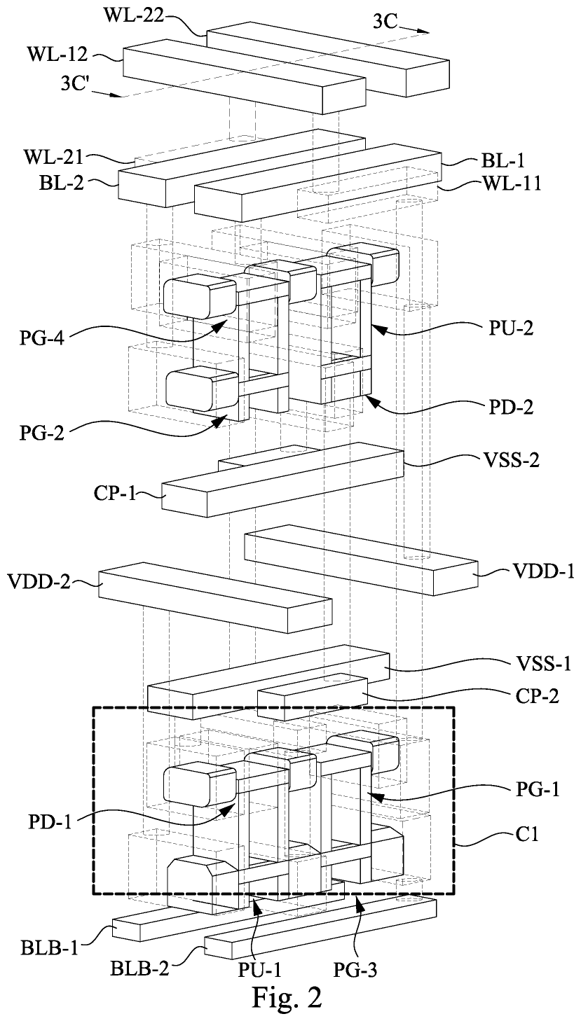

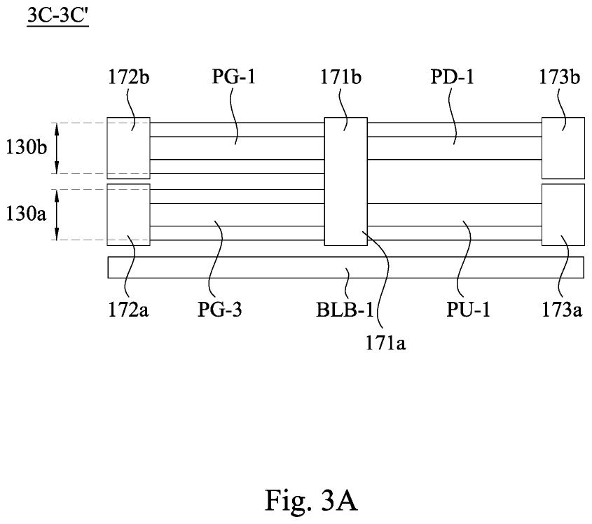

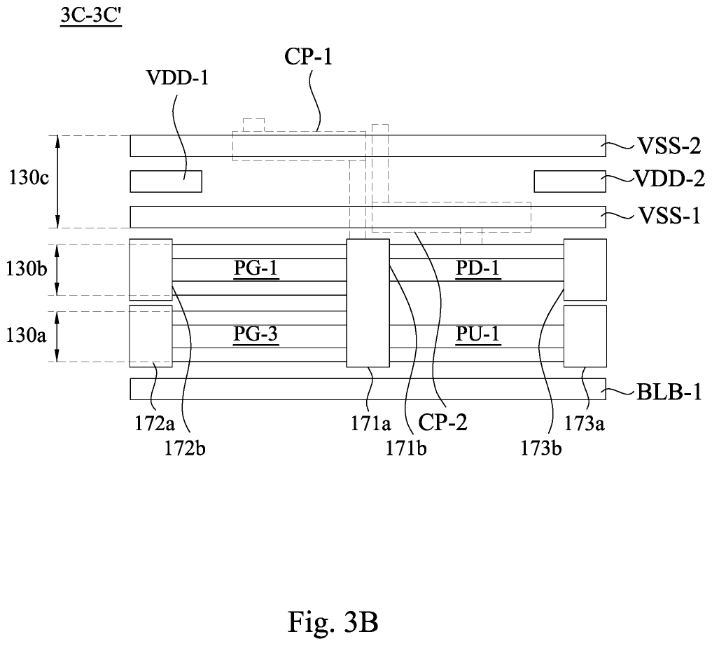

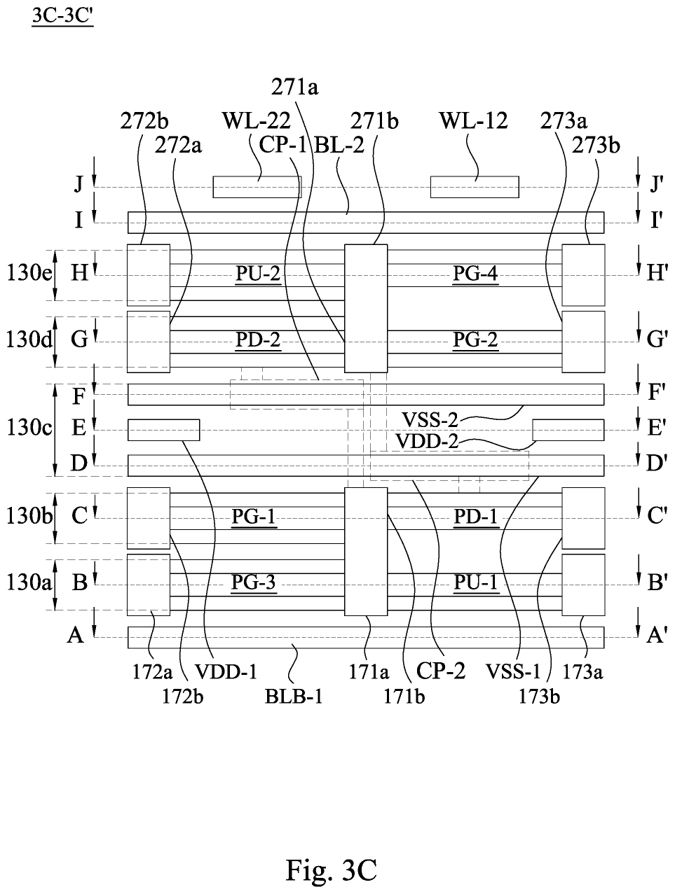

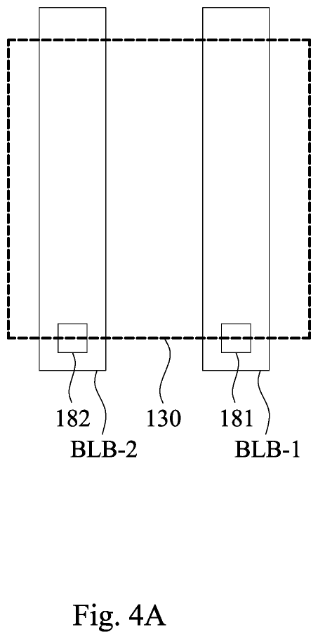

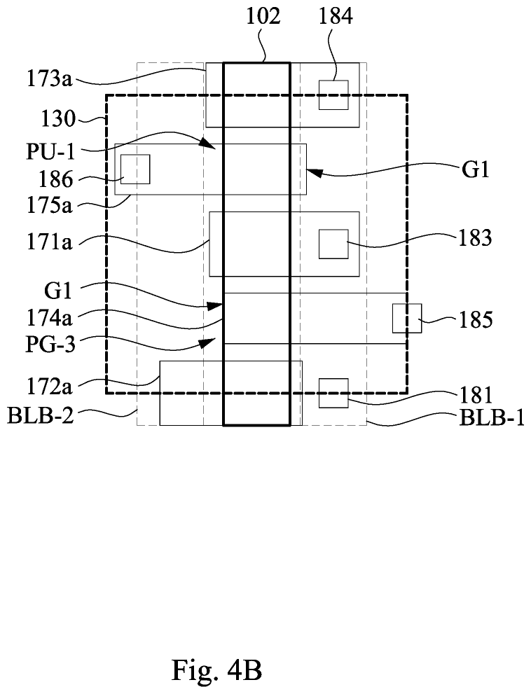

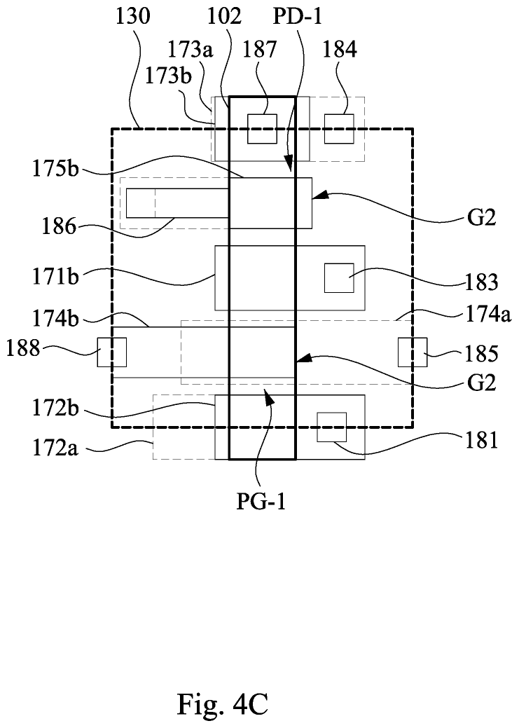

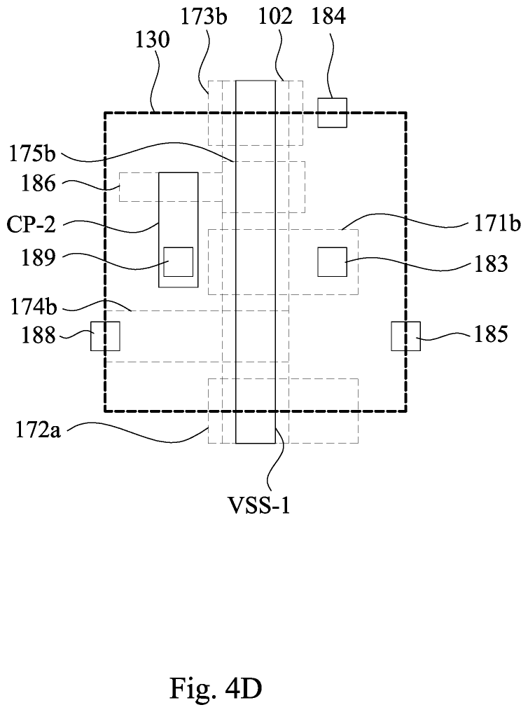

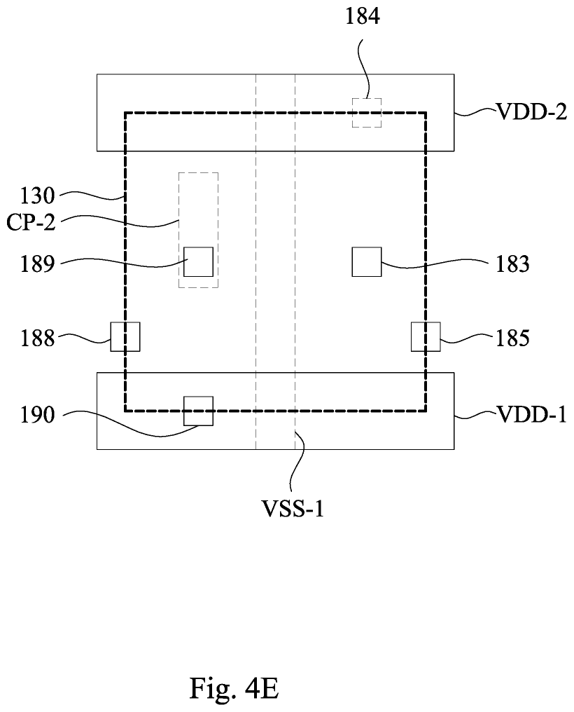

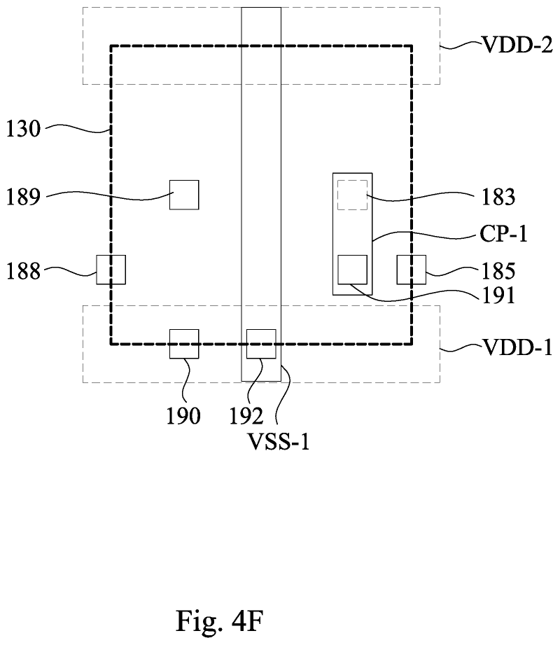

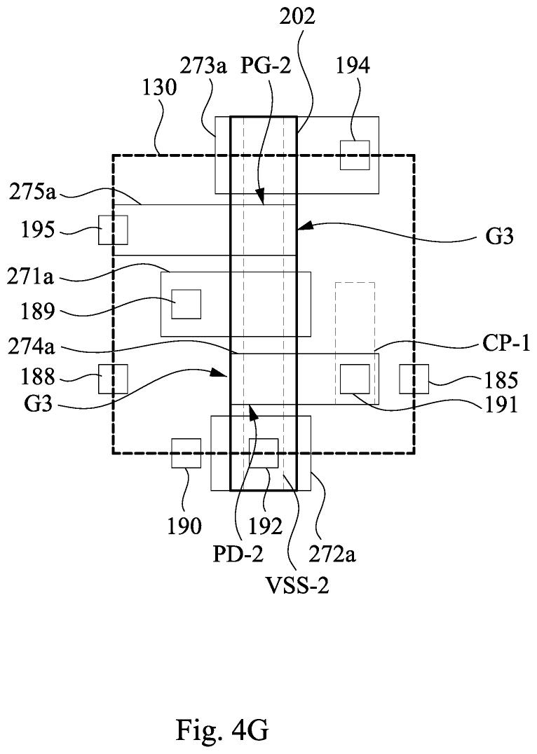

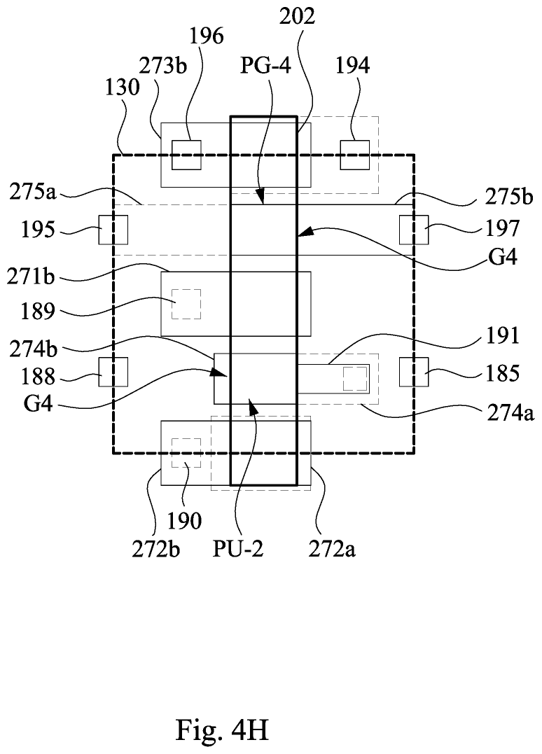

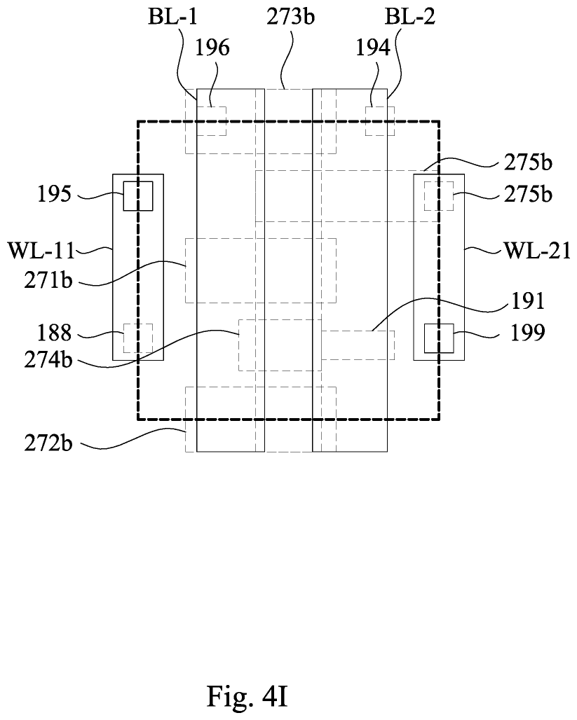

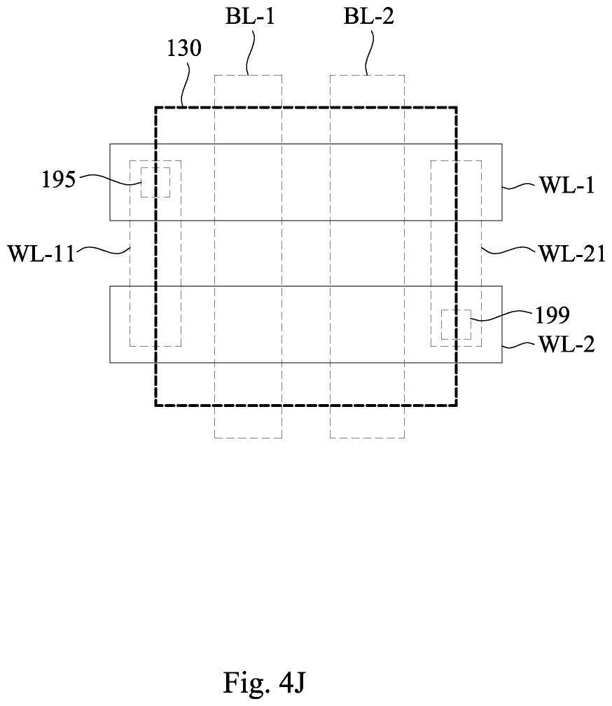

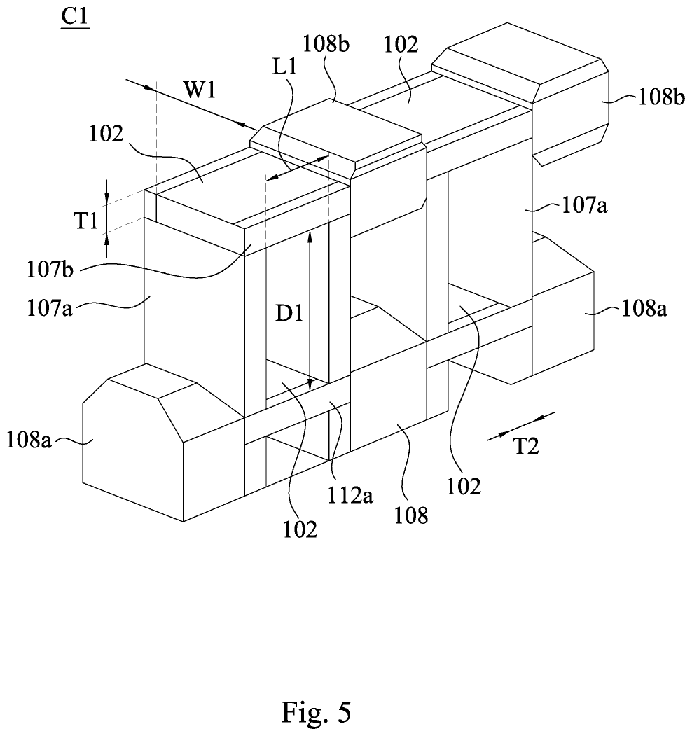

Reference is made to FIGS. 2-5. FIG. 2 illustrates a perspective view a semiconductor structure in accordance with some embodiments of the present disclosure. FIGS. 3A-3C illustrate cross-sectional views of intermediate stages in the formation of the semiconductor structure obtained from reference cross-section 3C-3C′ in FIG. 2. FIGS. 4A-4J illustrate cross-sectional views of obtained from reference cross-sections A-A′, B-B′, C-C′, D-D′. E-E′. F-F′, G-G′, H-H′, I-I′, and J-J′ in FIG. 3C. FIG. 5 illustrates a local enlarged view of region Cl in FIG. 2. Specifically, the present disclosure in various embodiments provides a sequential 4-layer structure for the dual port SRAM bitcell, which incorporates a total of 8 transistors (e.g., pass-gate transistors PG-1, PG-2, PG-3, and PG-4, pull-up transistors PU-1 and PU-2, and pull-down transistors PD-1 and PD-2 as shown in FIG. 3C). This approach enables us to achieve the same functionality with a significantly reduced footprint, requiring only 2 transistors.

In addition, an inter-metal dielectric layer (e.g. MEOL layer 130c) can be introduced to be formed above the bottom-tier transistors (e.g., pass-gate transistors PG-1 and PG-3, pull-up transistor PU-1, and pull-down transistor PD-1) in the dual port SRAM bitcell. This MEOL layer 130c can provide a platform for the placement of power lines (e.g. ground lines VSS-1 and VSS-2 and voltage source line VDD-1 and VDD-2 as shown in FIG. 3C) and cross coupling lines (e.g., cross coupling lines CP-1 and CP-2 as shown in FIG. 3C) between the bottom-tier transistors (e.g., pass-gate transistors PG-1 and PG-3, pull-up transistor PU-1, and pull-down transistor PD-1) and the top tier transistors (e.g., pass-gate transistors PG-2 and PG-4, pull-up transistor PU-2, and pull-down transistor PD-2). Moreover, buried metal lines (e.g., complementary bit lines BLB-1 and BLB-2 as shown in FIGS. 2 and 3C) are formed beneath the bottom-tier transistors to mitigate routing congestion. Hence, by reducing the footprint of the dual port SRAM bitcell from 12 transistors to only 2 transistors, we greatly enhance space efficiency and enable more compact designs. This reduction in footprint allows for higher device density, potentially leading to lower production costs. In addition, the introduction of the inter-metal dielectric layer and buried metal lines effectively addresses routing congestion, thereby improving the overall performance and efficiency of the SRAM bitcell.

As shown in FIGS. 2, and 3C, and 4A, the complementary bit lines BLB-1 and BLB-2 can be formed over a substrate (not shown) and extend in parallel with each other in a same level height. In some embodiments, a via 181 can be formed over the complementary bit line BLB-1 and further upwardly extend to connect a source/drain contact of the pass-gate transistors PG-1 formed subsequently. In some embodiments, a via 182 can be formed over the bit line complementary BLB-2 and further upwardly extend to connect a source/drain contact of the pass-gate transistors PG-3 formed subsequently.

As shown in FIGS. 2, and 3C, and 4B, the pass-gate transistors PG-3 and the pull-up transistor PU-1 can be formed over the complementary bit lines BLB-1 and BLB-2 and arranged in a lengthwise direction of the complementary bit line BLB-1 from a top view. The pass-gate transistors PG-3 and the pull-up transistor PU-1 each comprise a channel layer 102 (see FIG. 5), a gate structure G1 surrounding the channel region, and source/drain regions 108a (see FIG. 5) on opposite sides of the gate structure G1. In some embodiments, the layer in which the pass-gate transistors PG-3 and the pull-up transistor PU-1 are located can be interchangeably referred to as the bottom layer 130a within the 4-layer structure of the dual port SRAM bitcell 130.

In some embodiments, a number of the channel layer 102 in the transistor can be in a range from about 1 to 101, such as about 1, 2, 3, 4, 5, 6, 7, 8, 9, 10, 20, 30, 40, 50, 60, 70, 80, 90, 100, or 101. As shown in FIG. 5, the adjacent two channel layers 102 can be spaced apart from each by a vertical distance D1 in a range from about 5 to 50 nm, such as about 5, 10, 15, 20, 25, 30, 35, 40, 45, or 50 nm. In some embodiments, the channel layer 102 can has a length L1 in a range from about 5 to 500 nm, such as about 5, 10, 15, 20, 50, 100, 150, 200, 250, 300, 350, 400, 450, or 500 nm. In some embodiments, the channel layer 102 can has a thickness T1 in a range from about 0.5 to 50 nm, such as about 0.5, 1, 5, 10, 15, 20, 25, 30, 35, 40, 45, or 50 nm. In some embodiments, the channel layer 102 can has a width W1 in a range from about 5 to 100 nm, such as about 5, 10, 20, 30, 40, 50, 60, 70, 80, 90, or 100 nm. In some embodiments, geometry of the channel layer 102 can be square, rectangle, diamond, any suitable geometry, or combinations thereof. In some embodiments, the channel layer 102 may be made of may be made of a material, such as silicon, germanium, silicon germanium, silicon germanium tin, silicon carbide, a III-V compound semiconductor, a II-VI compound semiconductor, or the like. In some embodiments, the channel layer 102 can be interchangeably referred to as a channel pattern, a channel region, a semiconductive layer, a semiconductor sheet, a nanowire, or a nanostructure.

In some embodiments, the source/drain region 108a may include Ge, Si, GaAs, AlGaAs, SiGe, SiGeSn, GaAsP, SiP, or other suitable material. The source/drain regions 108a may be doped by introducing doping species including: p-type dopants, such as boron or BF₂; n-type dopants, such as phosphorus or arsenic; and/or other suitable dopants including combinations thereof. In some exemplary embodiments, the source/drain regions 108a in a p-type include SiGeB and/or GeSnB. In some embodiments, the source/drain regions 108a can be interchangeably referred to as a source/drain pattern, a source/drain structure, an epitaxial pattern, or an epitaxial structure.

In some embodiments, a spacer 107a can be formed to surround a lateral end portion of the channel layer 102, and the lateral end portion of the channel layer 102 can be interchangeably referred to as a source/drain extension. In some embodiments, the spacer may have a thickness T2 in a range from about 1 to 20 nm, such as about 1, 2, 3, 4, 5, 6, 7, 8, 9, 10, 11, 12, 13, 14, 15, 16, 17, 18, 19, or 20 nm. In addition, a channel sidewall spacer 112a can be formed on a sidewall of the channel layer 102 and extend from one of the source/drain regions 108a to another one of the source/drain regions 108a along a lengthwise direction of the channel layer 102. In some embodiments, the spacer 107a and/or the channel sidewall spacer 112a may include a dielectric material such as silicon oxide, silicon nitride, silicon carbide, silicon oxynitride, SiCN films, silicon oxycarbide, SiOCN films, and/or combinations thereof. In some embodiments, the spacer 107a may be made of a same material as the channel sidewall spacer 112a. In some embodiments, the spacer 107a may be made of a different material than the channel sidewall spacer 112a.

Referring back to FIGS. 2, and 3C, and 4B, a source/drain contact 171a can be formed over the source/drain region 108a between the pass-gate transistor PG-3 and the pull-up transistor PU-1, and can be electrically connected to the cross coupling lines CP-1 (FIG. 4F) formed subsequently through a via 183. A source/drain contact 172a can be formed to land on the source/drain region 108a of the pass-gate transistor PG-3 at a side opposing the pull-up transistor PU-1, and can be electrically connected to the complementary bit line BLB-2 through the via 182 (see FIG. 4A). A source/drain contact 173a can be formed to land on the source/drain region 108a of the pull-up transistor PU-1 at a side opposing the pass-gate transistor PG-3, and can be electrically connected to the voltage source line VDD-2 formed subsequently through a via 184. A gate contact 174a can be formed to land on the gate structure G1 of the pass-gate transistor PG-3, and can be electrically connected to the word line WL-21 through a via 185. A gate contact 175a can be formed to land on the gate structure G1 of the pull-up transistor PU-1, and can be electrically connected to the pull-down transistor PD-1 through a vertical local interconnect 186. In some embodiments, the vertical local interconnect 186 can have L-shaped configuration. In some embodiments, the source/drain contacts 171a, 172a, and 173a and the gate contacts 174a and 175a can extend in parallel with each other and along a direction perpendicular to the lengthwise direction of the complementary bit line BLB-1.

As shown in FIGS. 2, and 3C, and 4C, the pass-gate transistors PG-1 and the pull-down transistor PD-1 are formed over the pass-gate transistors PG-3 and the pull-up transistor PU-1 and are vertical stacked with the pass-gate transistors PG-3 and the pull-up transistor PU-1. In other words, the pass-gate transistors PG-1 and the pull-down transistor PD-1 are at a higher level height than the pass-gate transistors PG-3 and the pull-up transistor PU-1. The pass-gate transistors PG-1 and the pull-down transistor PD-1 each comprise a channel layer 102 (see FIG. 5), a gate structure G2 surrounding the channel region, and source/drain regions 108b (see FIG. 5) on opposite sides of the gate structure G2. Specifically, a complementary field-effect transistor (CFET) structure, is a transistor structure that incorporates vertically stacked nanostructure-FETs (e.g., pass-gate transistors PG-1. PG-3, pull-up transistor PU-1, and pull-down transistor PD-1). This arrangement allows for efficient vertical stacking of transistors, optimizing device density and facilitating memory operations. These nanostructure-FETs can include various types of nanoscale semiconductor structures such as nanowires, nanosheets, multi-bridge channel (MBC) FETs, nanoribbons, gate-all-around (GAA) FETs, or similar configurations. In some embodiments, the layer in which the pass-gate transistors PG-1 and the pull-down transistor PD-1 are located can be interchangeably referred to as the first middle layer 130b within the 4-layer structure of the dual port SRAM bitcell 130.

In some embodiments, the source/drain region 108b may include Ge, Si, GaAs, AlGaAs, SiGe, GaAsP, SiP, or other suitable material. The source/drain region 108b may be doped by introducing doping species including: p-type dopants, such as boron or BF₂; n-type dopants, such as phosphorus or arsenic; and/or other suitable dopants including combinations thereof. In some embodiments, the source/drain region 108b can be interchangeably referred to as a source/drain pattern, a source/drain structure, an epitaxial pattern, or an epitaxial structure.

The source/drain contact 171b can be formed over the source/drain region 108b between the pass-gate transistors PG-1 and the pull-down transistor PD-1, and can be electrically connected to the cross coupling lines CP-1 formed subsequently through the via 183. A source/drain contact 172b can be formed to land on the source/drain region 108b of the pass-gate transistor PG-1 at a side opposing the pull-down transistor PD-1, and can be electrically connected to the complementary bit line BLB-1 through the via 181 (see FIG. 4B). A source/drain contact 173b can be formed to land on the source/drain region 108b of the pull-down transistor PD-1 at a side opposing the pass-gate transistor PG-1, and can be electrically connected to the ground line VSS-1 formed subsequently through a via 187. A gate contact 174b can be formed to land on the gate structure G1 of the pass-gate transistor PG-1, and can be electrically connected to the word line WL-11 through a via 188. A gate contact 175b can be formed to land on the gate structure G1 of the pull-down transistor PD-1, and can be electrically connected to the pull-up transistor PU-1 through the vertical local interconnect 186. In some embodiments, the source/drain contacts 171b, 172b, and 173b and the gate contacts 174b and 175b can extend in parallel with each other and along a direction perpendicular to the lengthwise direction of the complementary bit line BLB-1.

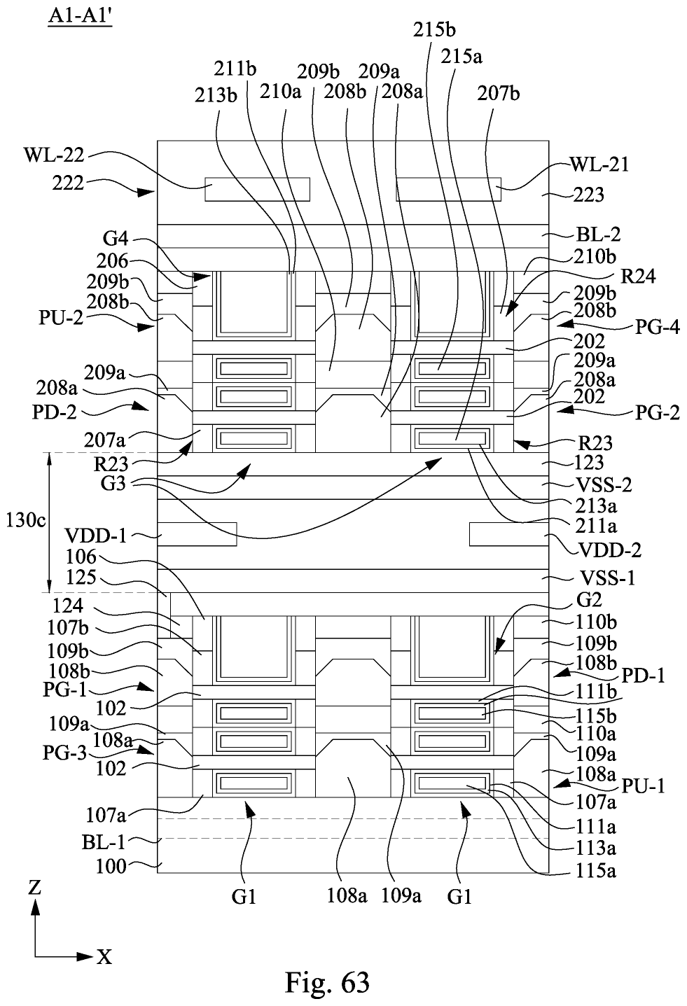

As shown in FIGS. 2, and 3C, and 4D, the ground line VSS-1 and the cross coupling line CP-2 can be formed over the pass-gate transistors PG-3 and the pull-down transistor PD-1 at a same level height. The ground line VSS-1 can be electrically connected to the underlying source/drain contact 173b (see FIG. 4C) on a source/drain region 108b (see FIG. 63) of the pull-up transistor PD-1 through a via 187. The cross coupling line CP-2 can be electrically connected to the underlying vertical local interconnect 186 (see FIG. 4C) to the gate structure G1 of the pull-up transistor PD-1, and can be electrically connected to the overlying source/drain contact 271a (see FIG. 4G) formed subsequently on the source/drain region 208a between the transistors PG-2 and PD-2 through a via 189. In some embodiments, the ground line VSS-1 and the cross coupling line CP-2 can extend in parallel with each other and along the lengthwise direction of the complementary bit line BLB-1.

As shown in FIGS. 2, and 3C, and 4E, the voltage source line VDD-1 and VDD-2 can be formed over the ground line VSS-1. The voltage source line VDD-2 can be electrically connected to the underlying source/drain contact 173a (see FIG. 4B) on the source/drain region 108a of the transistor PU-1 through the via 184 (see FIGS. 4B, 4C, and 4D). The voltage source line VDD-1 can be electrically connected to the overlying source/drain contact 272b (see FIG. 4B) on a source/drain region 208b (see FIG. 63) of the pull-up transistor PU-2 through the via 190. In some embodiments, the voltage source lines VDD-1 and VDD-2 can extend in parallel with each other and along a direction perpendicular to a lengthwise direction of the ground line VSS-1. In some embodiments, the voltage source lines VDD-1 and VDD-2 can be interchangeably referred to as power lines.

As shown in FIGS. 2, and 3C, and 4F, the ground line VSS-2 and the cross coupling line CP-1 can be formed over the voltage source line VDD-1 and VDD-2 at a same level height. That is, the ground line VSS-2 are at a higher level height than the voltage source line VDD-1 and VDD-2, the ground line VSS-2, and the coupling line CP-2. The ground line VSS-2 can be electrically connected to the overlying source/drain contact 272a (see FIG. 4G) formed subsequently on the source/drain region 208a of the transistor PD-2 through a via 192. The cross coupling line CP-1 can be electrically connected to the underlying source/drain contact 171b (see FIG. 4C) on the source/drain region 108b between the transistors PG-1 and PD-1 through the via 183, and can be electrically connected to an overlying gate contact 274b (see FIG. 4G) formed subsequently on the gate structure G3 of the transistors PD-2 through a vertical local interconnect 191. In some embodiments, the vertical local interconnect 191 can have L-shaped configuration. In some embodiments, the ground line VSS-2 and the cross coupling line CP-1 can extend in parallel with each other and along a direction perpendicular to a lengthwise direction of the voltage source line VDD-1. In some embodiments, the ground lines VSS-1 and VSS-2 can be interchangeably referred to as power lines. In some embodiments, the layer in which the ground lines VSS-1 and VSS-2, the voltage source line VDD-1 and VDD-2, and the cross coupling lines CP-1 and CP-2 are located can be interchangeably referred to as the MEOL layer 130c within the 4-layer structure of the dual port SRAM bitcell 130.

As shown in FIGS. 2, and 3C, and 4G, the pull-down transistor PD-2 and the pass-gate transistors PG-2 are formed over the ground line VSS-2 and the cross coupling line CP-1. In some embodiments, the pull-down transistor PD-2 and the pass-gate transistors PG-2 can be vertical stacked with the pass-gate transistors PG-1 and PG-3, the pull-up transistor PU-1, and the pull-down transistor PD-1. In other words, the pull-down transistor PD-2 and the pass-gate transistors PG-2 are at a higher level height than the pass-gate transistors PG-1 and the pull-down transistor PD-1. The pull-down transistor PD-2 may overlap with the pass-gate transistors PG-1 and PG-3, and the pass-gate transistor PG-2 may overlap with the pull-up transistor PU-1 and the pull-down transistor PD-1. The pull-down transistor PD-2 and the pass-gate transistors PG-2 each comprise a channel region 202 (see FIG. 5), a gate structure G3 surrounding the channel region 202, and source/drain regions 208a (see FIG. 5) on opposite sides of the gate structure G3. In some embodiments, the layer in which the pull-down transistor PD-2 and the pass-gate transistors PG-2 are located can be interchangeably referred to as the second middle layer 130d within the 4-layer structure of the dual port SRAM bitcell 130.

In some embodiments, the configuration, the material, and the formation method of the channel region 202 are similar to those of the channel layer 102, and thus relevant details will not be repeated for brevity. In some embodiments, the channel region 202 can be interchangeably referred to as a channel pattern, a channel layer, a semiconductive layer, a semiconductor sheet, a nanowire, or a nanostructure. In some embodiments, the source/drain region 208a may include Ge, Si, GaAs, AlGaAs, SiGe, GaAsP, SiP, or other suitable material. The source/drain region 208a may be doped by introducing doping species including: p-type dopants, such as boron or BF₂; n-type dopants, such as phosphorus or arsenic; and/or other suitable dopants including combinations thereof. In some embodiments, the source/drain region 208a can be interchangeably referred to as a source/drain pattern, a source/drain structure, an epitaxial pattern, or an epitaxial structure.

A source/drain contact 271a can be formed over the source/drain region 208a (see FIG. 63) between the pass-gate transistor PG-2 and the pull-up transistor PD-2, and can be electrically connected to the underlying cross coupling lines CP-2 (FIG. 4D) through the via 189 (FIGS. 4D-4F). A source/drain contact 272a can be formed to land on the source/drain region 208a of the pull-down transistor PD-2 at a side opposing the pass-gate transistor PG-2, and can be electrically connected to the underlying ground line VSS-2 (see FIG. 4F) through the underlying via 192 (see FIGS. 4F and 4G). A source/drain contact 273a can be formed to land on the source/drain region 208a of the pass-gate transistor PG-2 at a side opposing the pull-down transistor PD-2, and can be electrically connected to the overlying bit line BL-2 (see FIG. 4I) formed subsequently through a via 194. A gate contact 274a can be formed to land on the gate structure G3 of the pull-down transistor PD-2, can be electrically connected to the gate structure G3 of the pull-up transistor PU-2 (see FIG. 4H) formed subsequently through the vertical local interconnect 191. A gate contact 275a can be formed to land on the gate structure G3 of the pass-gate transistor PG-2, and can be electrically connected to the overlying word line WL-11 (see FIG. 4J) formed subsequently through a via 195 (see FIGS. 4H-4J). In some embodiments, the source/drain contacts 271a, 272a, and 273a and the gate contacts 274a and 275a can extend in parallel with each other and along a direction perpendicular to the lengthwise direction of the ground line VSS-1.

As shown in FIGS. 2, and 3C, and 4H, the pull-up transistor PU-2 and the pass-gate transistors PG-4 are formed over the pull-down transistor PD-2 and the pass-gate transistors PG-2 and are vertical stacked with the pass-gate transistors PG-2 and the pull-up transistor PG-2. In other words, the pull-up transistor PU-2 and the pass-gate transistors PG-4 are at a higher level height than the pull-down transistor PD-2 and the pass-gate transistors PG-2. The pull-down transistor PU-2 may overlap with the pull-down transistor PD-2, and the pass-gate transistor PG-4 may overlap with the pass-gate transistor PG-2. The pull-up transistor PU-2 and the pass-gate transistors PG-4 each comprise a channel region 202 (see FIG. 63), a gate structure G4 surrounding the channel region, and source/drain regions 208b on opposite sides of the gate structure G4. Specifically, a complementary field-effect transistor (CFET) structure, is a transistor structure that incorporates vertically stacked nanostructure-FETs (e.g., pass-gate transistors PG-2, PG-4, pull-up transistor PU-2, and pull-down transistor PD-2). This arrangement allows for efficient vertical stacking of transistors, optimizing device density and facilitating memory operations. In some embodiments, the gate structure G1. G2, G3, and/or G4 can be interchangeably referred to as a gate strip or a gate pattern. In some embodiments, the layer in which the pull-up transistor PU-2 and the pass-gate transistors PG-4 are located can be interchangeably referred to as the top layer 130e within the 4-layer structure of the dual port SRAM bitcell 130.

The source/drain contact 271b can be formed over the source/drain region 208b between the pass-gate transistors PG-2 and the pull-up transistor PU-2, and can be electrically connected to the underlying cross coupling line CP-2 (see FIG. 4D) through the via 189 (see FIGS. 4D-4G). A source/drain contact 272b can be formed to land on the source/drain region 108b of the pull-up transistor PU-2 at a side opposing the pass-gate transistor PG-4, and can be electrically connected to the underlying voltage source line VDD-1 (see FIG. 4E) through the via 190 (see FIGS. 4E-4H). A source/drain contact 273b can be formed to land on the source/drain region 208b of the pass-gate transistor PG-4 at a side opposing the pull-up transistor PU-2, can be electrically connected to the overlying bit line BL-1 (see FIG. 4I) formed subsequently through a via 196. A gate contact 274b can be formed to land on the gate structure G4 of the pull-up transistor PG-1, and can be electrically connected to the underlying gate contact 274a and further to the underlying cross coupling line CP-1 through the vertical local interconnect 191. A gate contact 275b can be formed to land on the gate structure G4 of the pass-gate transistor PG-4, and can be electrically connected to the word line WL-21 (see FIG. 4J) formed subsequently through a via 197. In some embodiments, the source/drain contacts 271b, 272b, and 273b and the gate contacts 274b and 275b can extend in parallel with each other and along the direction perpendicular to the lengthwise direction of the ground line VSS-2.

In some embodiments, the source/drain region 208b may include Ge, Si, GaAs, AlGaAs, SiGe, SiGeSn, GaAsP, SiP, or other suitable material. The source/drain regions 208a may be doped by introducing doping species including: p-type dopants, such as boron or BF₂; n-type dopants, such as phosphorus or arsenic; and/or other suitable dopants including combinations thereof. In some exemplary embodiments, the source/drain regions 208b in a p-type include SiGeB and/or GeSnB. In some embodiments, the source/drain regions 208b can be interchangeably referred to as a source/drain pattern, a source/drain structure, an epitaxial pattern, or an epitaxial structure.

In some embodiments, the pass-gate transistors PG-2 and PG-4, the pull-up transistors PU-2, and the pull-down transistor PD-2 can be interchangeably referred to as top tier transistors. In some embodiments, the pass-gate transistors PG-1 and PG-3, the pull-up transistors PU-1, and the pull-down transistor PD-1 can be interchangeably referred to as bottom-tier transistors.

As shown in FIGS. 2, and 3C, and 4I, the bit lines BL-1 and BL-2 and the word lines WL-11 and WL-21 can be formed over the pull-up transistor PU-2 and the pass-gate transistors PG-4. The bit line BL-1 can be electrically connected to the underlying the source/drain contact 273b (see FIG. 4H) on the source/drain region 208b of the pass-gate transistor PG-4 through the via 196. The bit line BL-2 can be electrically connected to the underlying source/drain contact 273a (see FIG. 4G) on the source/drain region 208a of the pass-gate transistor PG-2 through the via 194. The word line WL-11 can be electrically connected to the underlying gate contact 275a (see FIG. 4G) on the gate structure G3 of the pass-gate transistor PG-2 through the via 195, and can be electrically connected to the underlying gate contact 174b (see FIG. 4C) on the gate structure G1 of the pass-gate transistor PG-1 through the via 188. The word line WL-21 can be electrically connected to the underlying gate contact 275b (see FIG. 4H) on the gate structure G4 of the pass-gate transistor PG-4 through the via 197, and can be electrically connected to the underlying gate contact 174a (see FIG. 4B) on the gate structure G1 of the pass-gate transistor PG-3 through the via 185. In some embodiments, the bit lines BL-1 and BL-2 and the word lines WL-11 and WL-21 can extend in parallel with each other and along a direction perpendicular to a lengthwise direction of the gate structure G4. A via 198 can be formed to land on the word line WL-11, such that the word line WL-11 can be electrically connected to the overlying word line W21 (see FIG. 4J) formed subsequently through the via 198. A via 199 can be formed to land on the word line WL-12, such that the word line WL-12 can be electrically connected to the overlying word line W22 (see FIG. 4J) formed subsequently through the via 199.

As shown in FIGS. 2, and 3C, and 4J, the word lines WL-21 and WL-22 are formed over the bit lines BL-1 and BL-2. The word line WL-21 can be electrically connected to the underlying word line WL-11 (FIG. 4I) through the via 198, and the word line WL-22 can be electrically connected to the underlying word line WL-12 (FIG. 4I) through the via 199. In some embodiments, the word lines WL-21 and WL-22 can extend in parallel with each other and along a direction perpendicular to lengthwise directions of the word lines WL-11 and WL-12. In some embodiments, the bit lines BL-1 and BL-2 and the complementary bit lines BLB-1 and BLB-2, the cross coupling lines CP-1 and CP-2, the voltage source line VDD-1 and VDD-2, the ground lines VSS-1 and VSS-2, and/or the word lines WL-11, WL-12, W-21, and W-22 can be interchangeably referred to as conductive lines, metal lines, line patterns, or conductors.

The 4-layer structure for the dual port SRAM bitcell 130 can be formed using a monolithic process, as illustrated in FIGS. 3A-3C. This structure follows a sequential formation, starting from the bottom and progressing upwards. The sequential order includes the bottom layer 130a (depicted in FIGS. 3A and 4B), the first middle layer 130b (shown in FIGS. 3A and 4C), the MEOL layer 130c (illustrated in FIGS. 3B and 4D-4F), the second middle layer 130d (depicted in FIGS. 3C and 4G), and the top layer 130e (shown in FIGS. 3C and 4H). Alternatively, in other embodiments, the 4-layer structure for the dual port SRAM bitcell can be formed using a sequential process. This approach allows for the separate formation of at least one component from the bottom layer 130a, the first middle layer 130b, the MEOL layer 130c, the second middle layer 130d, or the top layer 130e within the 4-layer structure (as indicated in FIGS. 3A-3C and 4B-4H). These components can then be combined through bonding to construct the 4-layer structure for the dual port SRAM bitcell 130.

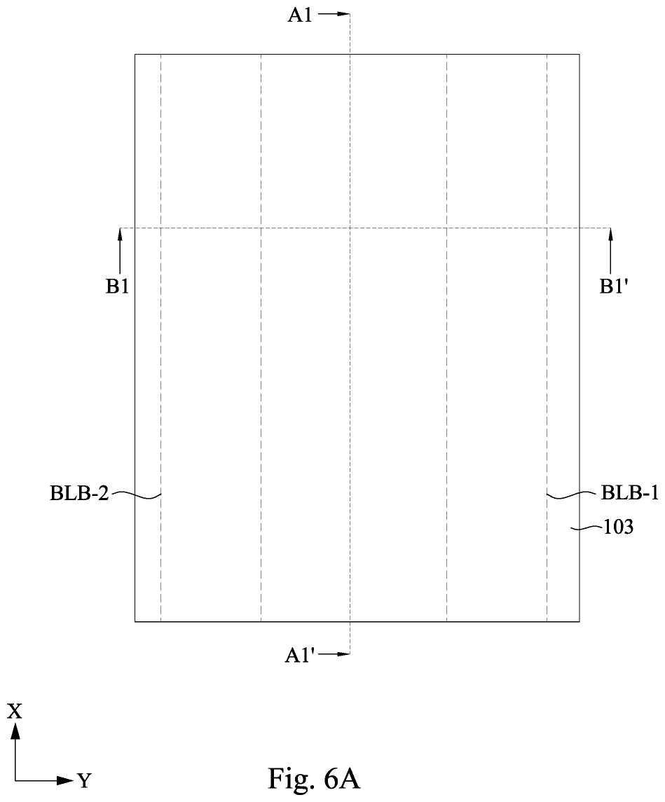

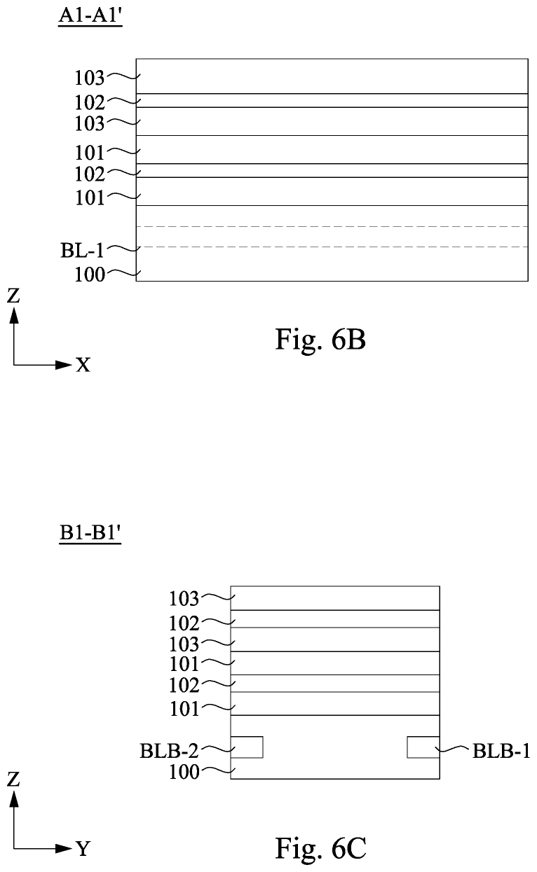

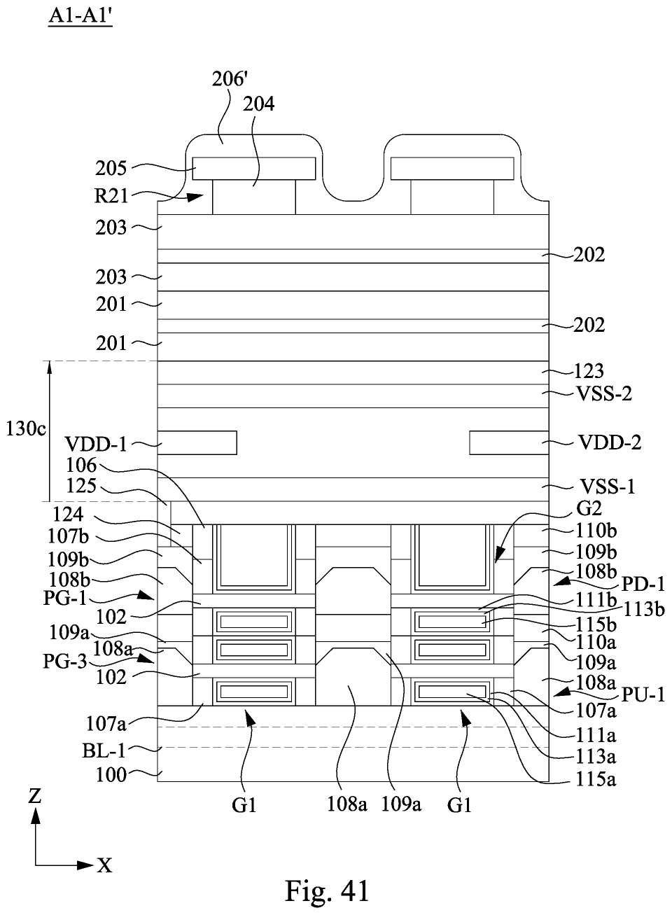

Reference is made to FIGS. 6A-63. FIGS. 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A, 29A, 30A, 31A, 32A, 33A, 34A, 35A, 36A, and 37A illustrate top views of intermediate stages in the formation of a semiconductor structure in accordance with some embodiments. FIGS. 6B, 7B, 8B, 9B, 10B, 11B, 12B, 13B, 14B, 15B, 16B, 17B, 18B, 19B, 20B, 21B, 22B, 23B, 24B, 25B, 26B, 27B, 28B, 29B, 30B, 31B, 32B, 33B, 34B, 35B, 36B, 37B, 38, 39, 40, 41, 42, 43, 44, 45, 46, 47, 48, 49, 50, 51, 52, 53, 54, 55, 56, 57, 58, 59, 60, 61, 62, and 63 illustrate cross-sectional views obtained from the reference cross-section A1-A1′ in FIGS. 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A, 29A, 30A, 31A, 32A, 33A, 34A, 35A, 36A, and 37A of intermediate stages in the formation of a semiconductor structure in accordance with some embodiments. FIGS. 6C, 7C, 8C, 9C, 10C, 11C, 12C, 13C, 14C, 15C, 16C, 17C, 18C, 19C, 20C, 21C, 22C, 23C, 24C, 25C, 26C, 27C, 28C, 29C, 30C, 31C, 32C, 33C, 34C, 35C, 36C, and 37C illustrate cross-sectional views obtained from the reference cross-section B1-B1′ in FIGS. 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A, 29A, 30A, 31A, 32A, 33A, 34A, 35A, 36A, and 37A of intermediate stages in the formation of a semiconductor structure in accordance with some embodiments.

Reference is made to FIGS. 6A, 6B, and 6C. An epitaxial stack is formed over a substrate 100. In some embodiments, the substrate 100 may include silicon (Si). Alternatively, the substrate 100 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 100 may include a semiconductor-on-insulator (SOI) structure such as a buried dielectric layer. Also alternatively, the substrate 100 may include a buried dielectric layer such as a buried oxide (BOX) layer, such as that formed by a method referred to as separation by implantation of oxygen (SIMOX) technology, wafer bonding, SEG, or another appropriate method.

The epitaxial stack includes sacrificial layers 101 and 103 of first and second compositions interposed by channel layers 102 of a third composition. The first, second, and third compositions can be different. In some embodiments, the sacrificial layers 101 and 103 may be made of SiGe and having different germanium atomic concentrations, and the channel layers 102 may be made of silicon (Si). In some embodiments, the sacrificial layer 101 has a greater germanium atomic concentration than the sacrificial layer 103. For example, the sacrificial layer 101 may having a germanium atomic concentration in a range from about 70 to 90%, such as about 70, 75, 80, 85, or 90%, and the sacrificial layer 103 may having a germanium atomic concentration in a range from about 30 to 70%, such as about 30, 35, 40, 45, 50, 55, 60, 65, or 70%. However, other embodiments are possible including those that provide for first, second, and third compositions having different etch selectivity. By way of example, the germanium atomic concentration of the sacrificial layer 101 can be about 80%, and the germanium atomic concentration of the sacrificial layer 101 can be about 60%.

The use of the channel layers 102 to define a channel or channels of a device is further discussed below. It is noted that two layers of the channel layers 102 are arranged as illustrated in FIGS. 6B and 6C, which is for illustrative purposes only and not intended to be limiting beyond what is specifically recited in the claims. It can be appreciated that any number of sacrificial layers can be formed in the epitaxial stack; the number of layers depending on the desired number of channels regions for the transistor. In some embodiments, the number of each of the channel layers 102 can be between about 2 and 200. As described in more detail below, the channel layers 102 may serve as channel region(s) for a subsequently-formed semiconductor device and the thickness is chosen based on device performance considerations. The sacrificial layers 101 and 103 in channel regions(s) may eventually be removed and serve to define a vertical distance between adjacent channel region(s) for a subsequently-formed multi-gate device and the thickness is chosen based on device performance considerations.

By way of example, epitaxial growth of the layers of the epitaxial stack may be performed by a molecular beam epitaxy (MBE) process, a metalorganic chemical vapor deposition (MOCVD) process, and/or other suitable epitaxial growth processes. In some embodiments, the epitaxially grown layers such as, the channel layers 102 and 102 include the same material as the substrate 100. In some embodiments, the sacrificial layers 101 and 103 and channel layer 102 can include different materials than the substrate 100. As stated above, in at least some examples, the sacrificial layers 101 and 103 can include epitaxially grown silicon germanium (SiGe) layers, and the channel layers 102 include an epitaxially grown silicon (Si) layer. Alternatively, in some embodiments, either of the sacrificial layers 101 and 103, and the channel layer 102 may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP. AlInAs, AlGaAs, InGaAs, GaInP, and/or GaInAsP, III-V, or combinations thereof. As discussed, the materials of the sacrificial layers 101 and 103 and the channel layer 102 may be chosen based on providing differing oxidation and/or etching selectivity properties.

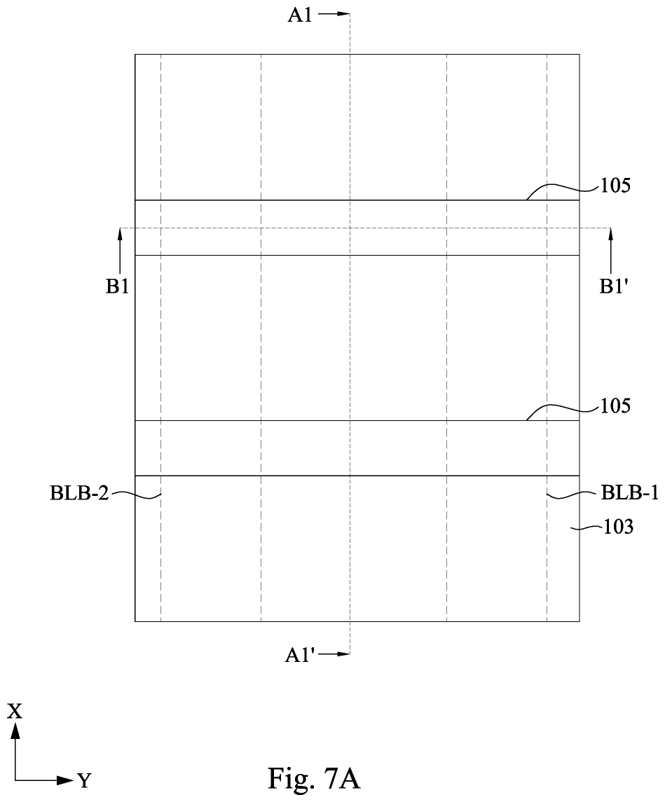

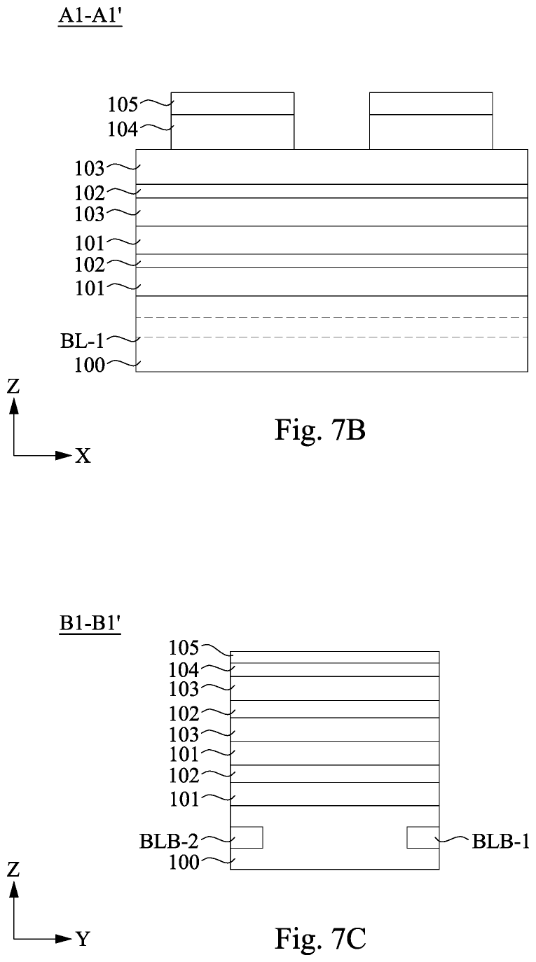

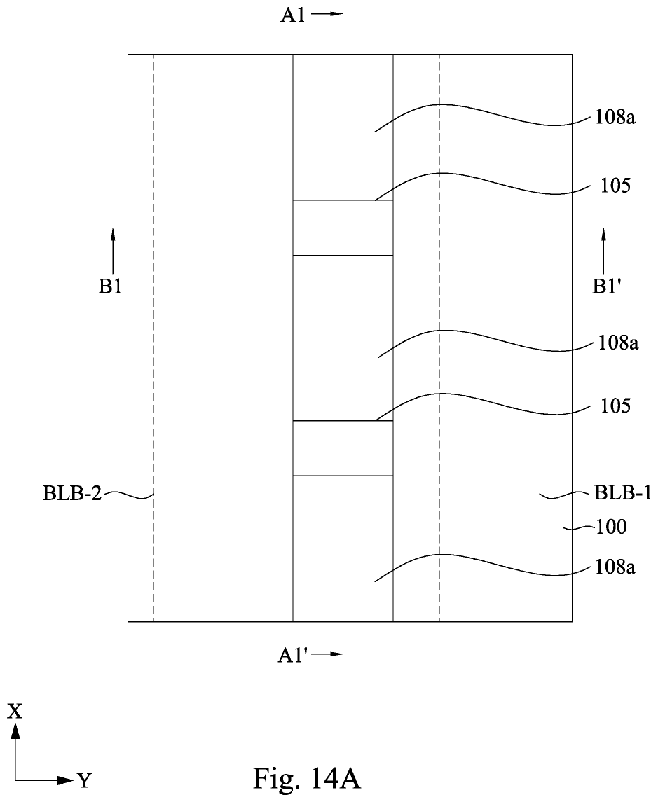

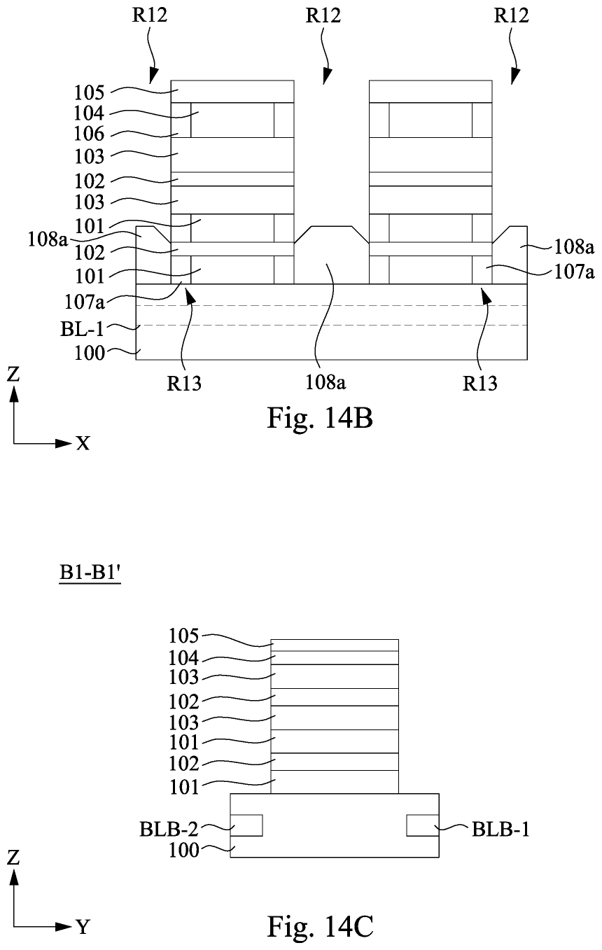

Reference is made to FIGS. 7A, 7B, and 7C. Dummy gate layers 104 and hard mask layers 105 are formed over the epitaxial stack as shown in FIGS. 6A-6C. Portions of the channel layer 102 underlying the dummy gate layers 104 may be referred to as the channel regions. The dummy gate layer 104 may also define source/drain regions 108a (labeled in FIGS. 14A and 14B). Dummy gate formation operation forms the dummy gate layer 104 and the hard mask layer 105 over the dummy gate layer 104. The hard mask layer 105 is then patterned, followed by patterning the dummy gate layer 104 by using the patterned hard mask layer 105 as an etch mask. The etch process may include a wet etch, a dry etch, and/or combinations thereof.

In some embodiments, the dummy gate layer 104 may include polycrystalline-silicon (poly-Si), poly-crystalline silicon-germanium (poly-SiGe), metallic nitrides, metallic silicides, metallic oxides, or metals. In some embodiments, the dummy gate layer 104 may include a metal-containing material such as TiN, TaN, TaC, Co, Ru, Al, combinations thereof, or multi-layers thereof. The hard mask layer 105 may be made of a dielectric material such as silicon nitride (SiN), silicon oxide (SiO₂), silicon carbo-nitride (SiCN), silicon oxynitride (SiON), silicon oxy-carbon (SiOC), or the like, and may have a single-layer structure or a multi-layer structure including a plurality of dielectric layers. In some embodiments, the dummy gate layer 104 may be deposited by CVD, physical vapor deposition (PVD), sputter deposition, or other techniques suitable for depositing conductive materials. In some embodiments, the hard mask layer 105 may be deposited by CVD, physical vapor deposition (PVD), sputter deposition, or other techniques suitable for depositing conductive materials. In some embodiments, the dummy gate layer 105 can be interchangeably referred to a dummy gate, a dummy gate pattern, a dummy gate strip, an isolation structure, or a dielectric gate.

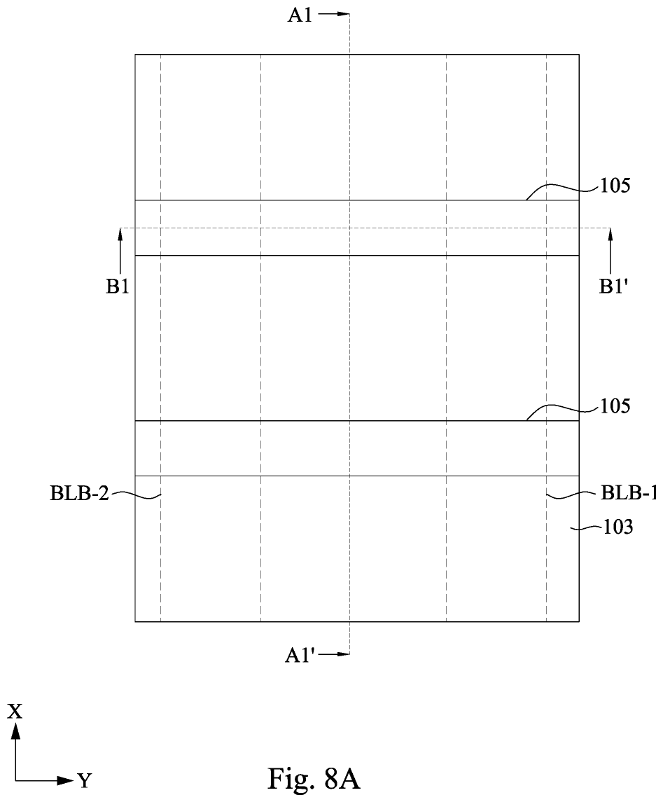

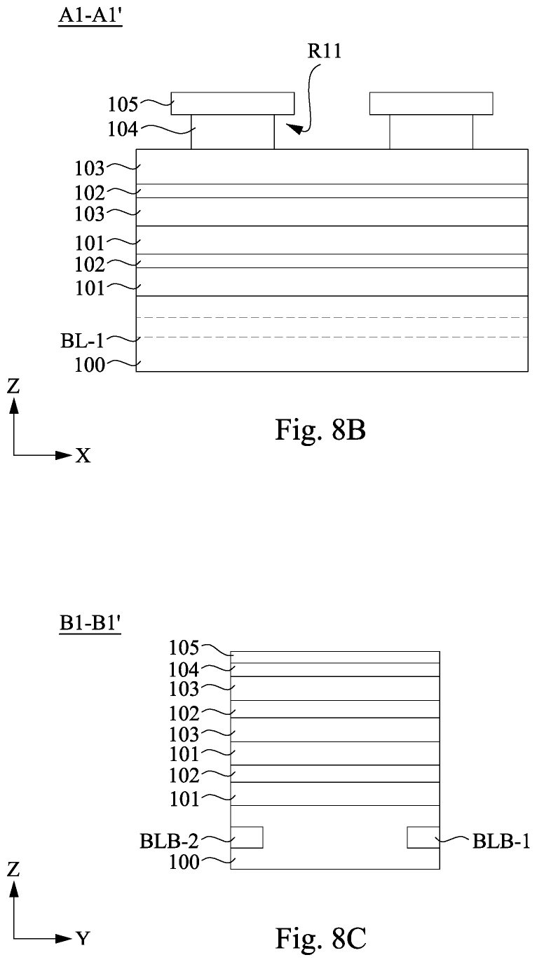

Reference is made to FIGS. 8A, 8B, and 8C. The dummy gate layer 104 is laterally or horizontally recessed by using suitable etch techniques, resulting in lateral recesses R11 vertically between the sacrificial layer 103 and the hard mask layer 105. This operation may be performed by using a selective etching process. By way of example and not limitation, the sacrificial layer 103 may be made of SiGe, the hard mask layer 105 may be made of a dielectric material and the dummy gate layer 104 may be made of silicon allowing for the selective etching of the dummy gate layer 104. In some embodiments, the selective dry etching etches Si at a faster etch rate than it etches Si and the dielectric material. As a result, the sacrificial layer 103 and the hard mask layer 105 laterally extend past opposite end surfaces of the dummy gate layer 104.

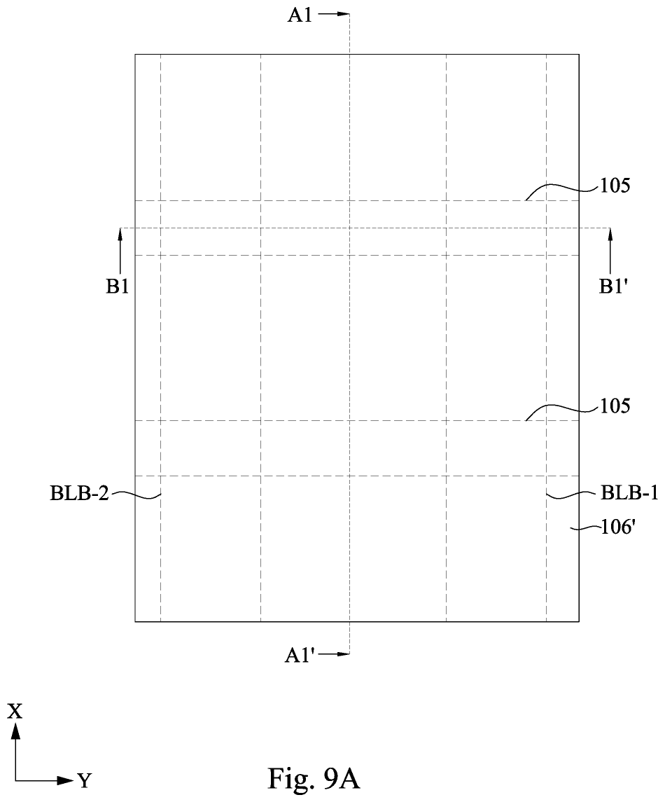

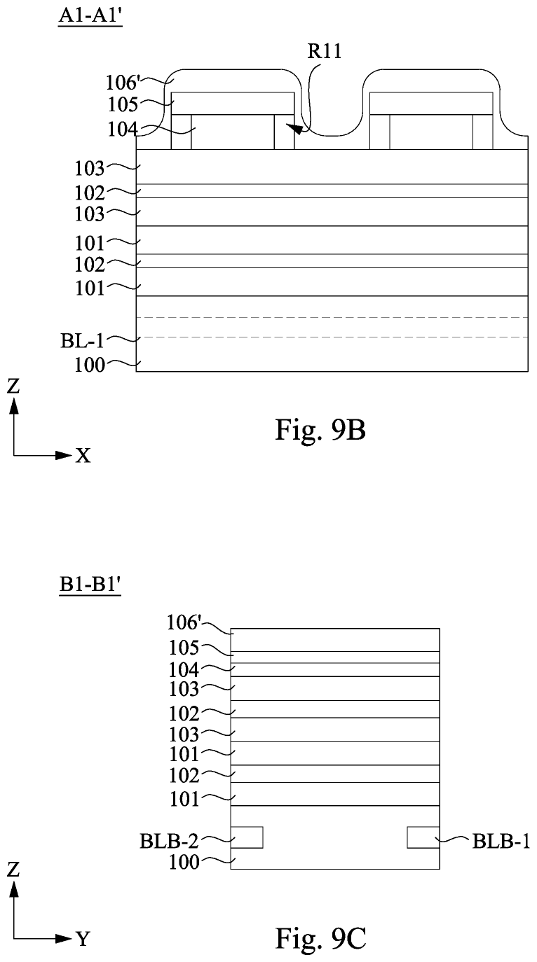

Reference is made to FIGS. 9A, 9B, and 9C. After recession of the dummy gate layer 104 is completed, a spacer material 106′ is deposited over the substrate 100. The spacer material 106′ may be a conformal layer on the topmost sacrificial layer 103, the dummy gate layers 104, and the hard mask layers 105. The spacer material 106′ may include a dielectric material such as silicon oxide, silicon nitride, silicon carbide, silicon oxynitride, SiCN films, silicon oxycarbide, SiOCN films, and/or combinations thereof. In some embodiments, the spacer material 106′ includes multiple layers, such as a first spacer layer and a second spacer layer formed over the first spacer layer. By way of example, the spacer material 106′ may be formed by depositing a dielectric material over the topmost sacrificial layer 103, the dummy gate layers 104, and the hard mask layers 105 using suitable deposition processes.

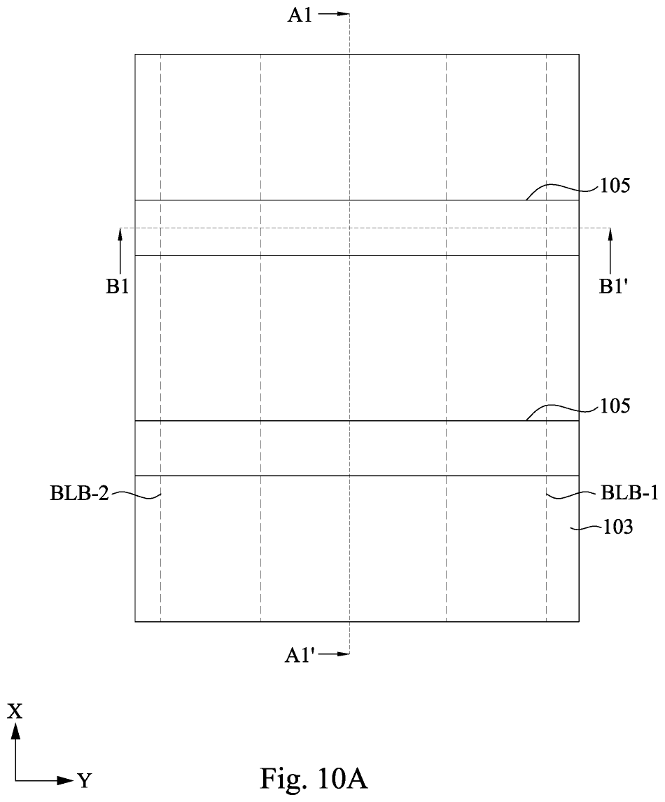

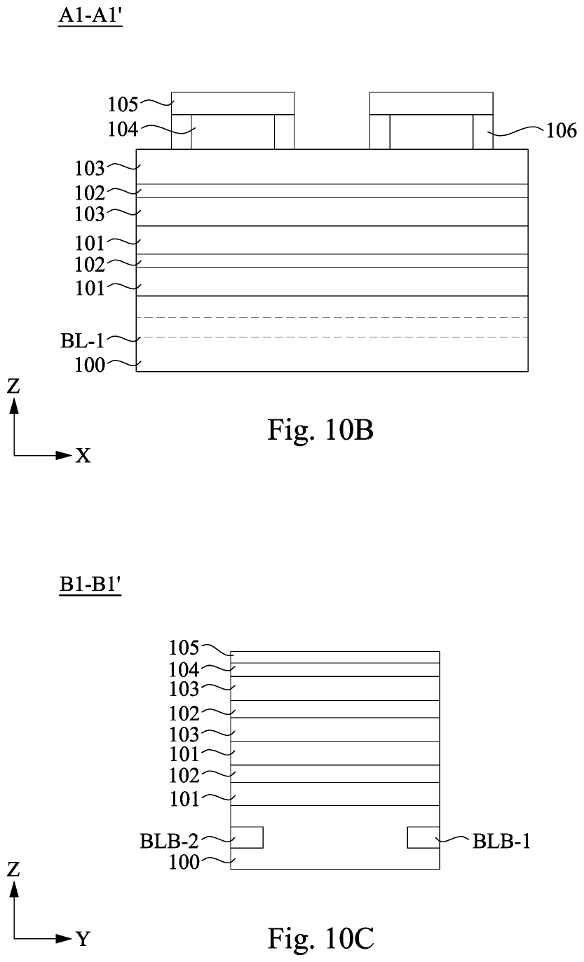

Reference is made to FIGS. 10A, 10B, and 10C. An anisotropic etching process is then performed on the deposited spacer material 106′ to expose the topmost sacrificial layer 103 and the hard mask layers 105. Portions of the spacer material 106′ directly on the hard mask layers 105 and on the topmost sacrificial layer 103 not covered by the hard mask layers 105 may be completely removed by this anisotropic etching process. Portions of the spacer material 106′ on sidewalls of the recessed dummy gate layer 104 may remain in the lateral recesses R11, forming gate sidewall spacers 106, which are denoted as the gate spacers 106.

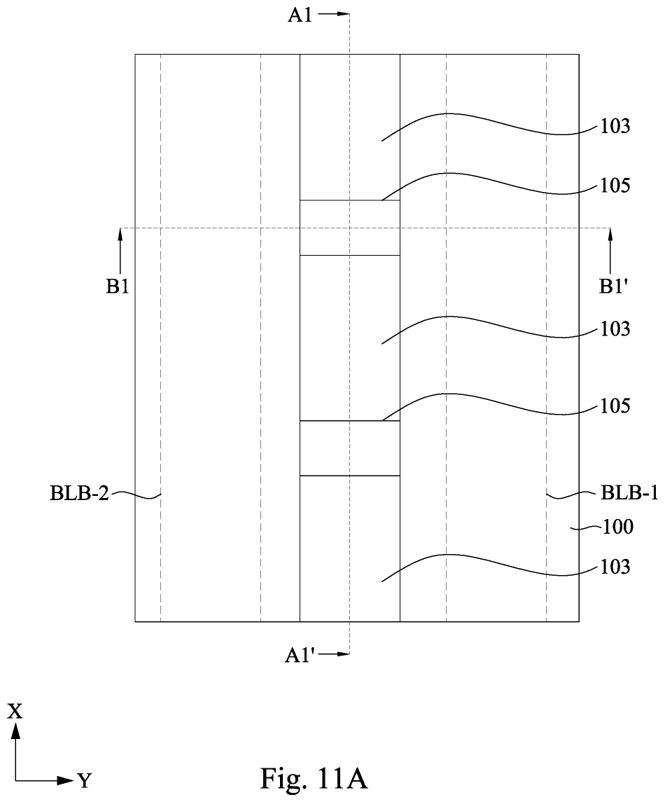

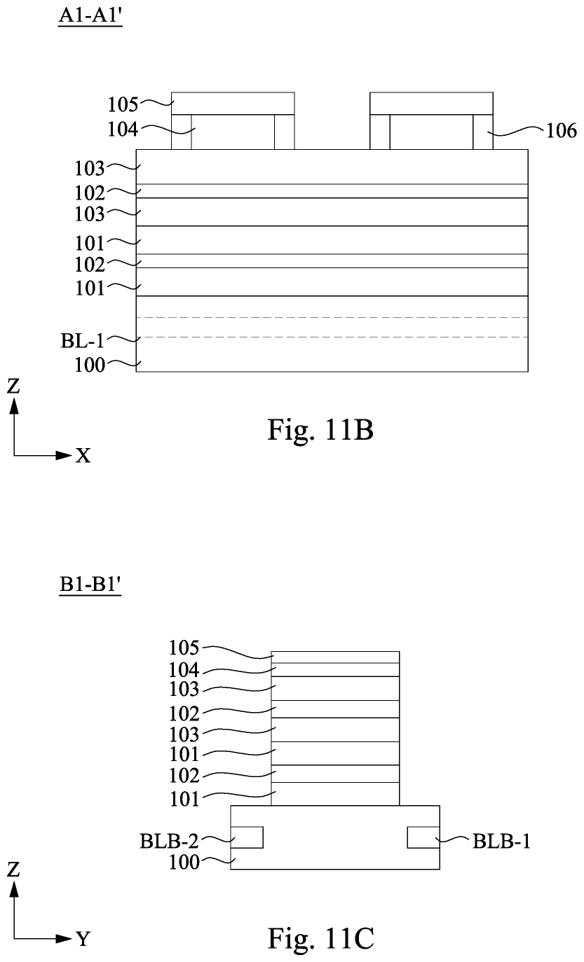

Reference is made to FIGS. 11A, 11B, and 11C. The epitaxial stack includes the channel layers 102 and the sacrificial layers 101 and 103 shown in FIGS. 10A-10C can be patterned, such that the channel layers 102 and the sacrificial layers 101 and 103 or portions thereof may be formed nanostructures. Specifically, the channel layers 102 may be formed nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The patterned channel layers 102 and the sacrificial layers 101 and 103 may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer can be formed over the substrate 100 and patterned using a photolithography process. Spacers are formed alongside the patterned sacrificial layer using a self-aligned process. The sacrificial layer is then removed. The etching process can include dry etching, wet etching, reactive ion etching (RIE), and/or other suitable processes.

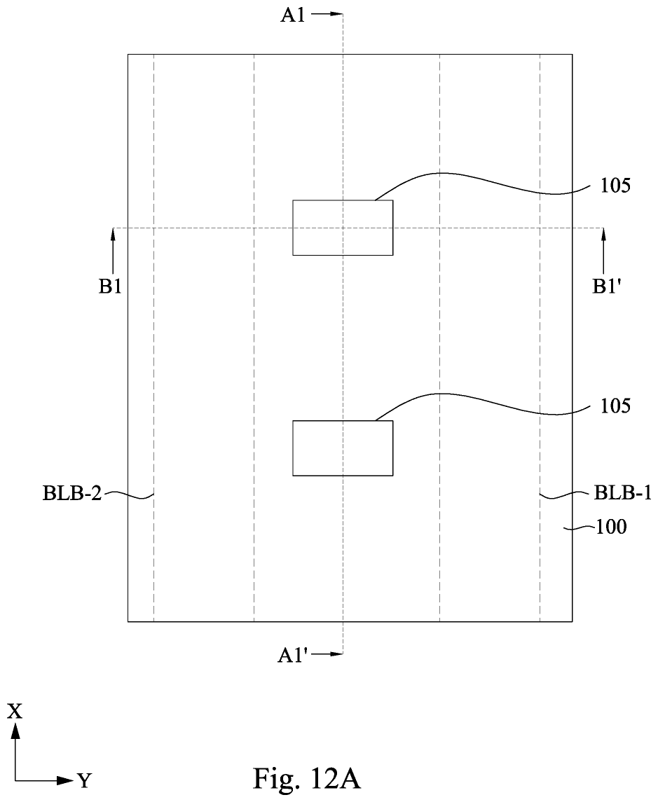

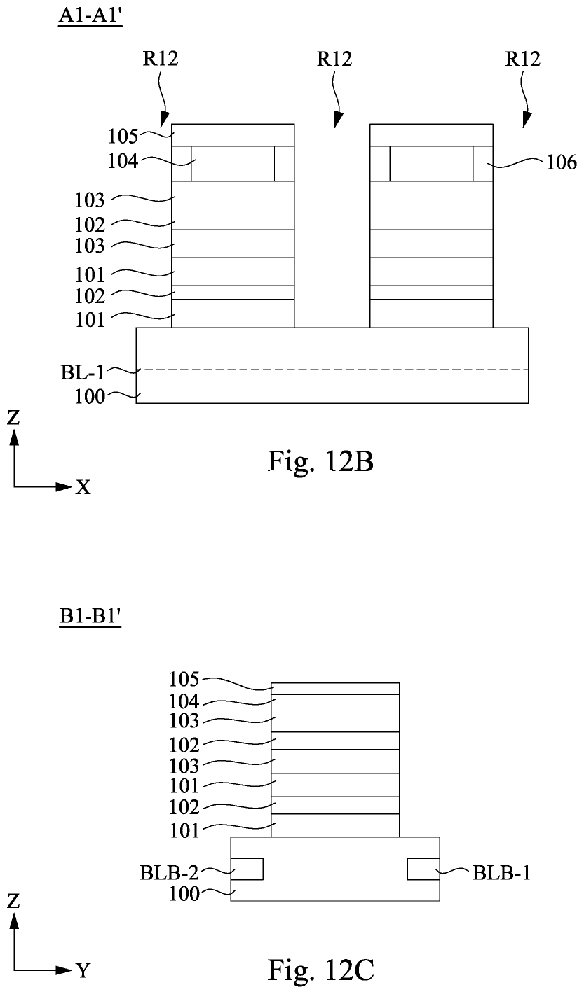

Reference is made to FIGS. 12A, 12B, and 12C. Exposed portions of the patterned channel layers 102 and the patterned sacrificial layers 101 and 103 that extend laterally beyond the gate spacers 106 are etched by using, for example, an anisotropic etching process that uses the dummy gate layer 104 and the gate spacers 106 as an etch mask, resulting in recesses R12 into the channel layers 102 and the sacrificial layers 101 and 103. After the anisotropic etching, end surfaces of the patterned channel layers 102 and the patterned sacrificial layers 101 and 103 and respective outermost sidewalls of the gate spacers 106 are substantially coterminous, due to the anisotropic etching. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

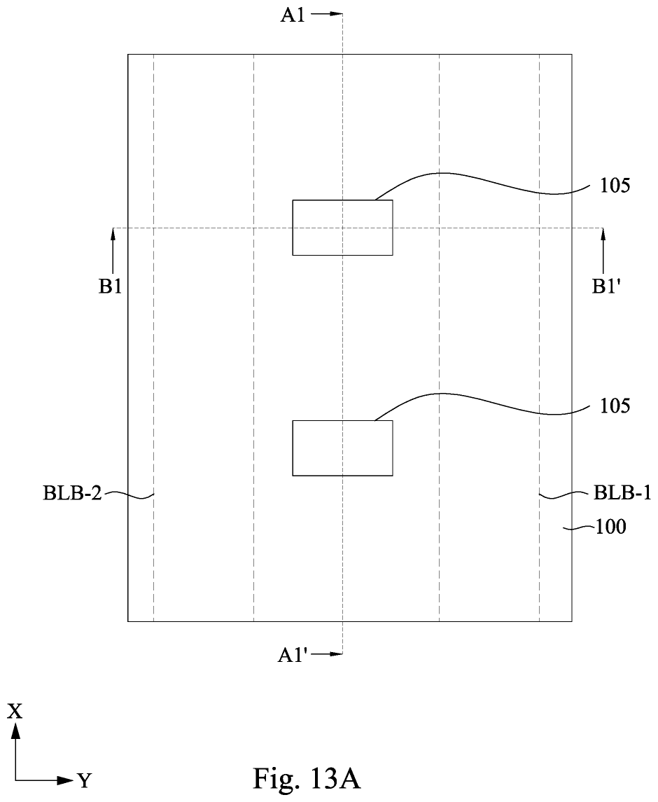

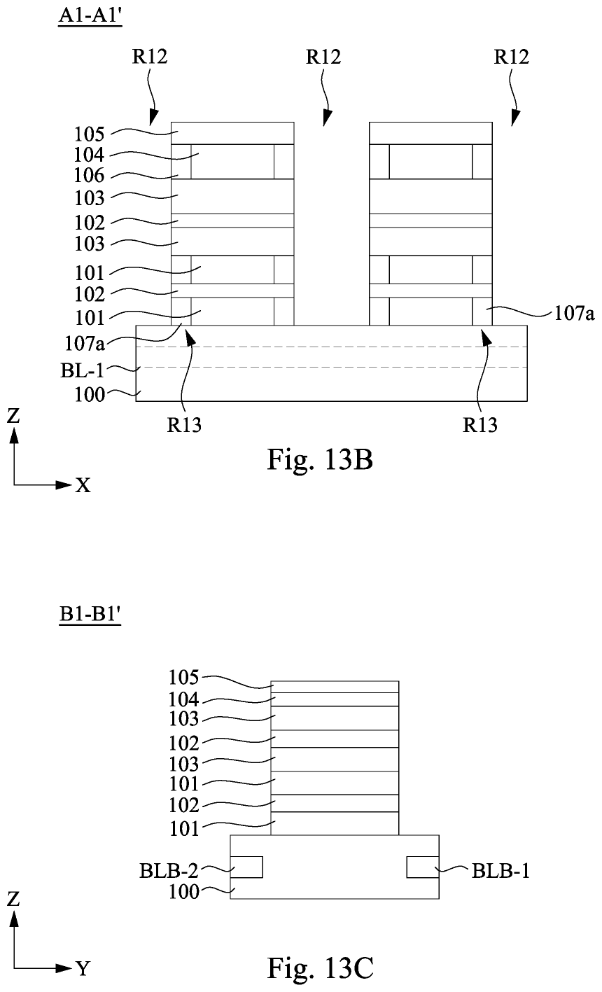

Reference is made to FIGS. 13A, 13B, and 13C. The patterned sacrificial layers 101 (see FIG. 13B) are laterally or horizontally recessed by using suitable etch techniques, resulting in lateral recesses R13 each vertically between corresponding channel layers 102. This operation may be performed by using a selective etching process. By way of example and not limitation, the sacrificial layers 101 can be made of SiGe and the channel layers 102 can be made of silicon allowing for the selective etching of the sacrificial layers 101. In some embodiments, the selective dry etching etches SiGe at a faster etch rate than it etches Si. As a result, the patterned channel layers 102 laterally extend past opposite end surfaces of the patterned sacrificial layers 101. In addition, since the sacrificial layers 101 (see FIGS. 13B and 13C) has a greater germanium atomic concentration than the sacrificial layers 103, the selective dry etching etches the sacrificial layers 101 at a faster etch rate than it etches the sacrificial layers 103, and thus the sacrificial layers 101 can be laterally or horizontally recessed while the sacrificial layers 103 can be only minimally consumed during an etching process.

Subsequently, inner spacers 107a are filled in the recesses R13 (see FIG. 13B), respectively. For example, spacer material layers are formed to fill the recesses R13 left by the lateral etching of the sacrificial layers 101 discussed above. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes. After the deposition of the spacer material layer, an anisotropic etching process may be performed to trim the deposited spacer material layer, such that portions of the deposited spacer material layer that fill the recesses R13 left by the lateral etching of the sacrificial layers 101 are left. After the trimming process, the remaining portions of the deposited spacer material are denoted as inner spacers 107a in the recesses R13. The inner spacers 107a serve to isolate metal gates from source/drain regions formed in subsequent processing.

Reference is made to FIGS. 14A, 14B, and 14C. Source/drain regions 108a are formed in the recesses R12 and connected to a lower one of the channel layers 102. The source/drain regions 108a may be formed by performing an epitaxial growth process that provides an epitaxial material on the substrate 100. During the epitaxial growth process, the dummy gate layer 104, gate spacers 106, and the inner spacers 107a limit the source/drain regions 108a to the substrate 100 and the channel layers 102. In some embodiments, the lattice constants of the source/drain regions 108a are different from the lattice constant of the channel layers 102, so that the channel layers 102 can be strained or stressed by the source/drain regions 108a to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the channel layers 102. In some embodiments, source/drain regions 108a may also be formed on an upper one of the channel layers 102. However, an etching process is performed to remove the source/drain regions 108a on the upper one of the channel layers 102, such that the upper one of the channel layers 102 can be exposed.

In some embodiments, the source/drain regions 108a may include Ge, Si, GaAs, AlGaAs, SiGe, GaAsP. SiP, or other suitable material. The source/drain regions 108a may be in-situ doped during the epitaxial process by introducing doping species including: p-type dopants, such as boron or BF₂; n-type dopants, such as phosphorus or arsenic; and/or other suitable dopants including combinations thereof. If the source/drain regions 108a are not in-situ doped, an implantation process (i.e., a junction implant process) is performed to dope the source/drain regions 108a. In some exemplary embodiments, the source/drain regions 108a in a p-type include SiGeB and/or GeSnB. In some embodiments, the source/drain regions 108a can be interchangeably referred to as a source/drain pattern, an epitaxial pattern, a source/drain structure, or an epitaxial structure.

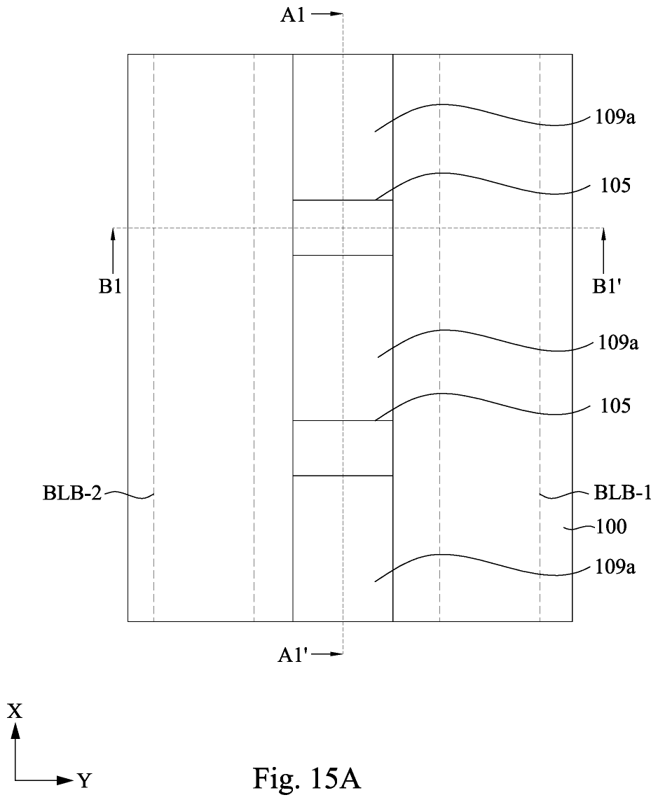

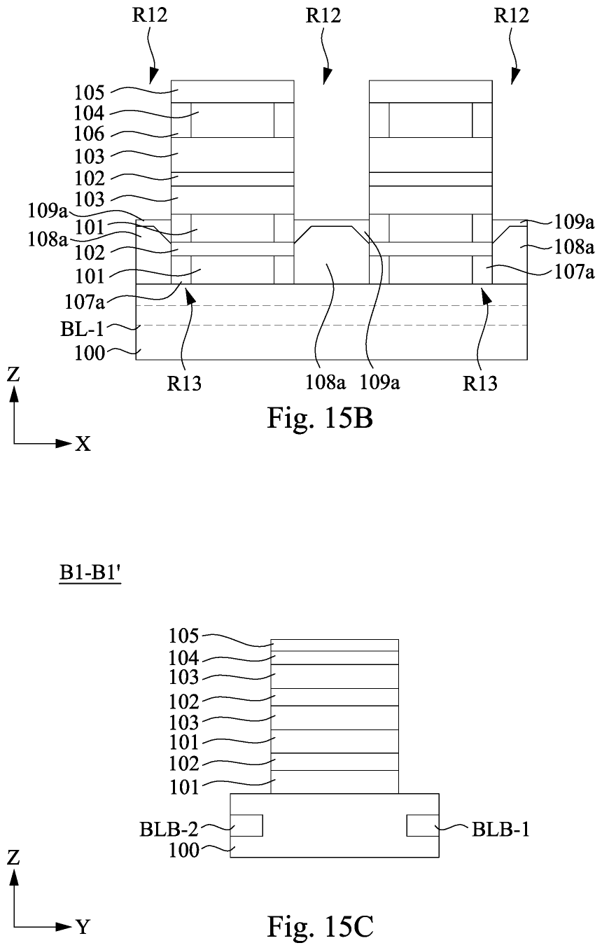

Reference is made to FIGS. 15A, 15B, and 15C. Source/drain contacts 109a (see FIGS. 15A and 15B) can be formed over the source/drain regions 108a. In some embodiments, the source/drain contacts 109a may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, other suitable materials, or combinations thereof. In some embodiments, the formation of the source/drain contacts 109a can be performed by such as a lift-off process. By way of example and not limitation, a mask layer (not shown) can be formed by depositing a photoresist layer over the substrate 100 by suitable process, such as spin-coating technique, which may include baking the photoresist layer after coating. In some embodiments, the mask layer may include a photoresist material including positive-type or negative-type resist materials. The mask layer can be patterned to form openings exposing the source/drain contacts 109a. Subsequently, a contact material can be deposited over the substrate 100 and formed on the source/drain contacts 109a and on the patterned mask layer. Subsequently, the substrate 100 can be immersed into a tank of appropriate solvent that will react with the patterned mask layer. The patterned mask layer may swell, dissolve, and lift off the contact material formed on the patterned mask layer, portions of the contact material on the source/drain regions 108a are remained to form the source/drain contacts 109a.

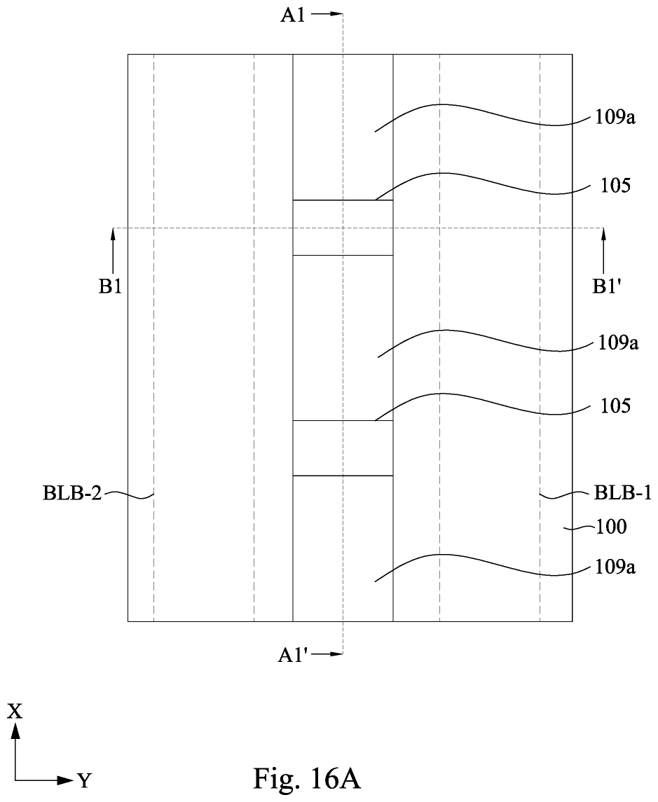

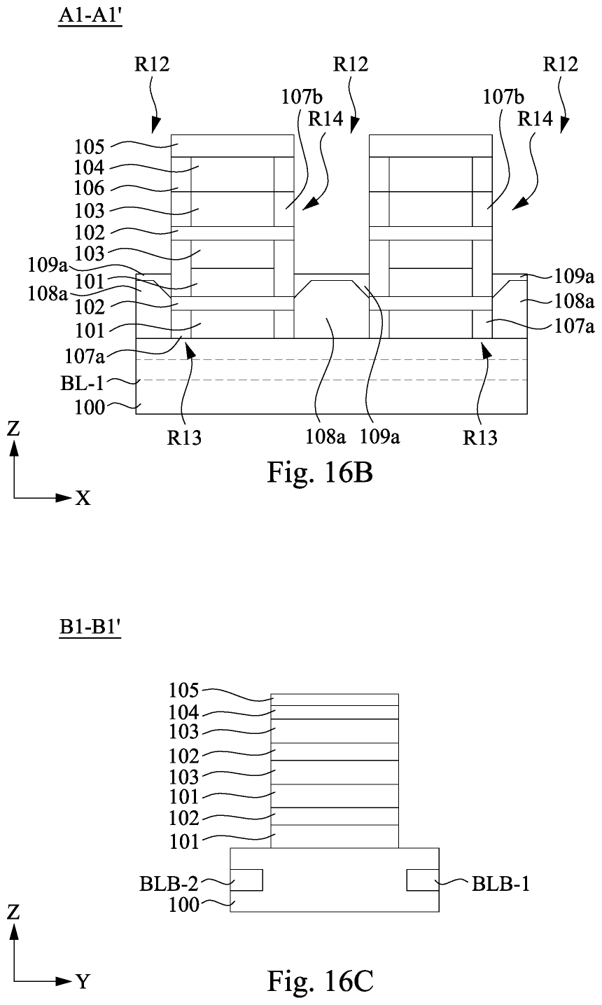

Reference is made to FIGS. 16A, 16B, and 16C. The sacrificial layers 103 (see FIG. 16B) are laterally or horizontally recessed by using suitable etch techniques, resulting in lateral recesses R14 each vertically between corresponding channel layers 102. This operation may be performed by using a selective etching process. By way of example and not limitation, the sacrificial layers 101 can be made of SiGe and the channel layers 102 can be made of silicon allowing for the selective etching of the sacrificial layers 101. In some embodiments, the selective dry etching etches SiGe at a faster etch rate than it etches Si. As a result, the patterned channel layers 102 laterally extend past opposite end surfaces of the patterned sacrificial layers 103.

Subsequently, inner spacers 107b are filled in the recesses R14 (see FIG. 16B), respectively. For example, spacer material layers are formed to fill the recesses R14 left by the lateral etching of the sacrificial layers 103 discussed above. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes. After the deposition of the spacer material layer, an anisotropic etching process may be performed to trim the deposited spacer material layer, such that portions of the deposited spacer material layer that fill the recesses R14 left by the lateral etching of the sacrificial layers 103 are left. After the trimming process, the remaining portions of the deposited spacer material are denoted as inner spacers 107b in the recesses R14. The inner spacers 107b serve to isolate metal gates from source/drain regions formed in subsequent processing.

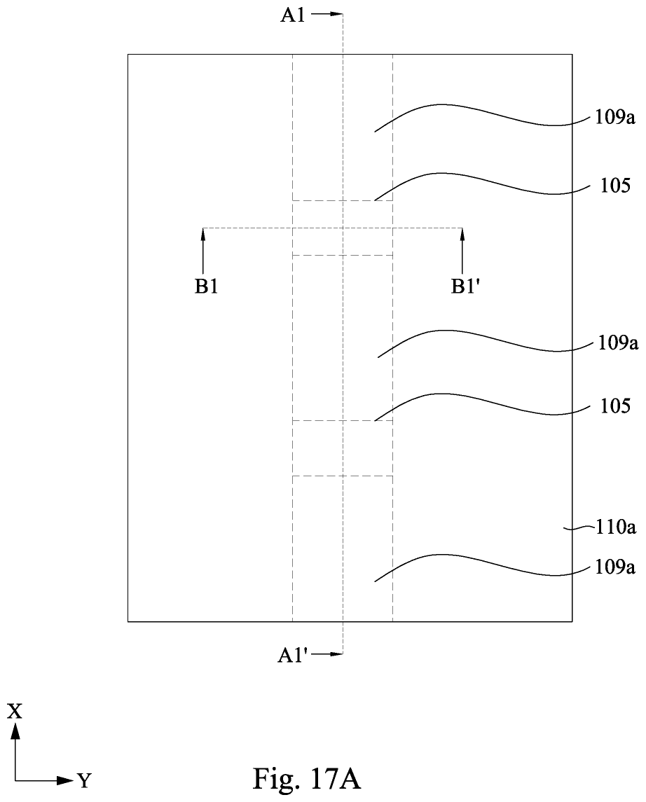

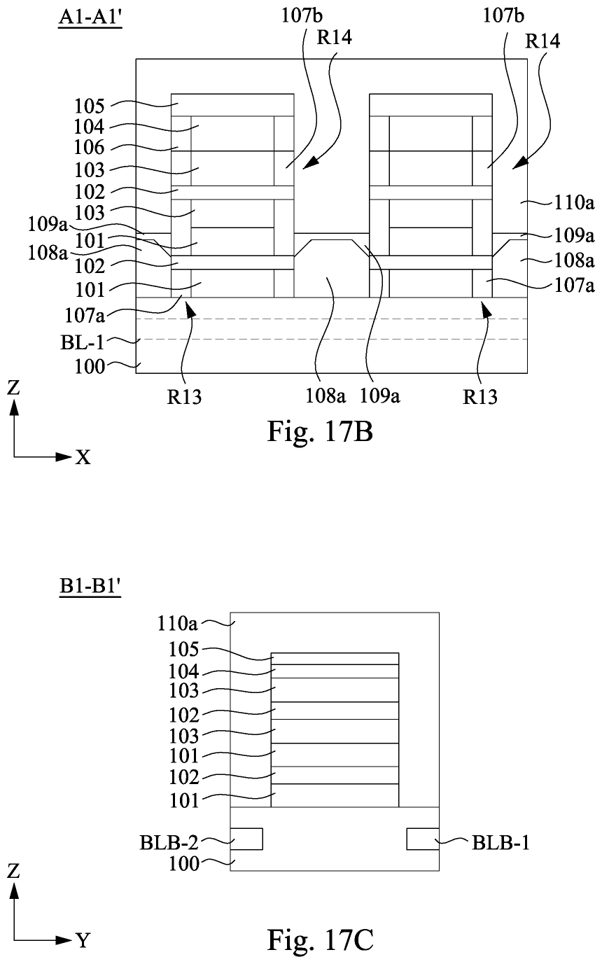

Reference is made to FIGS. 17A, 17B, and 17C. An interlayer dielectric (ILD) layer 110a is formed over the substrate 100. In some embodiments, the ILD layer 110a includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the ILD layer 110a may be deposited by a plasma-enhanced chemical vapor deposition (PECVD) process or other suitable deposition technique. In some embodiments, after formation of the ILD layer 110a, the substrate 100 may be subject to a high thermal budget process to anneal the ILD layer 110a.

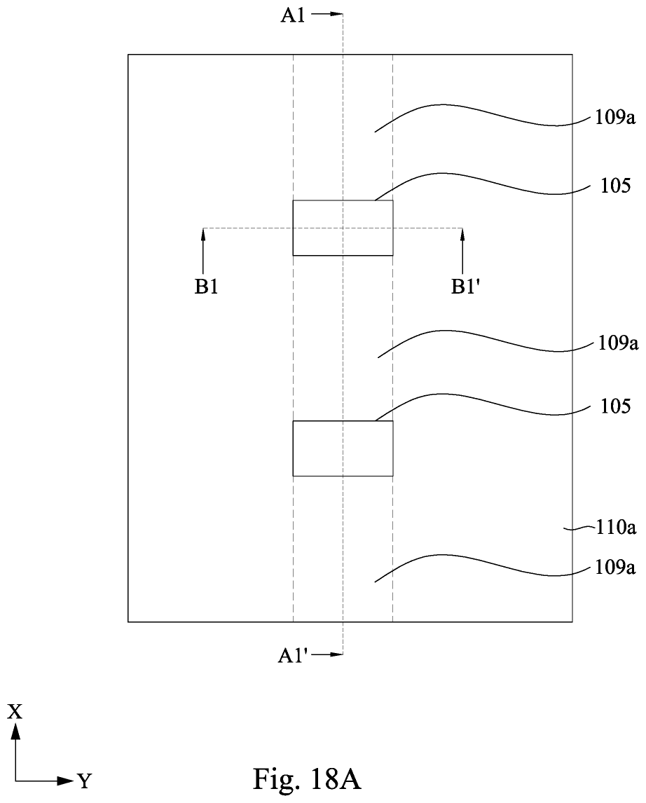

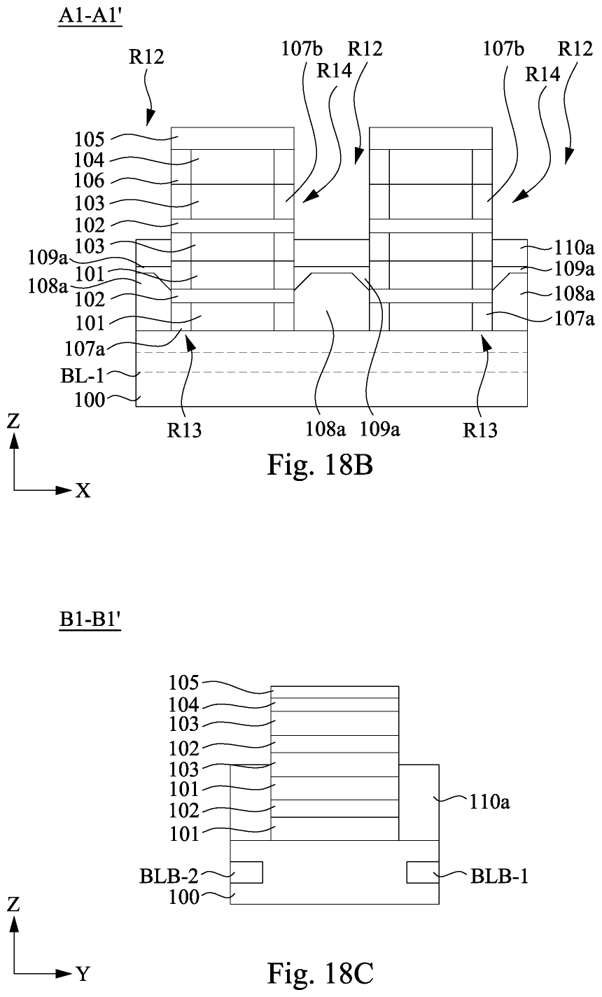

Reference is made to FIGS. 18A, 18B, and 18C. After depositing of the ILD layer 110a, a planarization process may be performed to remove excessive materials of the ILD layer 110a. For example, a planarization process includes a chemical mechanical planarization (CMP) process which removes portions of the ILD layer 110a overlying the hard mask layer 105. Subsequently, the ILD layer 110a can be recessed, such that the upper portions of the recesses R12 may reappear. The etching may be performed using a dry etching process, wherein NH₃ and NF₃ are used as the etching gases. During the etching process, plasma may be generated. Argon may also be included. In accordance with alternative embodiments of the present disclosure, the recessing of the ILD layer 110a can be performed by using a wet etch process. In some embodiments, the etching chemical may include diluted HF, for example.

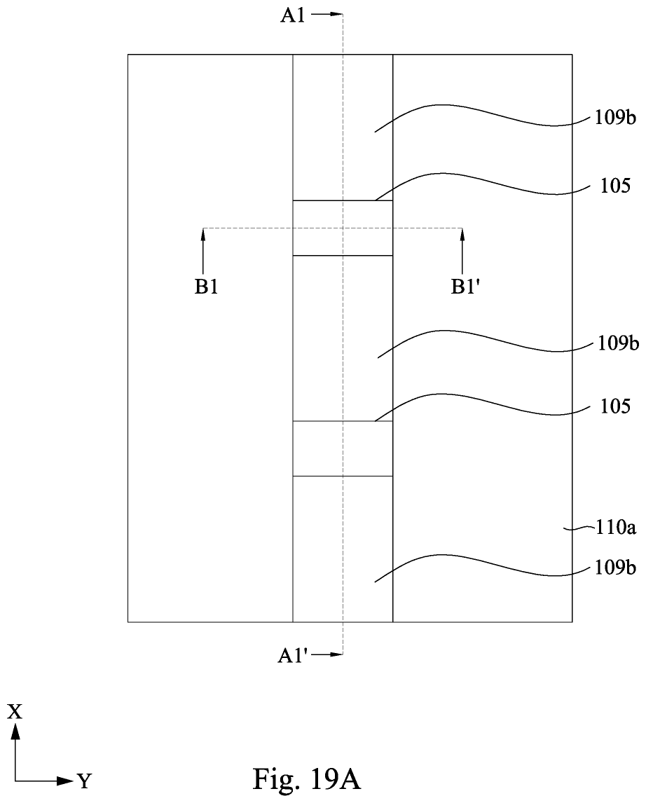

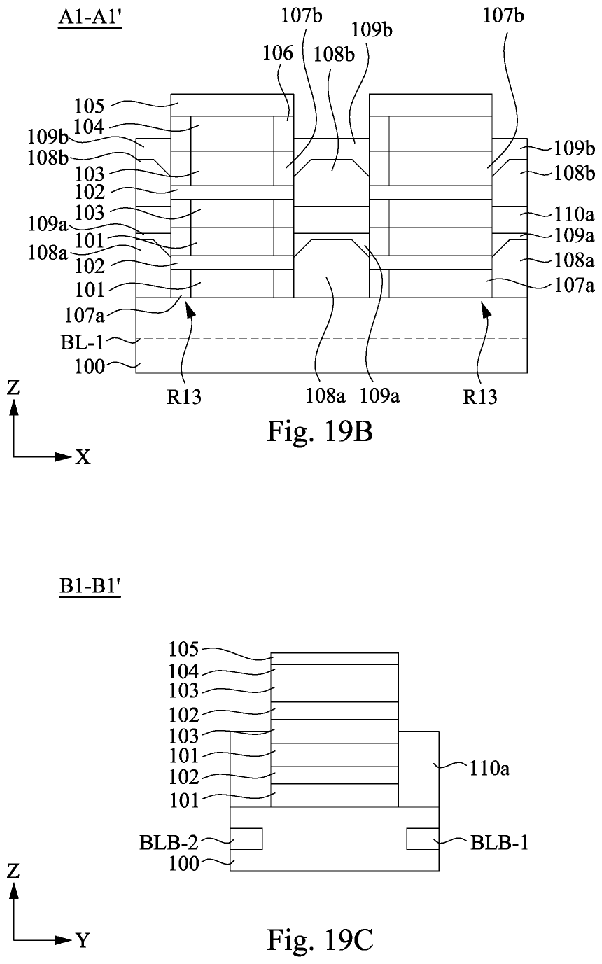

Reference is made to FIGS. 19A, 19B, and 19C. Source/drain regions 108b are formed over the ILD layer 110a. The source/drain regions 108b may be formed by performing an epitaxial growth process that provides an epitaxial material on the ILD layer 110a. During the epitaxial growth process, the dummy gate layer 104, the gate spacers 106, and the inner spacers 107b limit the source/drain regions 108b to the channel layer 102. In some embodiments, the lattice constants of the source/drain regions 108b are different from the lattice constant of the channel layer 102, so that the channel layer 102 can be strained or stressed by the source/drain regions 108b to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the channel layer 102.

In some embodiments, the source/drain regions 108b may include Ge, Si, GaAs, AlGaAs, SiGe, GaAsP, SiP, or other suitable material. The source/drain regions 108b may be in-situ doped during the epitaxial process by introducing doping species including: p-type dopants, such as boron or BF₂; n-type dopants, such as phosphorus or arsenic; and/or other suitable dopants including combinations thereof. If the source/drain regions 108b are not in-situ doped, an implantation process (i.e., a junction implant process) is performed to dope the source/drain regions 108b. In some embodiments, the source/drain regions 108b can be in an n-type transistor and include SiP. In some embodiments, the source/drain regions 108a and the source/drain regions 108b can be made of different materials. For example, the source/drain regions 108a can be made of SiGeB, and the source/drain regions 108b can be made of SiP. In some embodiments, the source/drain regions 108b can be interchangeably referred to as a source/drain pattern, an epitaxial pattern, a source/drain structure, or an epitaxial structure. Each of the ILD layer 110a is between the source/drain regions 108a and 108b to electrically isolate the source/drain region 108b from the source/drain region 108a.

Subsequently, source/drain contacts 109b (see FIGS. 19A and 19B) can be formed over the source/drain regions 108b. In some embodiments, the source/drain contacts 109a may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, other suitable materials, or combinations thereof. In some embodiments, the formation of the source/drain contacts 109a can be performed by such as a lift-off process. By way of example and not limitation, a mask layer (not shown) can be formed by depositing a photoresist layer over the substrate 100 by suitable process, such as spin-coating technique, which may include baking the photoresist layer after coating. In some embodiments, the mask layer may include a photoresist material including positive-type or negative-type resist materials. The mask layer can be patterned to form openings exposing the source/drain contacts 109b. Subsequently, a contact material can be deposited over the substrate 100 and formed on the source/drain contacts 109b and on the patterned mask layer. Subsequently, the substrate 100 can be immersed into a tank of appropriate solvent that will react with the patterned mask layer. The patterned mask layer may swell, dissolve, and lift off the contact material formed on the patterned mask layer, portions of the contact material on the source/drain regions 108b are remained to form the source/drain contacts 109b.

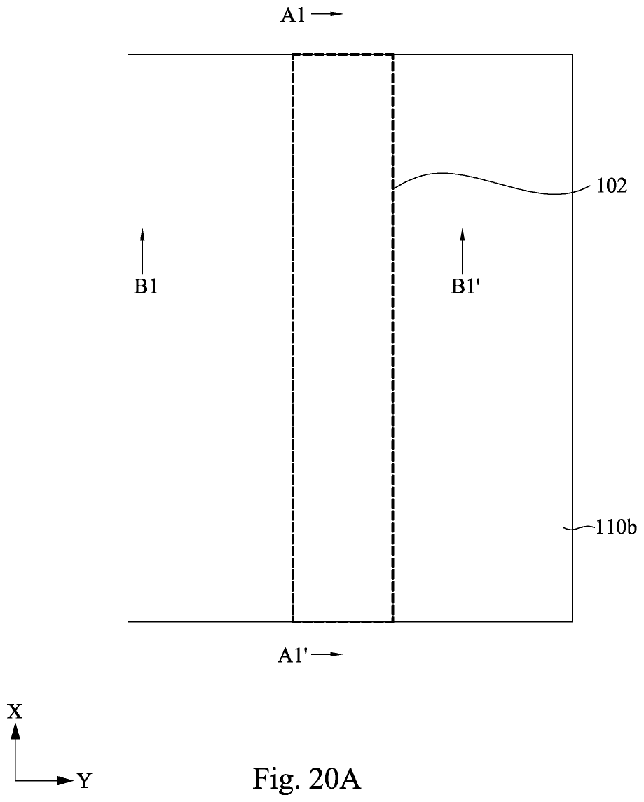

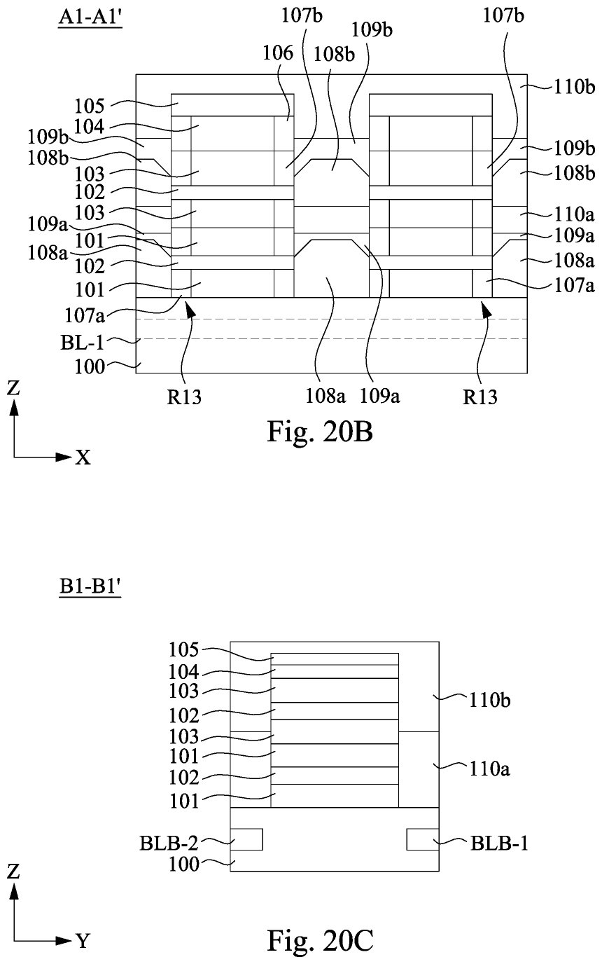

Reference is made to FIGS. 20A, 20B, and 20C. An ILD layer 110b is formed over the substrate 100. In some embodiments, the ILD layer 110a includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the ILD layer 110b may be deposited by a plasma-enhanced chemical vapor deposition (PECVD) process or other suitable deposition technique. In some embodiments, after formation of the ILD layer 110a, the substrate 100 may be subject to a high thermal budget process to anneal the ILD layer 110b.

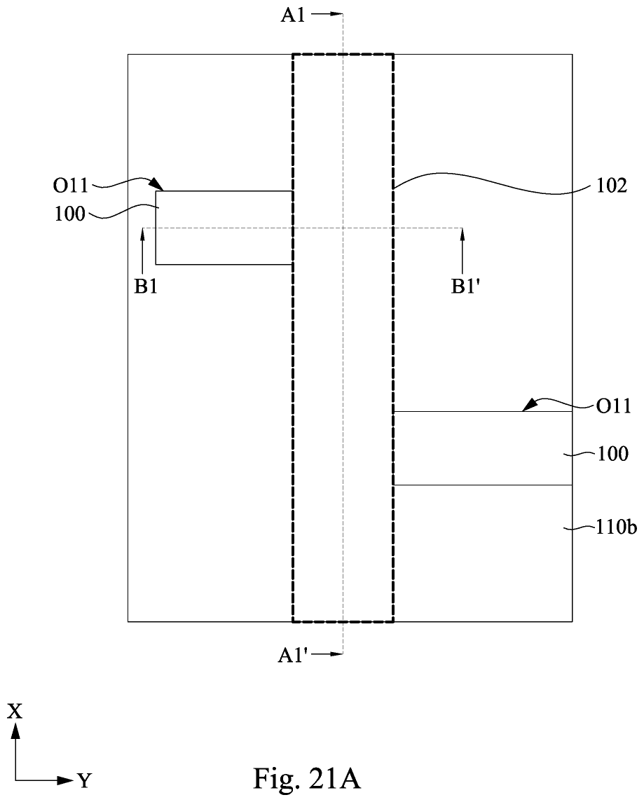

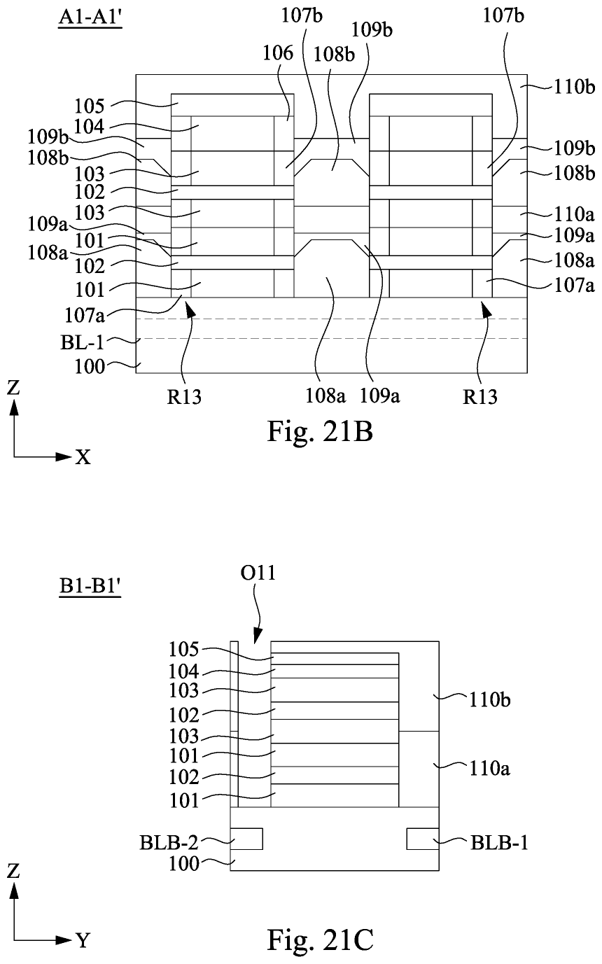

Reference is made to FIGS. 21A, 21B, and 21C. An opening O11 is formed to extend through the ILD layers 110a and 110b to expose a first sidewall of the epitaxial stack, such that the channel layer 102 and the sacrificial layers 101 and 103 can be exposed from the opening O11. For example, a patterned mask (not shown) may be formed over the ILD layer 110b and used to etch the ILD layers 110a and 110b to form the opening O11 that extends through the ILD layers 110a and 110b by using photolithography and etching techniques to expose a first sidewall of the sacrificial multi-layer stack. The lithography process may include photoresist (or resist) coating (e.g., spin-on coating), soft baking, mask aligning, exposure, post-exposure baking, developing the photoresist, rinsing, drying (e.g., hard baking), other suitable processes, and/or combinations thereof. The etching process includes dry etching, wet etching, and/or other etching methods (e.g., reactive ion etching). In some embodiments, the opening O11 may have a rectangular profile extending along Y-direction from the top view. After the formation of the opening O11, the patterned mask can be removed by a suitable technique, such as a wet clean process, an ashing process, or the like.

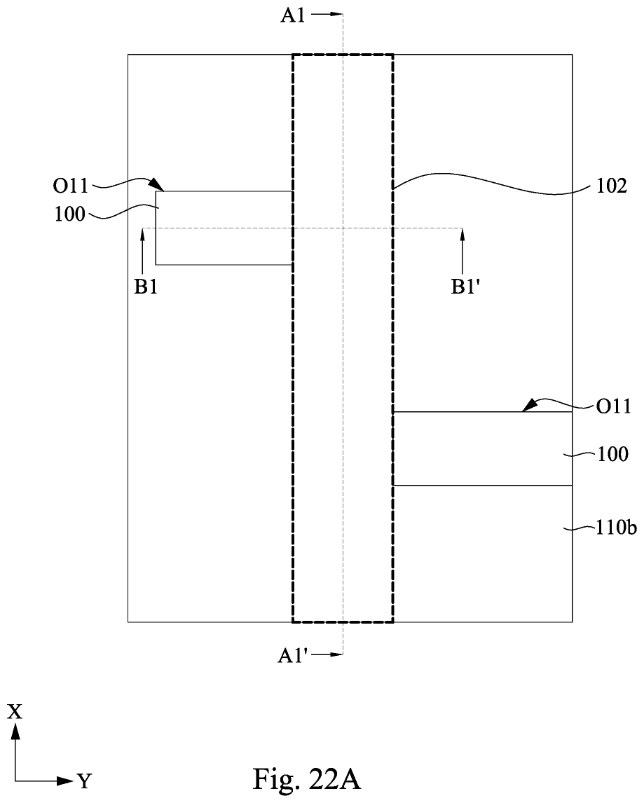

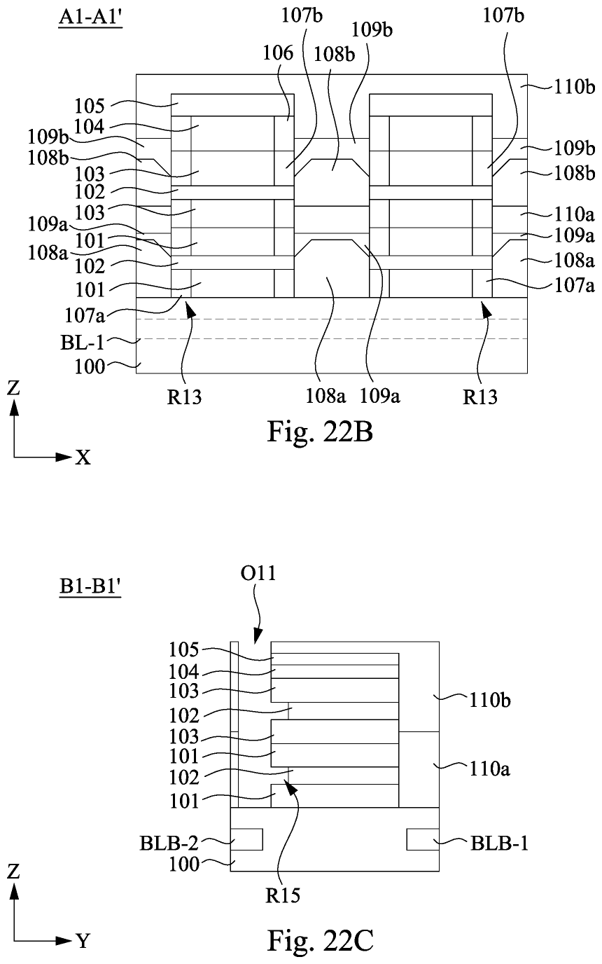

Reference is made to FIGS. 22A, 22B, and 22C. The channel layer 102 (see FIG. 22C) are laterally or horizontally recessed by using suitable etch techniques through the opening O11, resulting in lateral recesses R15 each vertically between corresponding sacrificial layers 101 and 103. This operation may be performed by using a selective etching process. By way of example and not limitation, the channel layers 102 can be made of Si and the sacrificial layers 101 and 103 can be made of SiGe allowing for the selective etching of the channel layers 102. In some embodiments, the selective dry etching etches Si at a faster etch rate than it etches SiGe.

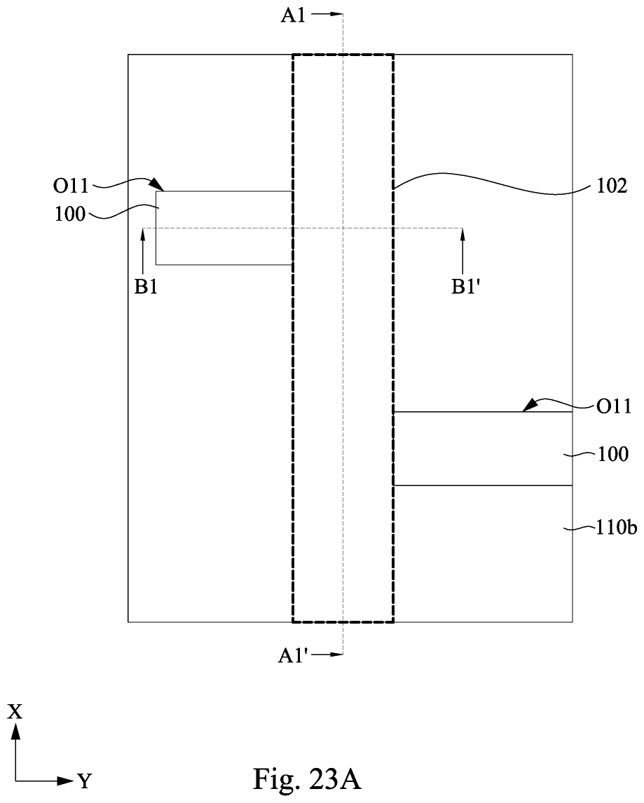

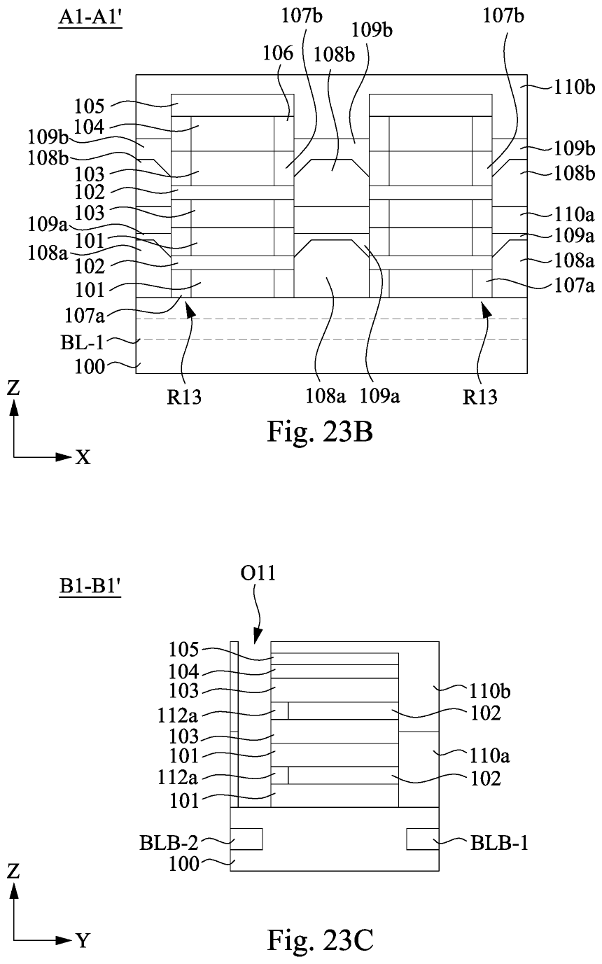

Reference is made to FIGS. 23A, 23B, and 23C. Channel sidewall spacers 112a can be filled in the recesses R15 (see FIG. 23C), respectively. For example, spacer material layers are formed to fill the recesses R15 left by the lateral etching of the channel layers 102 discussed above. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes. After the deposition of the spacer material layer, an anisotropic etching process may be performed to trim the deposited spacer material layer, such that portions of the deposited spacer material layer that fill the recesses R15 left by the lateral etching of the sacrificial layer 101 are left. After the trimming process, the remaining portions of the deposited spacer material are denoted as channel sidewall spacer 112a in the recesses R15.

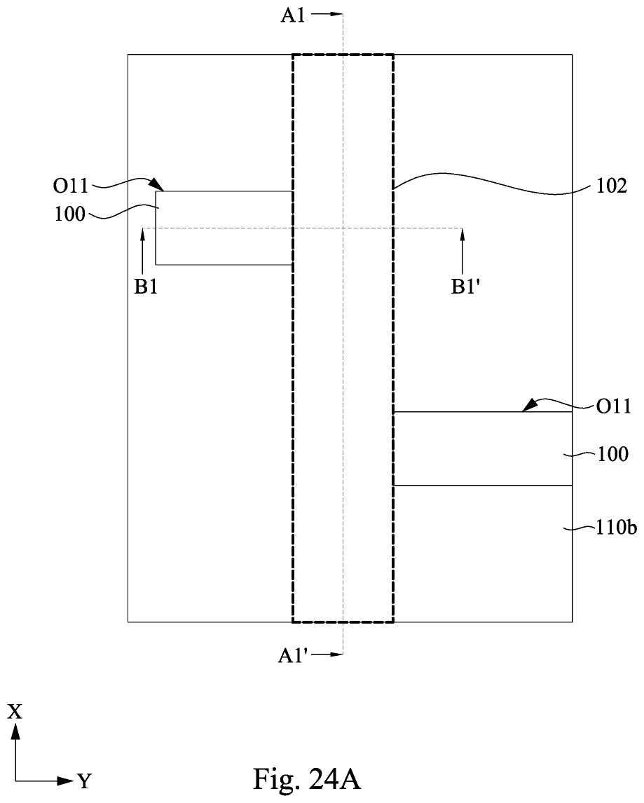

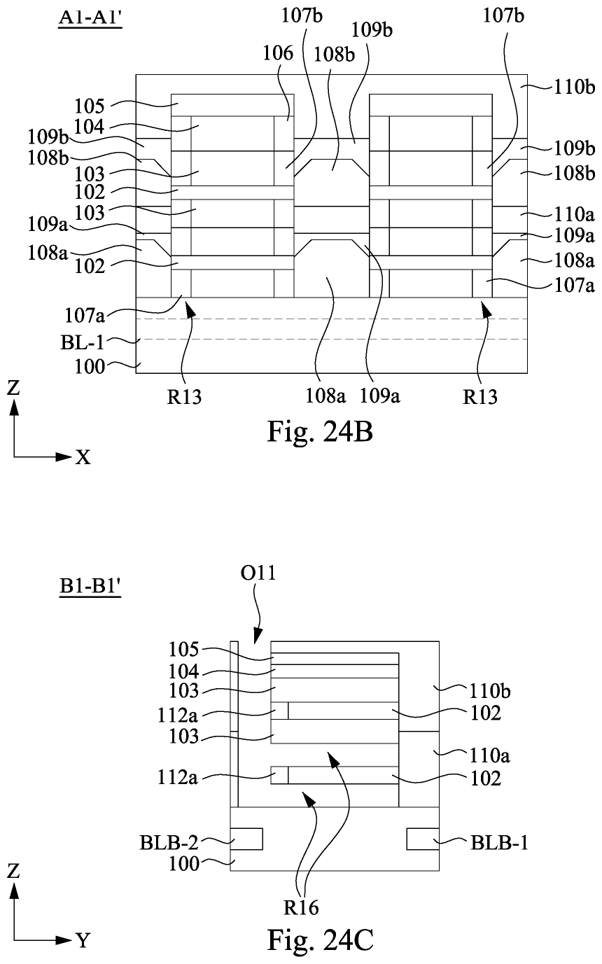

Reference is made to FIGS. 24A, 24B, and 24C. The sacrificial layers 101 (see FIGS. 24B and 24C) are removed in one or more etching process through the opening O11, so that the recesses R16 are formed to inherit the shapes of the sacrificial layers 101. The recesses R16 can expose top and bottom surfaces of the lower one of the channel layers 102. In some embodiments, the sacrificial layers 101 can be removed by an anisotropic dry etch process. For example, the etching process may include a dry etch process using reaction gas(es) that selectively etch the sacrificial layers 101 at faster rates than the substrate 100, the ILD layers 110a and 110b, the channel sidewall spacer 112a, and the sacrificial layers 103. In some embodiments, the sacrificial layers 101 and 103 can be made of silicon germanium, and the sacrificial layers 101 can have a higher germanium atomic concentration than the sacrificial layers 103.

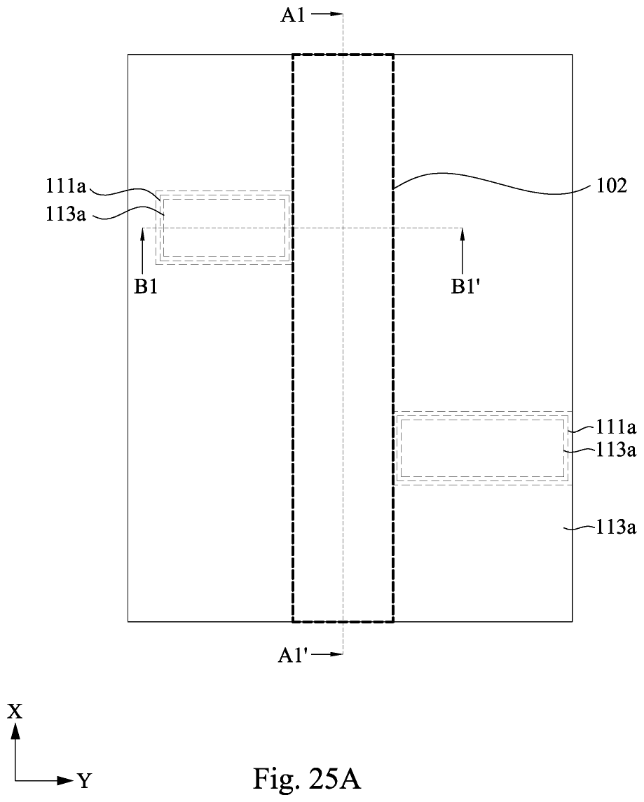

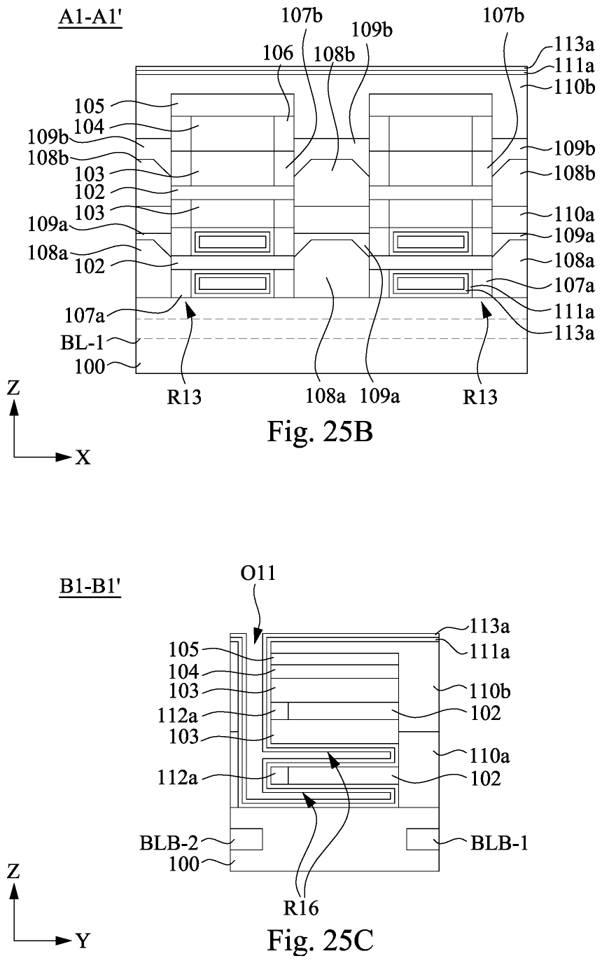

Reference is made to FIGS. 25A, 25B, and 25C. An interfacial layer 111a and a high-k dielectric layer 113a can be conformally formed over the ILD layers 110a and 110b and in the opening O11 and the recesses R16. In some embodiments, the interfacial layer of the gate dielectric layer 111a may include a dielectric material such as silicon oxide (SiO₂), HfSiO, or silicon oxynitride (SiON). In some embodiments, the interfacial layer 111a may be deposited using any suitable method, such as CVD, physical vapor deposition (PVD), ALD, PEALD, PECVD, SACVD, FCVD, spin-on, and/or the like, or a combination thereof.

In some embodiments, the high-k dielectric layer 113a may include high-k dielectric material, such as hafnium oxide (HfO₂). hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. In some embodiments, the high-k dielectric layer 113a may be deposited using any suitable method, such as CVD, physical vapor deposition (PVD), ALD, PEALD, PECVD, SACVD, FCVD, spin-on, and/or the like, or a combination thereof.

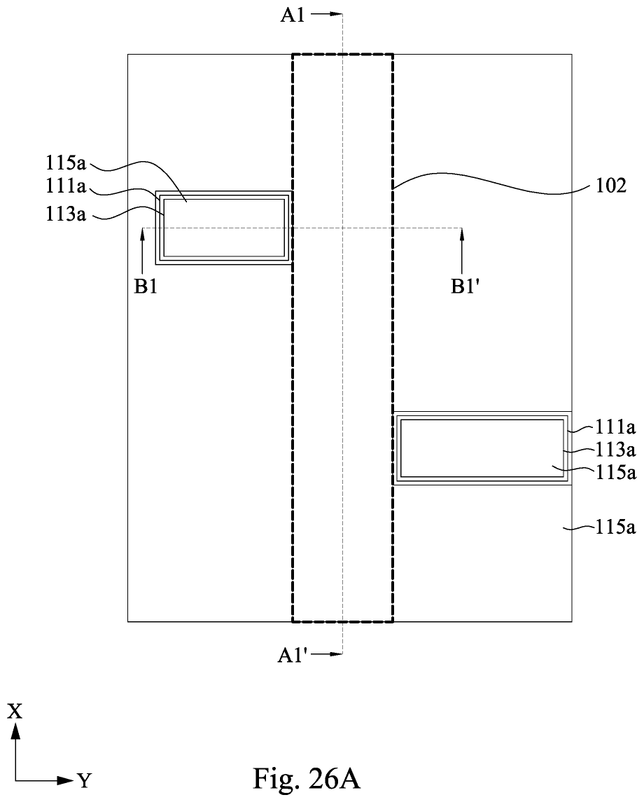

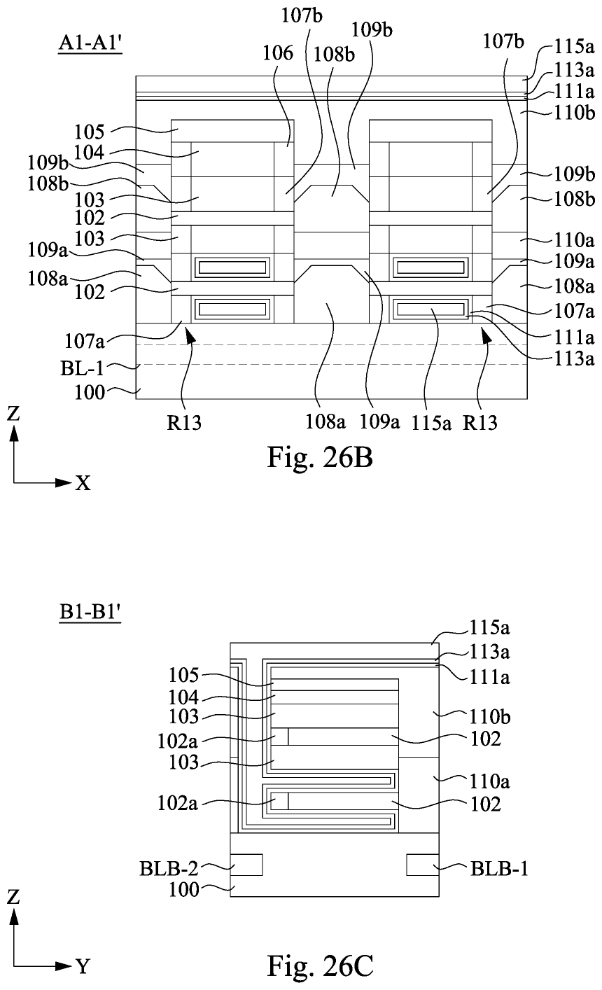

Reference is made to FIGS. 26A, 26B, and 26C. A gate electrode layer 115a can be conformally formed over the high-k dielectric layer 113a. The gate electrode layer 115a may include a work function metal layer and/or a fill metal formed around the work function metal layer. The work function metal layer and/or the fill metal may include a metal, metal alloy, or metal silicide. For an n-type FinFET, the work function metal layer may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TIC), aluminum carbide (AIC)), aluminides, and/or other suitable materials. On the other hand, for a p-type FinFET, the work function metal layer may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

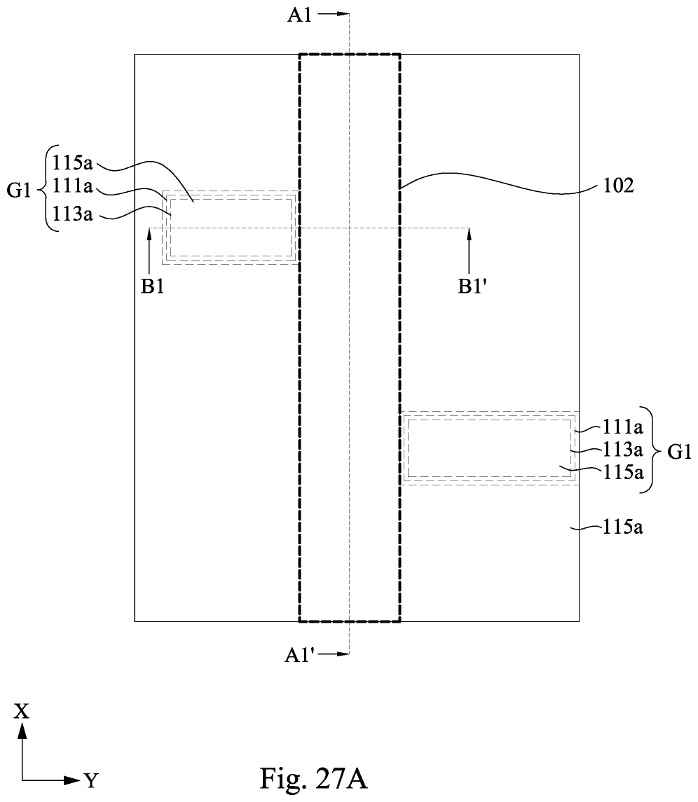

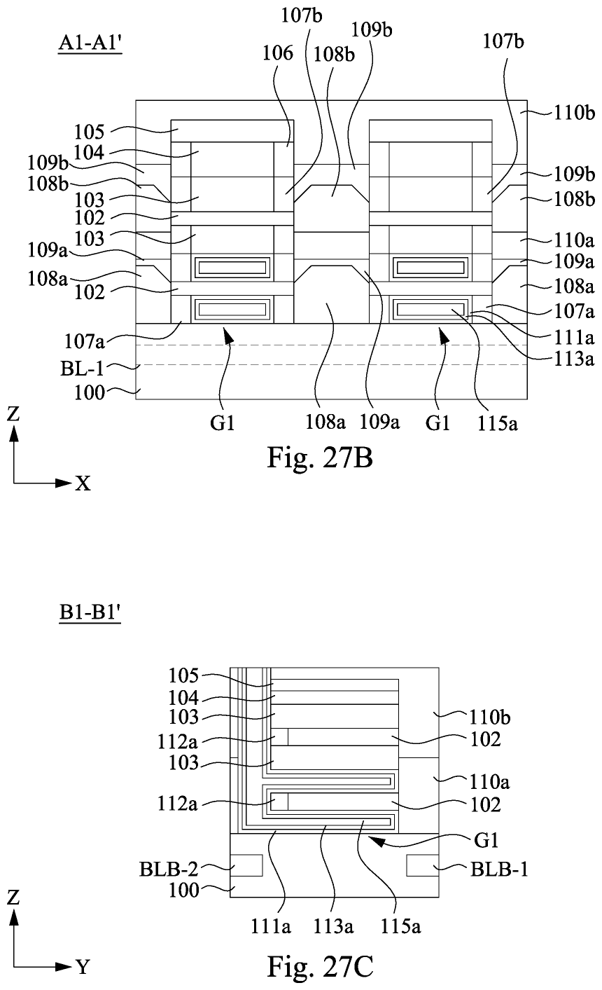

Reference is made to FIGS. 27A, 27B, and 27C. A planarization process (e.g., CMP) is performed to remove the excessive gate electrode layer 115a, the high-k dielectric layer 113a, and the interfacial layer 111a above the ILD layer 110b. The ILD layer 110b may also act as an etch stop layer for etching the gate electrode layer 115a, the high-k dielectric layer 113a, and the interfacial layer 111a. Therefore, a (metal) gate structure G1 including the gate electrode layer 115a, the high-k dielectric layer 113a, and the interfacial layer 111a can be formed in the recesses R16 to surround each of the lower one of the channel layers 102 suspended in the recesses R16. In some embodiments, the gate structure G1 may be the final gate of a GAA FET.

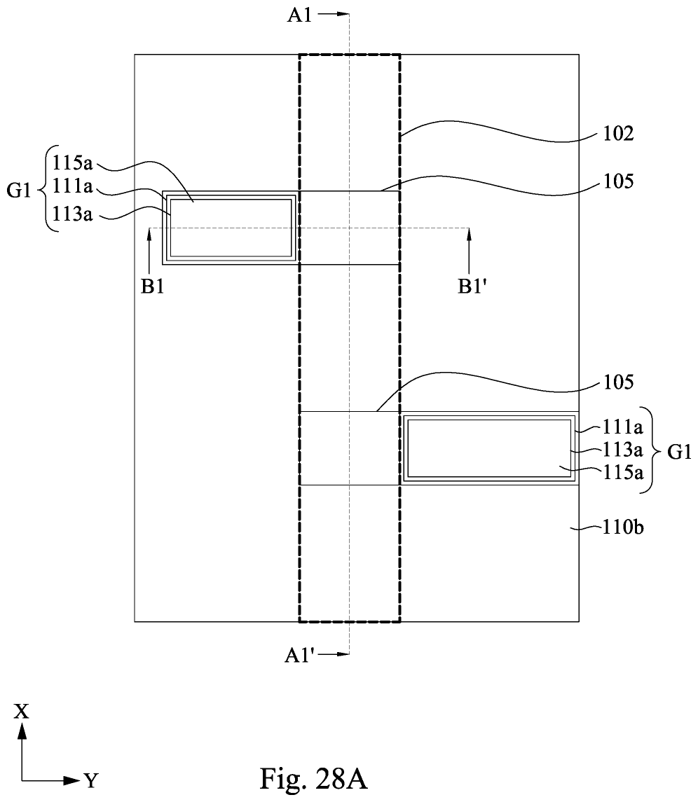

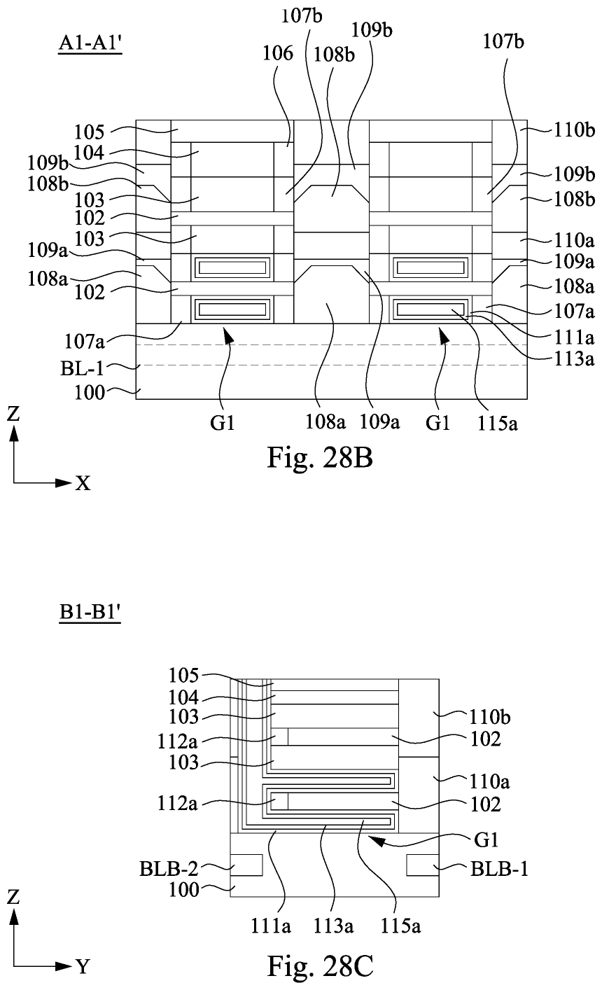

Reference is made to FIGS. 28A, 28B, and 28C. After the formation of the gate structure G1, a planarization process (e.g., CMP) is performed to remove the excessive ILD layer 110b, the gate electrode layer 115a, the high-k dielectric layer 113a, and the interfacial layer 111a above the hard mask layer 105 until the hard mask layer 105 is exposed. In some embodiments, the hard mask layer 105 may also act as an etch stop layer for etching the ILD layer 110b.

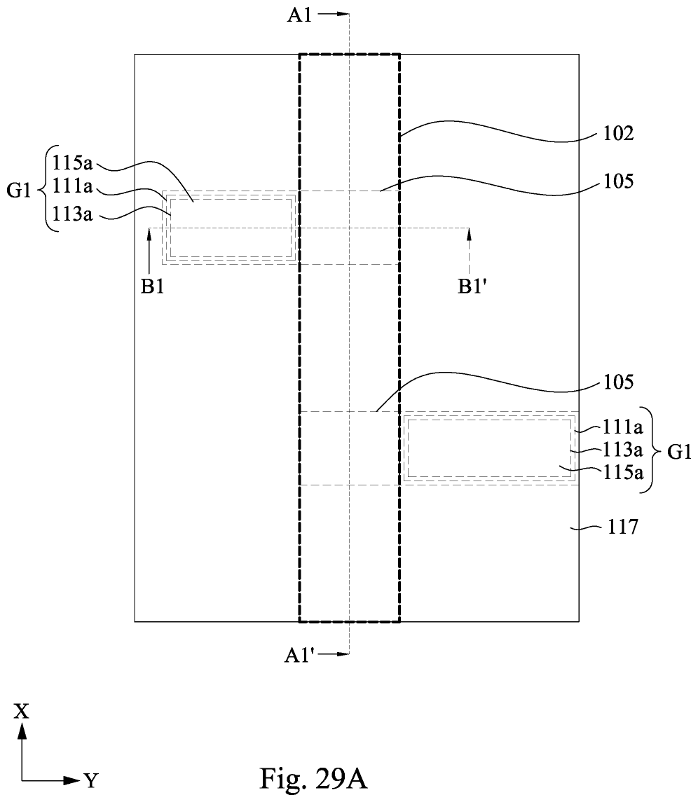

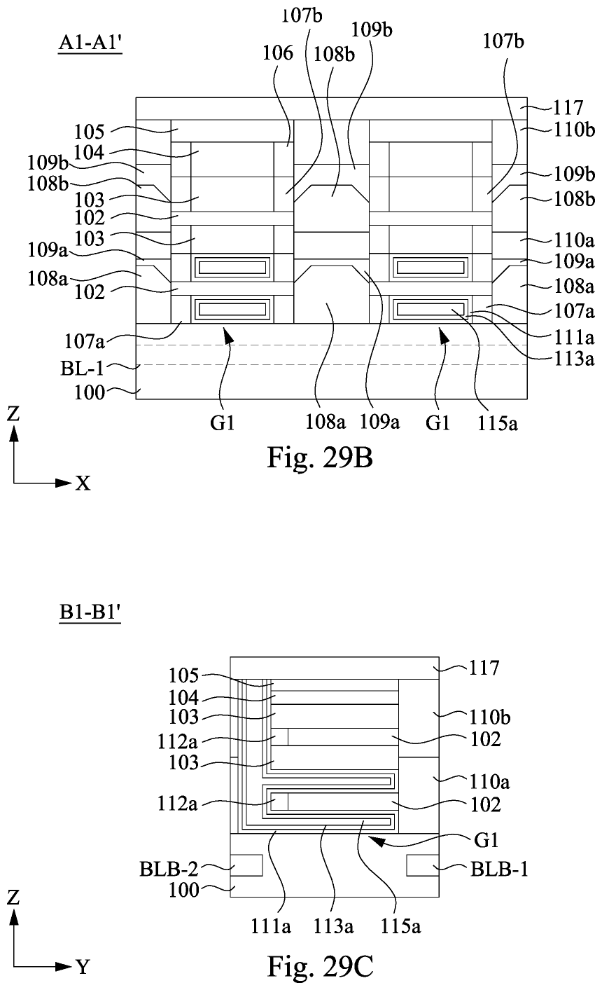

Reference is made to FIGS. 29A, 29B, and 29C. A hard mask layer 117 may be formed over the ILD layer 110b and the hard mask layer 105. In some embodiments, the hard mask layer 117 may be made of the same material as the ILD layer 110b, thereby resulting in a substantially indistinguishable interface between the hard mask layer 117 and the ILD layer 110b. In some embodiments, the hard mask layer 117 may be made of a different material than the ILD layer 110b. In some embodiments, the hard mask layer 117 may be made of silicon oxide, silicon nitride, silicon oxynitride, silicon carbide, silicon oxycarbide (SiOC), tetraethoxysilane (TEOS), phosphosilicate glass (PSG), borophosphosilicate glass (BPSG), low-k dielectric material, other suitable material, or combinations thereof. Examples of low-k dielectric materials include, but are not limited to, fluorinated silica glass (FSG), carbon doped silicon oxide, amorphous fluorinated carbon, parylene, bis-benzocyclobutenes (BCB), or polyimide. In some embodiments, the formation of the hard mask layer 117 can be performed by using any suitable method, such as CVD, physical vapor deposition (PVD), ALD, PEALD, PECVD, SACVD, FCVD, spin-on, and/or the like, or a combination thereof.

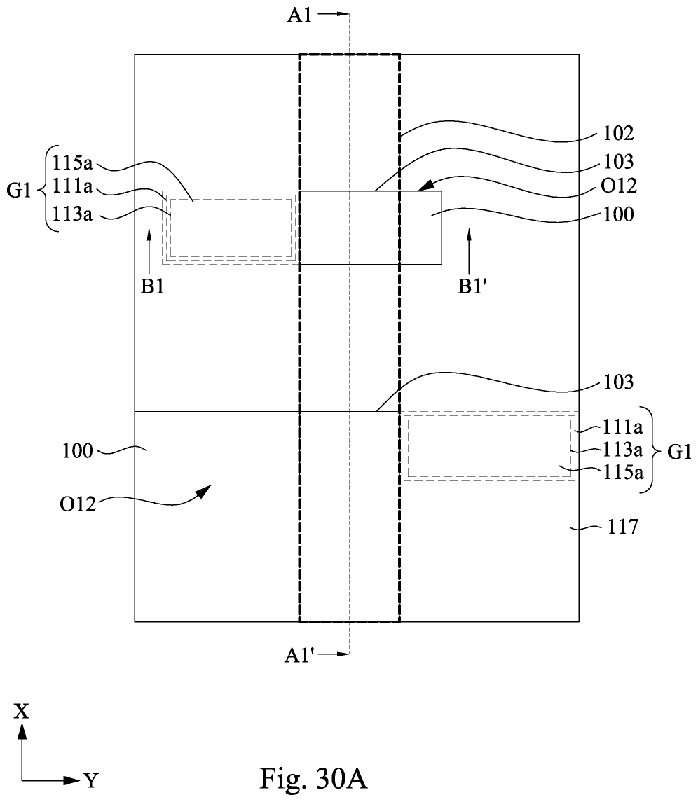

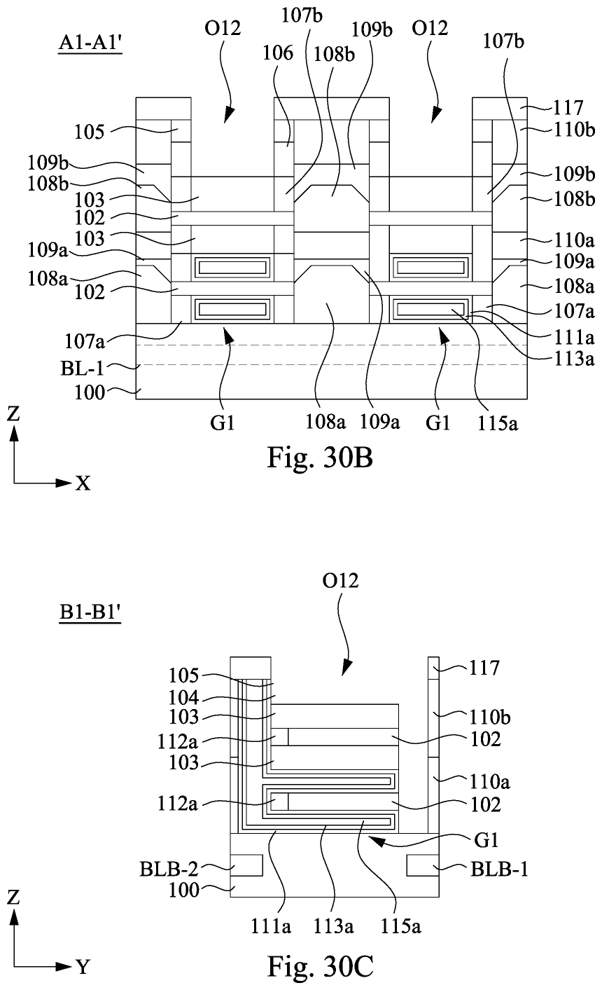

Reference is made to FIGS. 30A, 30B, and 30C. The hard mask layer 117 may be patterned and then be used to etch the dummy gate layer 104, the hard mask layer 105, and the ILD layers 110a and 110b. The hard mask layer 117 may be patterned by a lithography process including include photoresist (or resist) coating (e.g., spin-on coating), soft baking, mask aligning, exposure, post-exposure baking, developing the photoresist, rinsing, drying (e.g., hard baking), other suitable processes, and/or combinations thereof. The etching process includes dry etching, wet etching, and/or other etching methods (e.g., reactive ion etching).

After the formation of the patterned hard mask layer 117, the dummy gate layer 104, the hard mask layer 105, and the ILD layers 110a and 110b can be etched through the patterned hard mask layer 117 to form the opening O12. The opening O12 can extend through the ILD layers 110a and 110b to expose a second sidewall of the epitaxial stack, such that the channel layer 102 and the sacrificial layers 101 and 103 can be exposed from the opening O12. The etching process may include dry etching, wet etching, and/or other etching methods (e.g., reactive ion etching). In some embodiments, the opening O12 may have a rectangular profile extending along Y-direction from the top view. After the formation of the opening O12, the patterned mask can be removed by a suitable technique, such as a wet clean process, an ashing process, or the like.

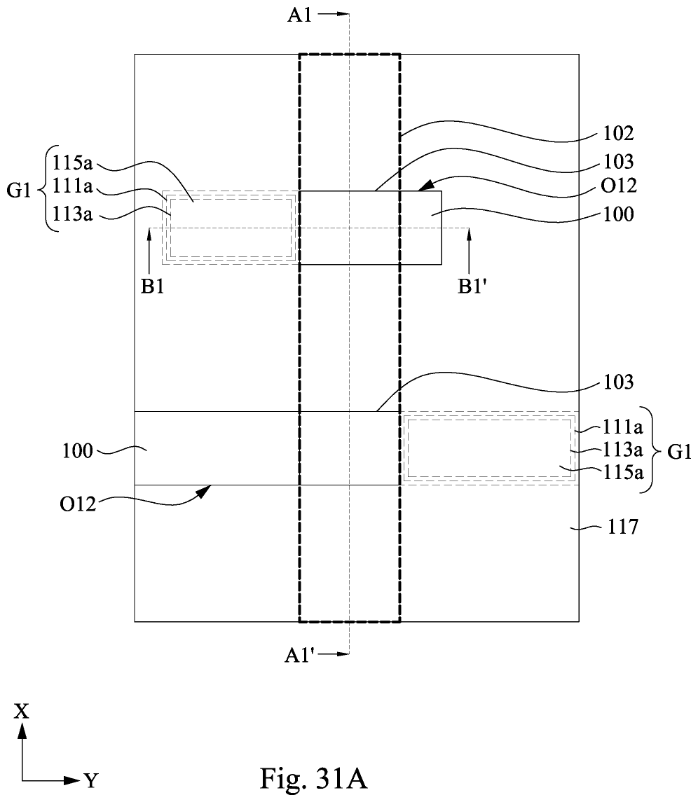

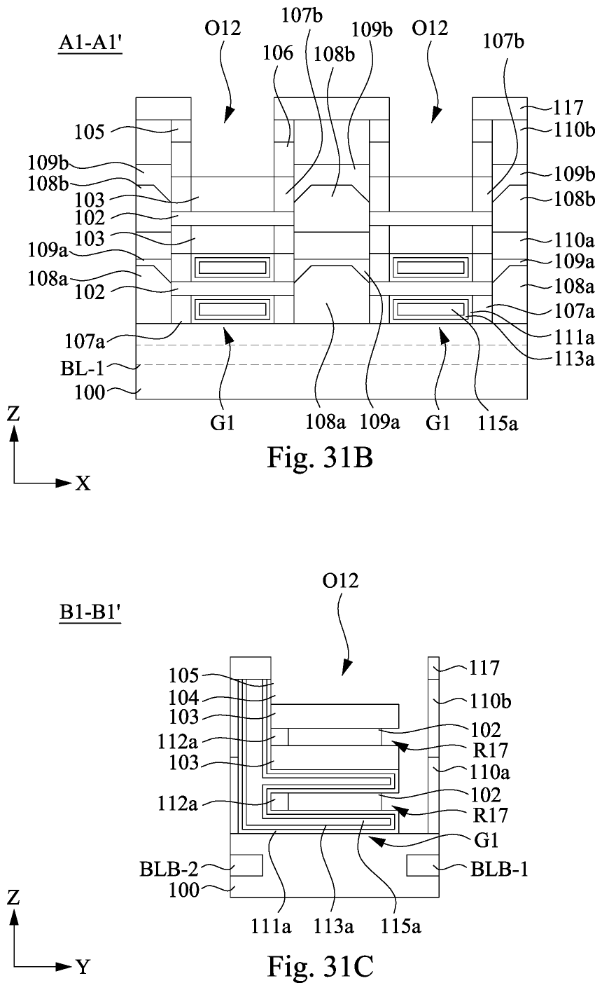

Reference is made to FIGS. 31A, 31B, and 31C. The channel layer 102 (see FIG. 31C) are laterally or horizontally recessed by using suitable etch techniques through the opening O12, resulting in lateral recesses R17 each vertically between corresponding sacrificial layers 101 and 103. This operation may be performed by using a selective etching process. By way of example and not limitation, the channel layers 102 can be made of Si and the sacrificial layers 101 and 103 can be made of SiGe allowing for the selective etching of the channel layers 102. In some embodiments, the selective dry etching etches Si at a faster etch rate than it etches SiGe.

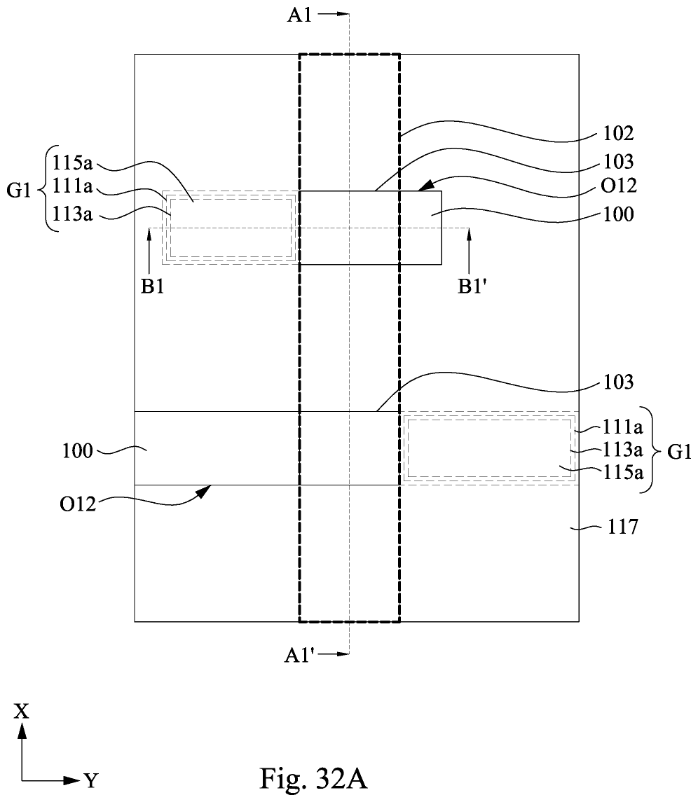

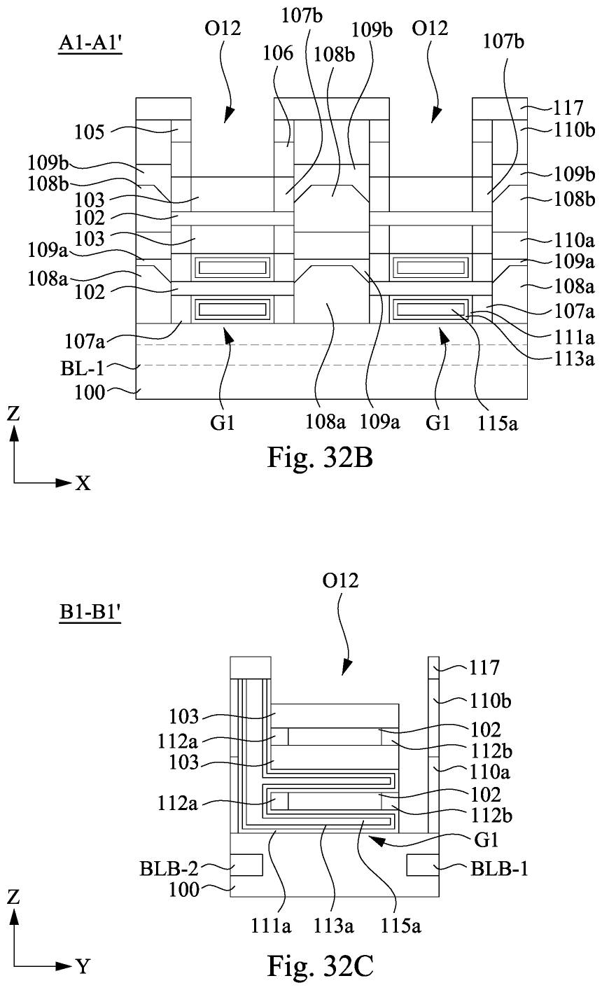

Reference is made to FIGS. 32A, 32B, and 32C. Channel sidewall spacers 112b can be filled in the recesses R17 (see FIG. 23C), respectively. For example, spacer material layers are formed to fill the recesses R17 left by the lateral etching of the channel layers 102 discussed above. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes. After the deposition of the spacer material layer, an anisotropic etching process may be performed to trim the deposited spacer material layer, such that portions of the deposited spacer material layer that fill the recesses R17 left by the lateral etching of the sacrificial layer 101 are left. After the trimming process, the remaining portions of the deposited spacer material are denoted as channel sidewall spacer 112b in the recesses R17.

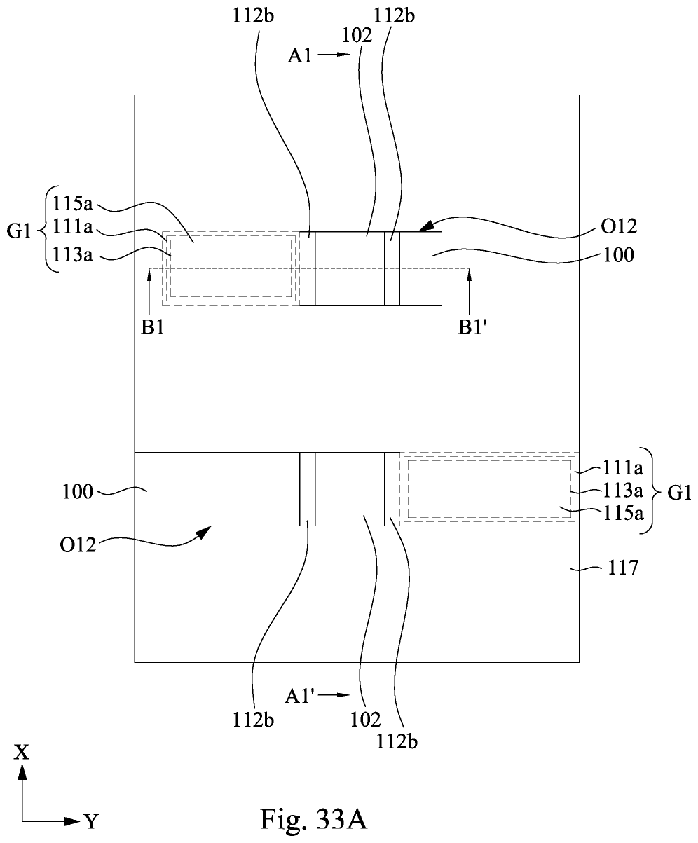

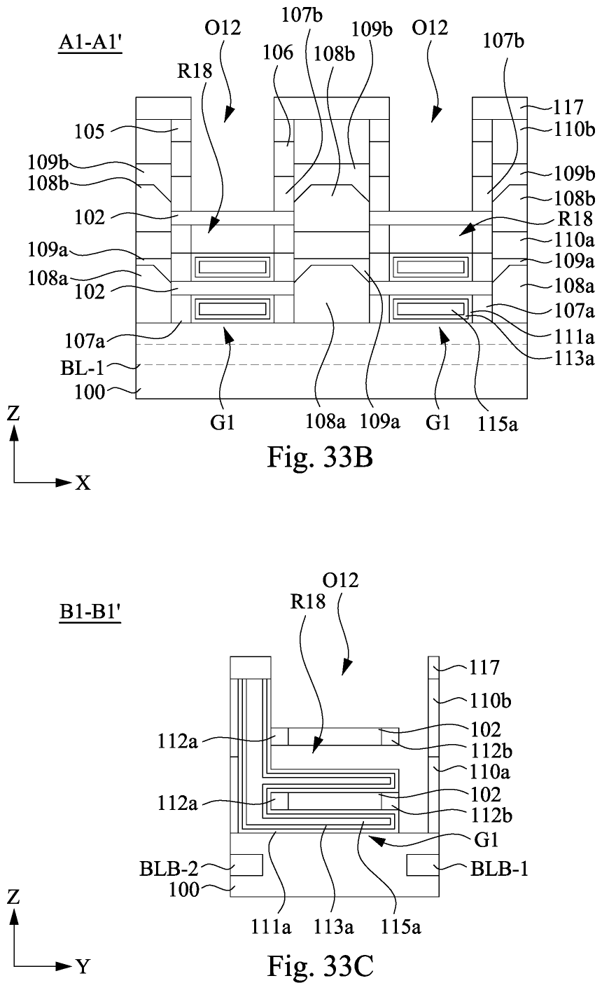

Reference is made to FIGS. 33A, 33B, and 33C. The sacrificial layers 103 (see FIGS. 33B and 33C) are removed in one or more etching process, so that a recess R18 can be formed to inherit the shape of a lower one of the sacrificial layers 103. The recess R18 can expose a bottom surface of the upper one of the channel layers 102, and the opening O12 can expose a top surface of the upper one of the channel layers 102. In some embodiments, the sacrificial layers 103 can be removed by an anisotropic dry etch process. For example, the etching process may include a dry etch process using reaction gas(es) that selectively etch the sacrificial layers 103 at faster rates than the substrate 100, the ILD layers 110a and 110b, the channel sidewall spacers 112a and 112b.

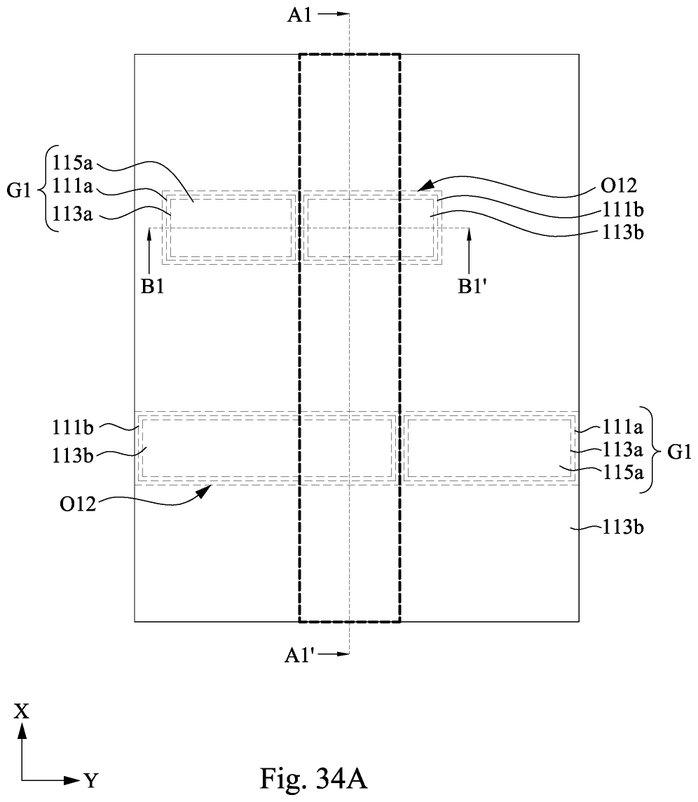

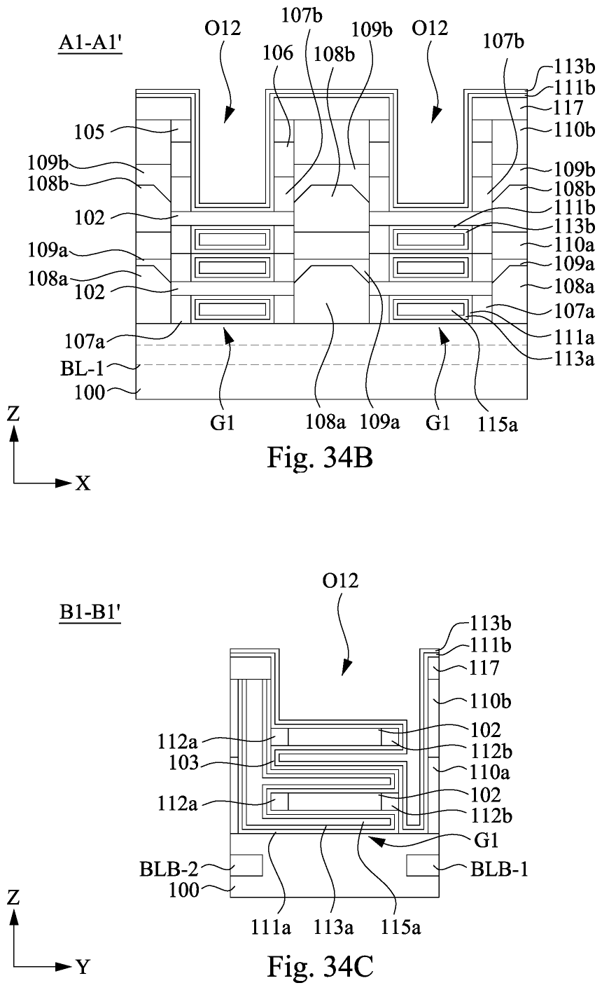

Reference is made to FIGS. 34A, 34B, and 34C. An interfacial layer 111b and a high-k dielectric layer 113b can be conformally formed over the hard mask layer 117 and in the opening O12 and the recesses R18. In some embodiments, the interfacial layer of the gate dielectric layer 111b may include a dielectric material such as silicon oxide (SiO₂). HfSiO, or silicon oxynitride (SiON). In some embodiments, the interfacial layer 111a may be deposited using any suitable method, such as CVD, physical vapor deposition (PVD), ALD, PEALD, PECVD, SACVD, FCVD, spin-on, and/or the like, or a combination thereof.

In some embodiments, the high-k dielectric layer 113b may include high-k dielectric material, such as hafnium oxide (HfO₂). hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. In some embodiments, the high-k dielectric layer 113b may be deposited using any suitable method, such as CVD, physical vapor deposition (PVD), ALD, PEALD, PECVD, SACVD, FCVD, spin-on, and/or the like, or a combination thereof.

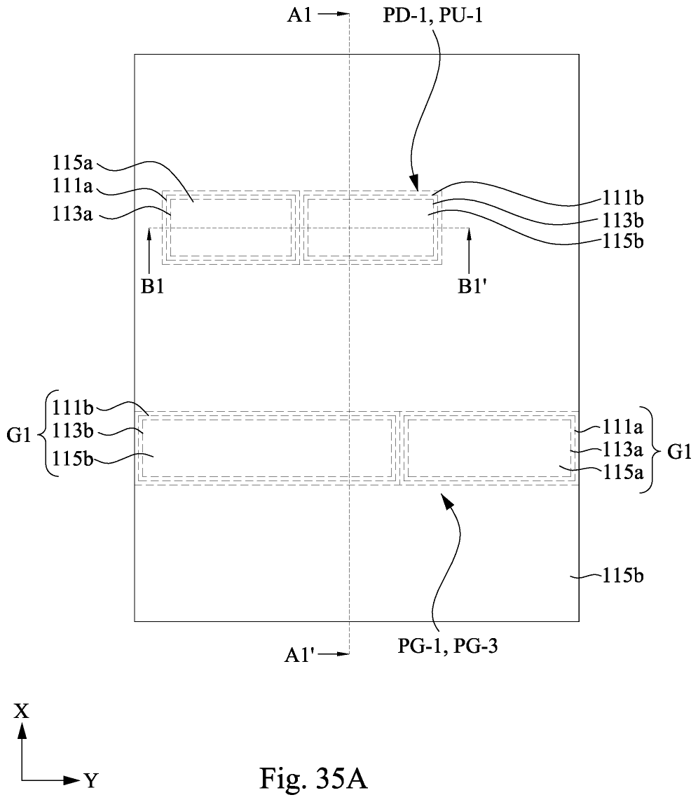

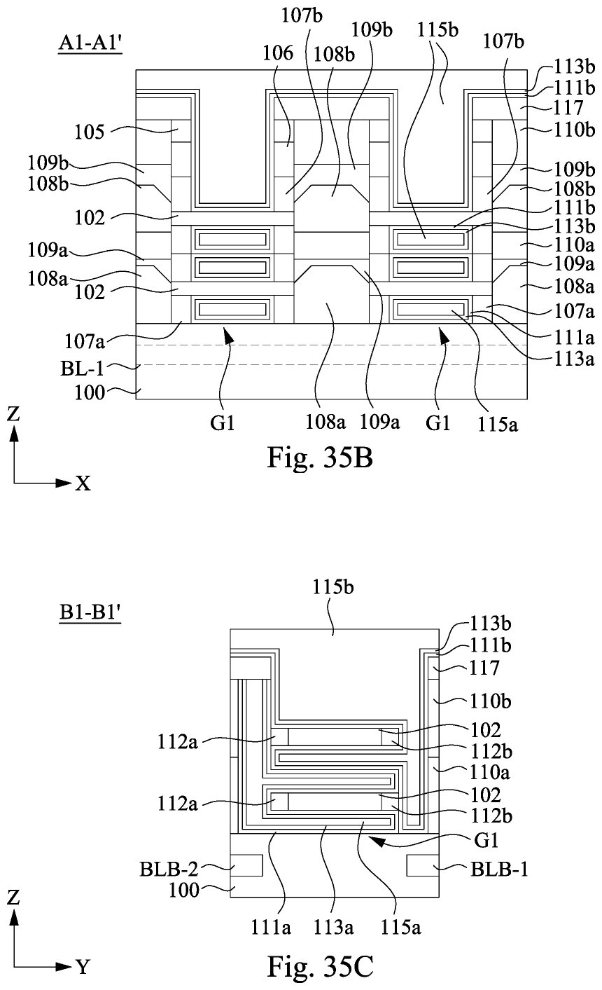

Reference is made to FIGS. 35A, 35B, and 35C. A gate electrode layer 115b can be conformally formed over the high-k dielectric layer 113b. The gate electrode layer 115b may include a work function metal layer and/or a fill metal formed around the work function metal layer. The work function metal layer and/or the fill metal may include a metal, metal alloy, or metal silicide. For an n-type FinFET, the work function metal layer may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TIC), aluminum carbide (AIC)), aluminides, and/or other suitable materials. On the other hand, for a p-type FinFET, the work function metal layer may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials. In some embodiments, the gate electrode layer 115b may be made of a different material than the gate electrode layer 115a.

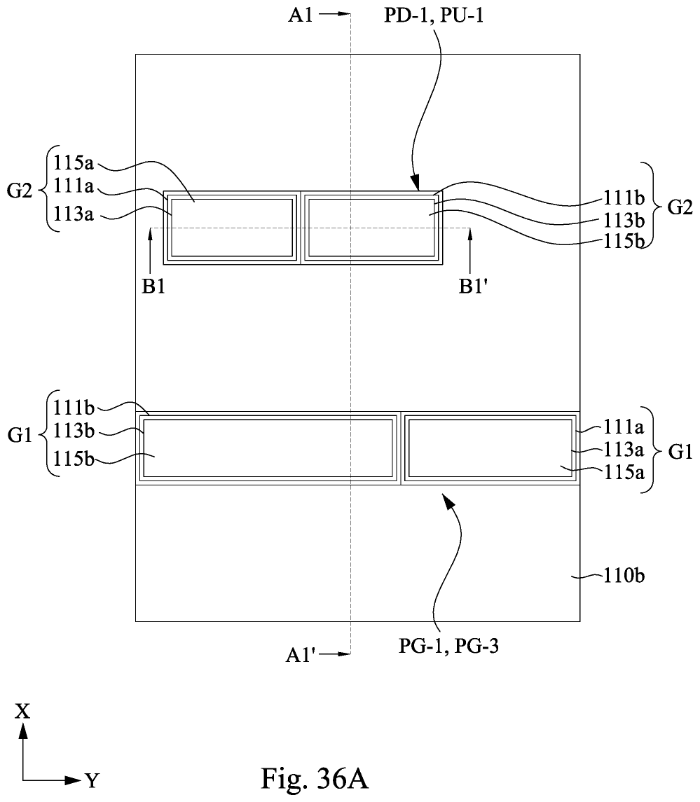

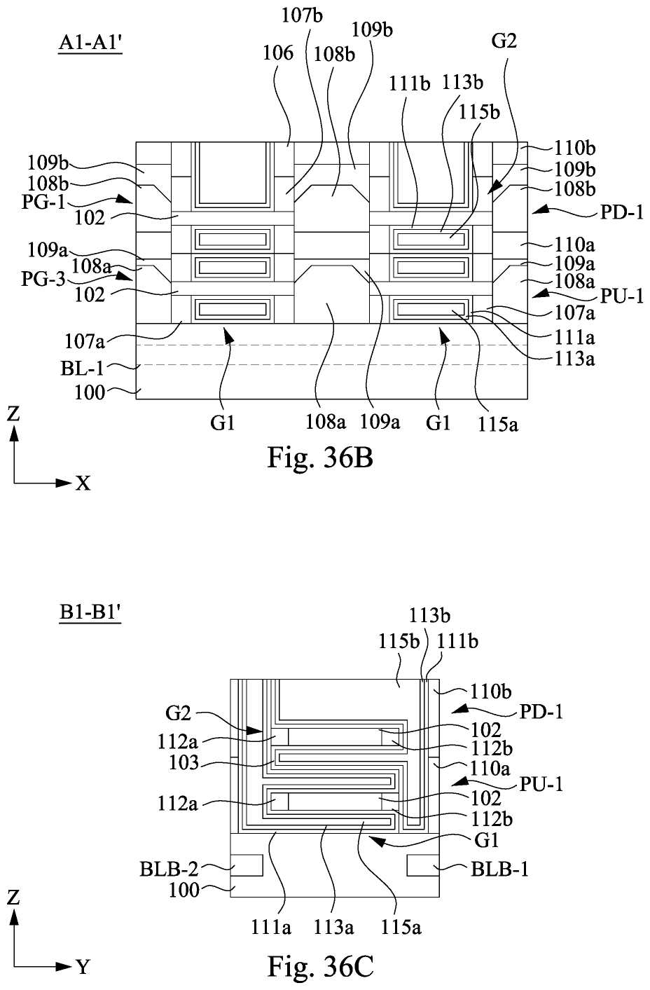

Reference is made to FIGS. 36A, 36B, and 36C. A planarization process (e.g., CMP) is performed to remove the excessive gate electrode layer 115b, the high-k dielectric layer 113b, the interfacial layer 111b, the hard mask layers 105 and 117 above the gate spacers 106. The gate spacers 106 may also act as an etch stop layer for etching the gate electrode layer 115b, the high-k dielectric layer 113b, the interfacial layer 111b, the hard mask layers 105 and 117. Therefore, a (metal) gate structure G2 including the gate electrode layer 115b, the high-k dielectric layer 113b, and the interfacial layer 111b can be formed in the recesses R18 to surround each of the upper one of the channel layers 102 suspended in the recesses R18. In some embodiments, the gate structure G2 may be the final gate of a GAA FET.

Therefore, the semiconductor structure can include the transistors PG-1, PG-3, PU-1, and PD-1. The transistor PG-1 is over the transistor PG-3, and the transistor PD-1 is over the transistor PU-1. The transistors PG-3 and PU-1 each includes the channel layers 102, the source/drain regions 108a on opposite sides of the channel layer 102 and connected to the channel layer 102, and the gate structure G1 wrapping around the channel layer 102. The transistors PG-1 and PD-1 each includes the channel layers 102, the source/drain regions 108b on opposite sides of the channel layer 102 and connected to the channel layer 102, and the gate structure G2 wrapping around the channel layer 102. In some embodiments, the transistors PG-1, PG-3, PU-1, and PD-1 can be interchangeably referred to as bottom-tier transistors. In some embodiments, the transistors PG-3 and PU-1 may be p-type transistors, and the transistors PG-1 and PU-1 are n-type transistors. In some embodiments, the transistors PG-3 and PU-1 may be n-type transistors, and the transistors PG-1 and PU-1 are p-type transistors.

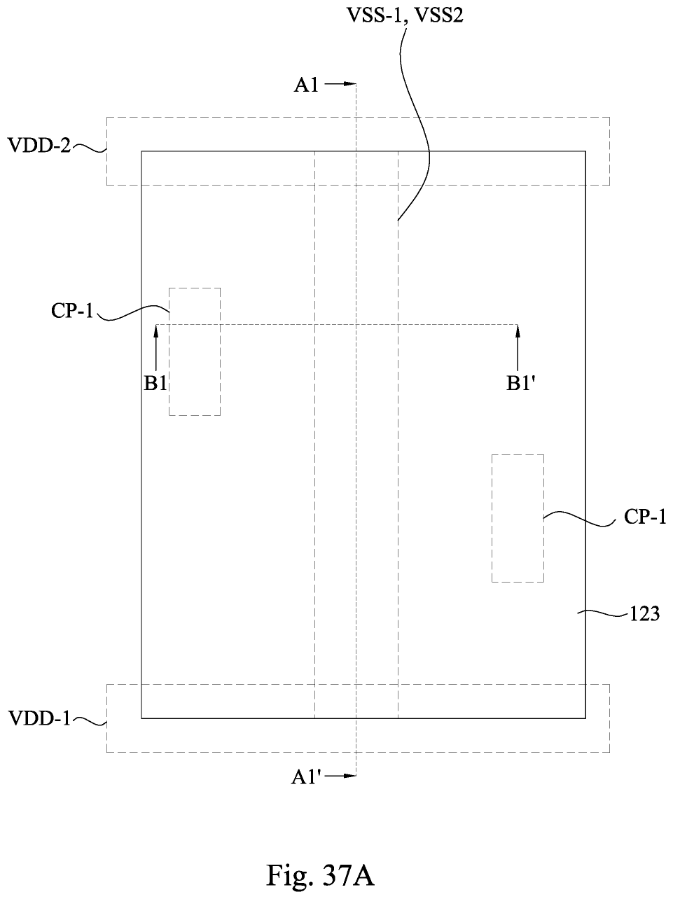

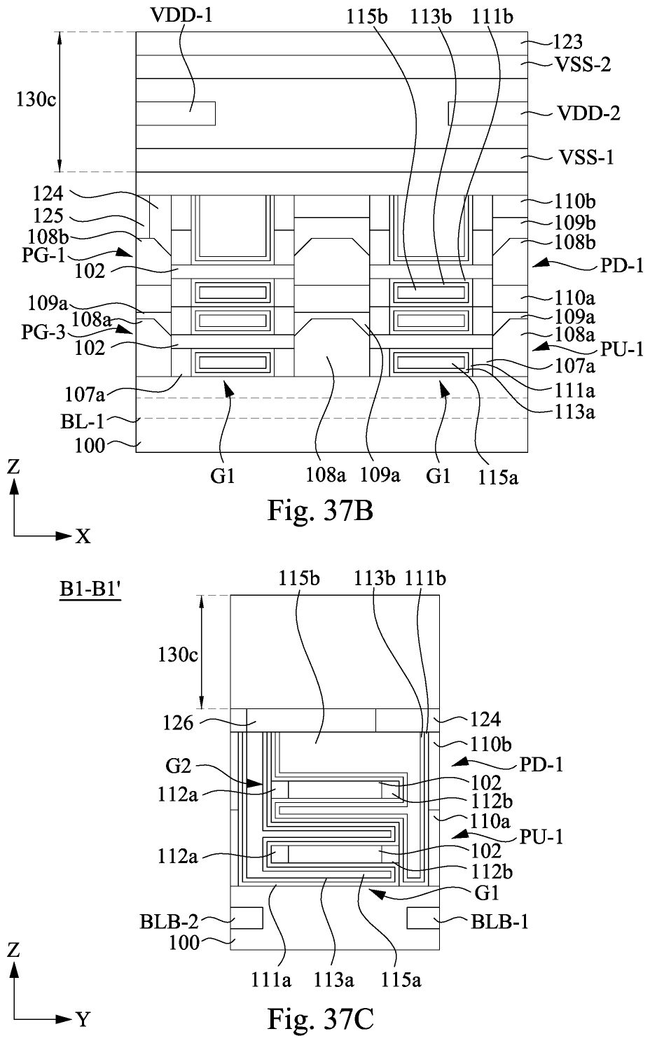

Reference is made to FIGS. 37A, 37B, and 37C. A MEOL layer 130c can be formed over the transistors PG-1. PG-3, PU-1, and PD-1. The MEOL layer 130c may include an inter-metal dielectric 123 and the ground lines VSS-1 and VSS-2, the cross coupling lines CP-1 and CP-2 (see FIG. 3C), and the voltage source line VDD-1 and VDD-2 in the inter-metal dielectric 123. The ground line VSS-1 and the cross coupling line CP-2 (see FIG. 3C) can be formed over the pass-gate transistors PG-3 and the pull-down transistor PD-1 at a same level height. The ground line VSS-1 can be electrically connected to the underlying source/drain region 108b of the transistor PD-1. The cross coupling line CP-2 (see FIG. 3C) can be electrically connected to the underlying the gate structure G1 of the pull-up transistor PD-1, and can be electrically connected to the overlying source/drain region 208a between the transistors PG-2 and PD-2. The voltage source line VDD-1 and VDD-2 can be formed over the ground line VSS-1 and the cross coupling line CP-2 (see FIG. 3C). The voltage source line VDD-2 can be electrically connected to the underlying source/drain region 108a of the transistor PU-1. The voltage source line VDD-1 can be electrically connected to the overlying source/drain region 208b of the transistor PU-2. The ground line VSS-2 and the cross coupling line CP-1 (see FIG. 3C) can be formed over the voltage source line VDD-1 and VDD-2 at a same level height. The ground line VSS-2 can be electrically connected to the overlying source/drain 208a of the transistor PD-2. The cross coupling line CP-1 (see FIG. 3C) can be electrically connected to the underlying source/drain contact 171b on the source/drain region 108b between the transistors PG-1 and PD-1 through the via 183, and can be electrically connected to an overlying gate contact 274b (see FIG. 4G) formed subsequently on the gate structure G3 of the transistors PD-2 through a vertical local interconnect 191. In some embodiments, a dielectric layer 124 can formed between the MEOL layer 130c and the transistors PG-1, PG-3, PU-1, and PD-1, a via 125 can be formed to pass through the dielectric layer 124 and electrically connect the source/drain contact 109b to the ground line VSS-1, and a gate contact 126 can be formed in the dielectric layer 124 and electrically connect the gate structure G1 to the gate structure G2.

In some embodiments, the inter-metal dielectric 123 and/or the dielectric layer 124 may include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the ground lines VSS-1 and VSS-2, the cross coupling lines CP-1 and CP-2, the voltage source line VDD-1 and VDD-2, the via 125, and the gate contact 126 can be made of tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

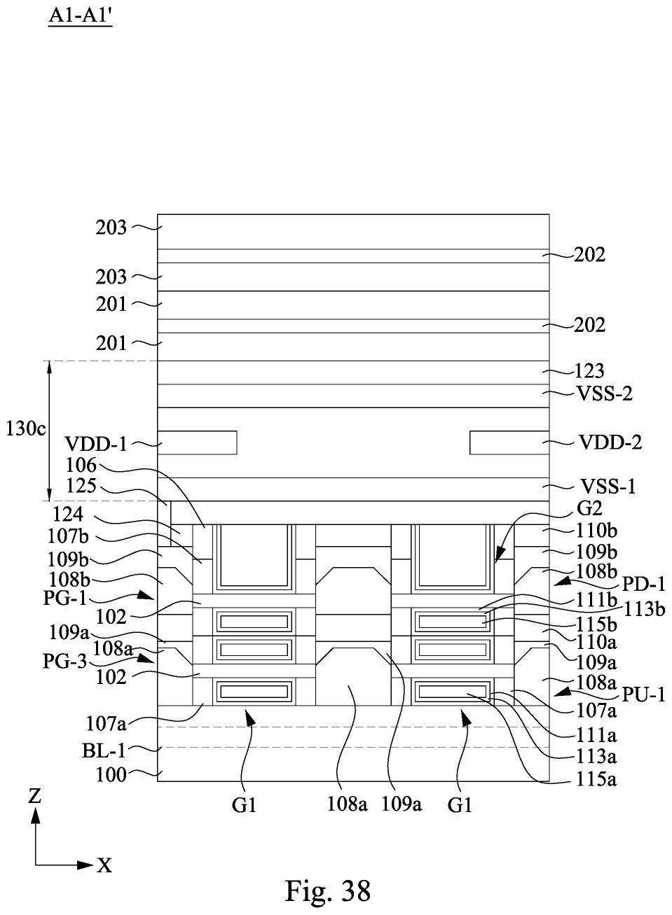

Reference is made to FIG. 38. An epitaxial stack is formed over the MEOL layer 130c. The epitaxial stack includes sacrificial layers 201 and 203 of first and second compositions interposed by channel layers 202 of a third composition. The first, second, and third compositions can be different. In some embodiments, the sacrificial layers 201 and 203 may be made of SiGe and having different germanium atomic concentrations, and the channel layers 202 may be made of silicon (Si). In some embodiments, the sacrificial layer 201 has a greater germanium atomic concentration than the sacrificial layer 203. For example, the sacrificial layer 201 may having a germanium atomic concentration in a range from about 70 to 90%, such as about 70, 75, 80, 85, or 90%, and the sacrificial layer 203 may having a germanium atomic concentration in a range from about 30 to 70%, such as about 30, 35, 40, 45, 50, 55, 60, 65, or 70%. However, other embodiments are possible including those that provide for first, second, and third compositions having different etch selectivity. By way of example, the germanium atomic concentration of the sacrificial layer 201 can be about 80%, and the germanium atomic concentration of the sacrificial layer 201 can be about 60%.

The use of the channel layers 202 to define a channel or channels of a device is further discussed below. It is noted that two layers of the channel layers 202 are arranged as illustrated in FIG. 38, which is for illustrative purposes only and not intended to be limiting beyond what is specifically recited in the claims. It can be appreciated that any number of sacrificial layers can be formed in the epitaxial stack; the number of layers depending on the desired number of channels regions for the transistor. In some embodiments, the number of each of the channel layers 202 can be between about 2 and 200. As described in more detail below, the channel layers 202 may serve as channel region(s) for a subsequently-formed semiconductor device and the thickness is chosen based on device performance considerations. The sacrificial layers 201 and 203 in channel regions(s) may eventually be removed and serve to define a vertical distance between adjacent channel region(s) for a subsequently-formed multi-gate device and the thickness is chosen based on device performance considerations.

By way of example, epitaxial growth of the layers of the epitaxial stack may be performed by a molecular beam epitaxy (MBE) process, a metalorganic chemical vapor deposition (MOCVD) process, and/or other suitable epitaxial growth processes. In some embodiments, the sacrificial layers 201 and 203 and channel layer 202 can include different materials than the substrate 100. As stated above, in at least some examples, the sacrificial layers 201 and 203 can include epitaxially grown silicon germanium (SiGe) layers, and the channel layers 202 include an epitaxially grown silicon (Si) layer. Alternatively, in some embodiments, either of the sacrificial layers 201 and 203, and the channel layer 202 may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP. AlInAs, AlGaAs, InGaAs, GaInP, and/or GaInAsP, III-V, or combinations thereof. As discussed, the materials of the sacrificial layers 201 and 203 and the channel layer 202 may be chosen based on providing differing oxidation and/or etching selectivity properties.

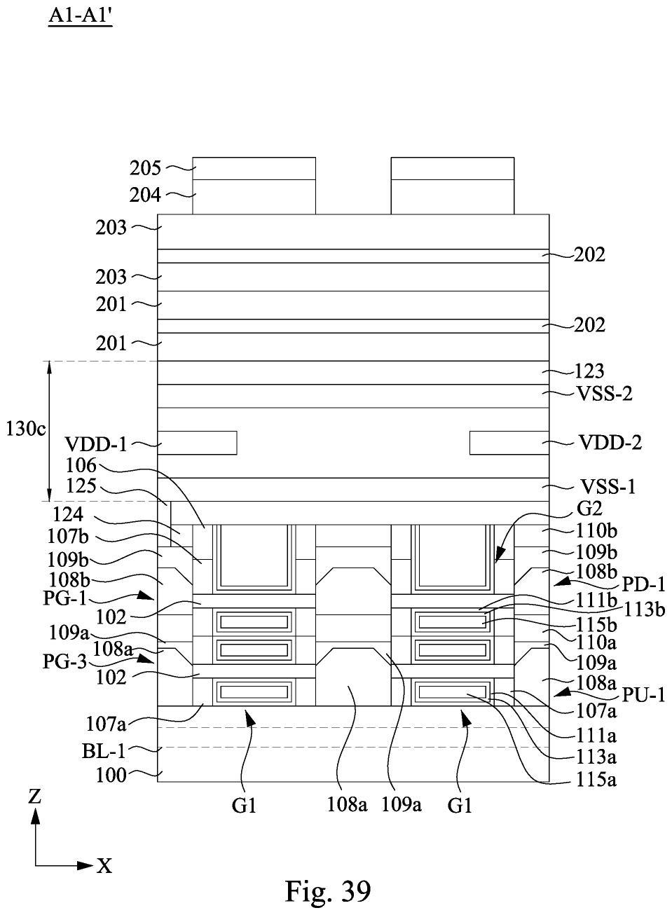

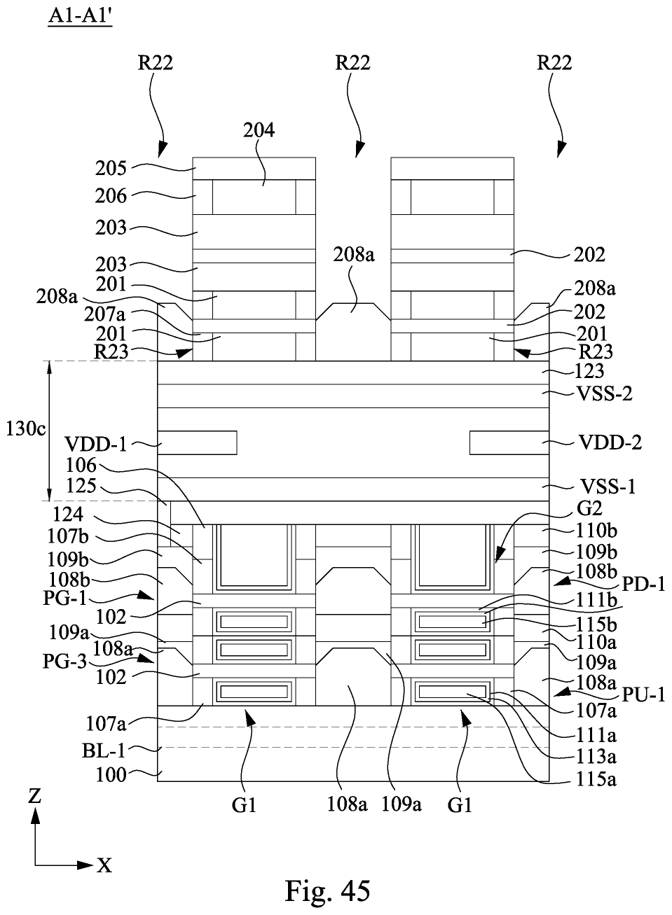

Reference is made to FIG. 39. Dummy gate layers 204 and hard mask layers 205 are formed over the epitaxial stack. Portions of the channel layer 202 underlying the dummy gate layers 204 may be referred to as the channel regions. The dummy gate layer 204 may also define source/drain regions 208a (labeled in FIG. 45). Dummy gate formation operation forms the dummy gate layer 204 and the hard mask layer 205 over the dummy gate layer 204. The hard mask layer 205 is then patterned, followed by patterning the dummy gate layer 204 by using the patterned hard mask layer 205 as an etch mask. The etch process may include a wet etch, a dry etch, and/or combinations thereof.

In some embodiments, the dummy gate layer 204 may include polycrystalline-silicon (poly-Si), poly-crystalline silicon-germanium (poly-SiGe), metallic nitrides, metallic silicides, metallic oxides, or metals. In some embodiments, the dummy gate layer 204 may include a metal-containing material such as TiN, TaN, TaC, Co, Ru, Al, combinations thereof, or multi-layers thereof. The hard mask layer 205 may be made of a dielectric material such as silicon nitride (SiN), silicon oxide (SiO₂), silicon carbo-nitride (SiCN), silicon oxynitride (SiON), silicon oxy-carbon (SiOC), or the like, and may have a single-layer structure or a multi-layer structure including a plurality of dielectric layers. In some embodiments, the dummy gate layer 204 may be deposited by CVD, physical vapor deposition (PVD), sputter deposition, or other techniques suitable for depositing conductive materials. In some embodiments, the hard mask layer 205 may be deposited by CVD, physical vapor deposition (PVD), sputter deposition, or other techniques suitable for depositing conductive materials. In some embodiments, the dummy gate layer 205 can be interchangeably referred to a dummy gate, a dummy gate pattern, a dummy gate strip, an isolation structure, or a dielectric gate.

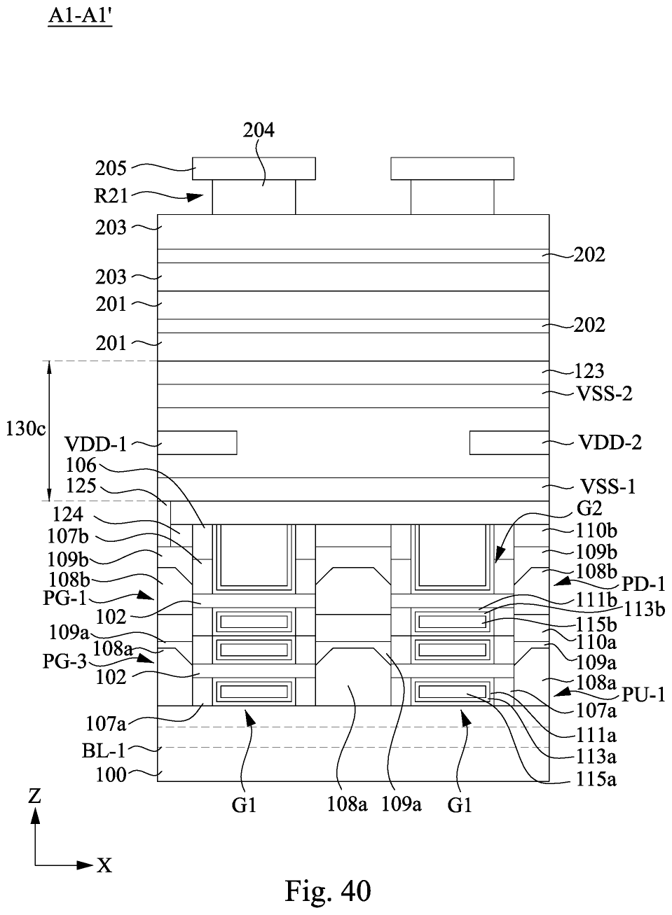

Reference is made to FIG. 40. The dummy gate layer 204 is laterally or horizontally recessed by using suitable etch techniques, resulting in lateral recesses R21 vertically between the sacrificial layer 203 and the hard mask layer 205. This operation may be performed by using a selective etching process. By way of example and not limitation, the sacrificial layer 203 may be made of SiGe, the hard mask layer 205 may be made of a dielectric material and the dummy gate layer 204 may be made of silicon allowing for the selective etching of the dummy gate layer 204. In some embodiments, the selective dry etching etches Si at a faster etch rate than it etches Si and the dielectric material. As a result, the sacrificial layer 203 and the hard mask layer 205 laterally extend past opposite end surfaces of the dummy gate layer 204.

Reference is made to FIG. 4I. After recession of the dummy gate layer 204 is completed, a spacer material 206′ is deposited over the substrate 100. The spacer material 206′ may be a conformal layer on the topmost sacrificial layer 203, the dummy gate layers 204, and the hard mask layers 205. The spacer material 206′ may include a dielectric material such as silicon oxide, silicon nitride, silicon carbide, silicon oxynitride, SiCN films, silicon oxycarbide, SiOCN films, and/or combinations thereof. In some embodiments, the spacer material 206′ includes multiple layers, such as a first spacer layer and a second spacer layer formed over the first spacer layer. By way of example, the spacer material 206′ may be formed by depositing a dielectric material over the topmost sacrificial layer 203, the dummy gate layers 204, and the hard mask layers 205 using suitable deposition processes.

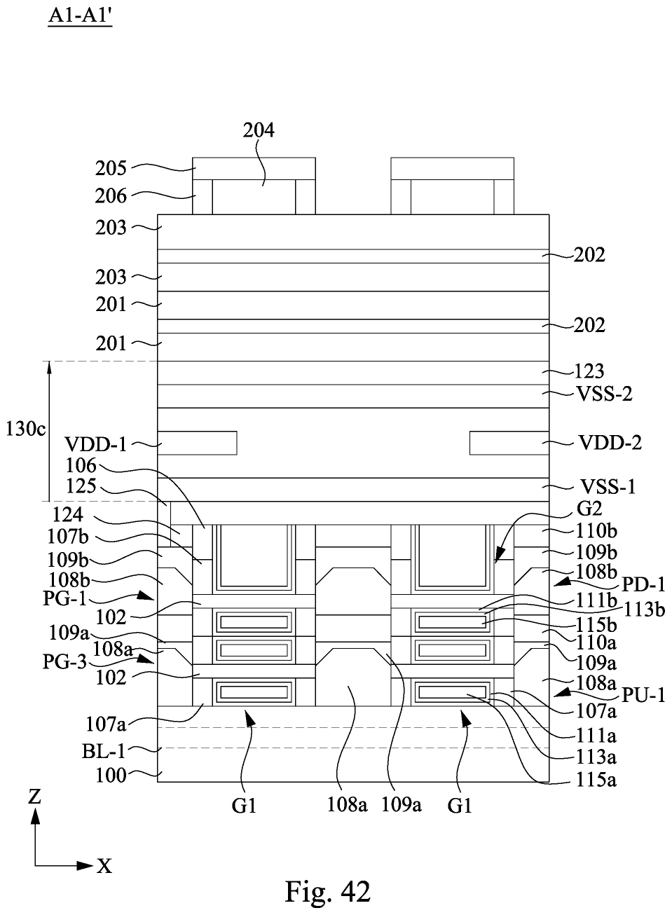

Reference is made to FIG. 42. An anisotropic etching process is then performed on the deposited spacer material 206′ to expose the topmost sacrificial layer 203 and the hard mask layers 205. Portions of the spacer material 206′ directly on the hard mask layers 205 and on the topmost sacrificial layer 203 not covered by the hard mask layers 205 may be completely removed by this anisotropic etching process. Portions of the spacer material 206′ on sidewalls of the recessed dummy gate layer 204 may remain in the lateral recesses R21, forming gate sidewall spacers 206, which are denoted as the gate spacers 206.

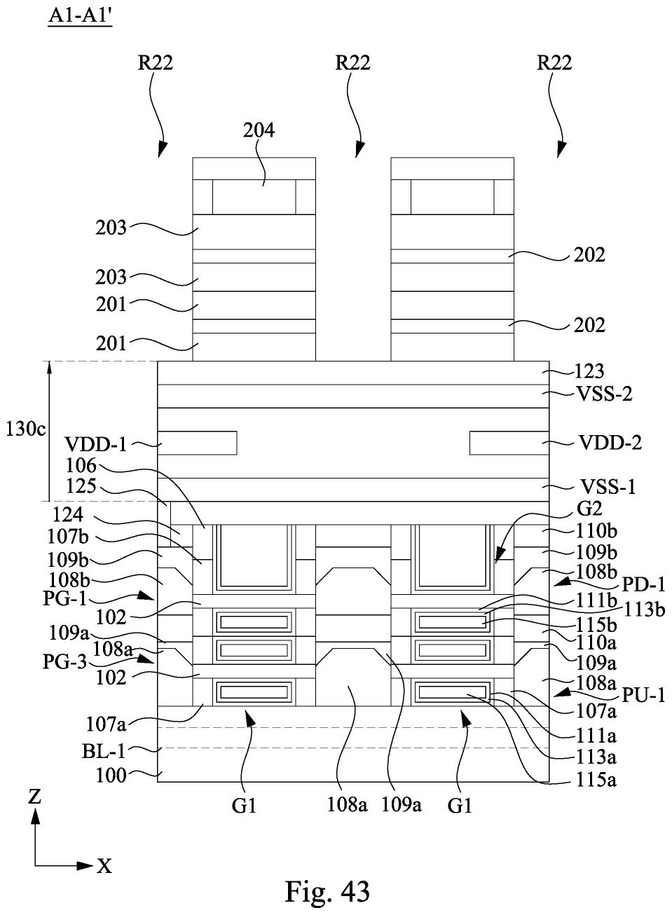

Reference is made to FIG. 43. The epitaxial stack includes the channel layers 202 and the sacrificial layers 201 and 203 shown in FIG. 42 can be patterned as that shown in FIGS. 10A-10C, such that the channel layers 202 and the sacrificial layers 201 and 203 or portions thereof may be formed nanostructures. Subsequently, exposed portions of the patterned channel layers 202 and the patterned sacrificial layers 201 and 203 that extend laterally beyond the gate spacers 206 are etched by using, for example, an anisotropic etching process that uses the dummy gate layer 204 and the gate spacers 206 as an etch mask, resulting in recesses R22 into the channel layers 202 and the sacrificial layers 201 and 203. After the anisotropic etching, end surfaces of the patterned channel layers 202 and the patterned sacrificial layers 201 and 203 and respective outermost sidewalls of the gate spacers 206 are substantially coterminous, due to the anisotropic etching. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

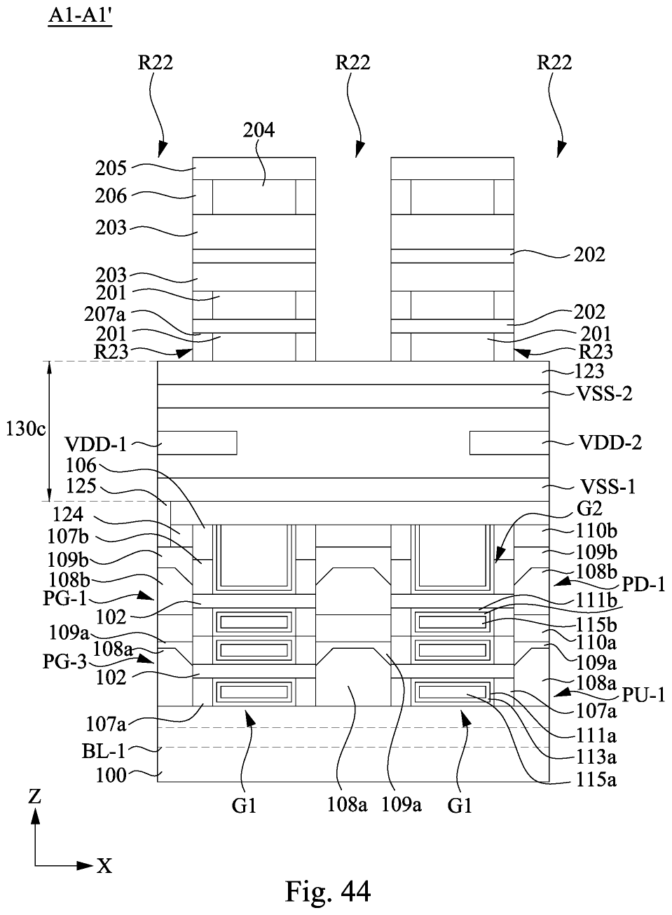

Reference is made to FIG. 44. The patterned sacrificial layers 201 are laterally or horizontally recessed by using suitable etch techniques, resulting in lateral recesses R23 each vertically between corresponding channel layers 202. This operation may be performed by using a selective etching process. By way of example and not limitation, the sacrificial layers 201 can be made of SiGe and the channel layers 202 can be made of silicon allowing for the selective etching of the sacrificial layers 201. In some embodiments, the selective dry etching etches SiGe at a faster etch rate than it etches Si. As a result, the patterned channel layers 202 laterally extend past opposite end surfaces of the patterned sacrificial layers 201. In addition, since the sacrificial layers 201 has a greater germanium atomic concentration than the sacrificial layers 203, the selective dry etching etches the sacrificial layers 201 at a faster etch rate than it etches the sacrificial layers 203, and thus the sacrificial layers 201 can be laterally or horizontally recessed while the sacrificial layers 203 can be only minimally consumed during an etching process.

Subsequently, inner spacers 207a are filled in the recesses R23, respectively. For example, spacer material layers are formed to fill the recesses R23 left by the lateral etching of the sacrificial layers 201 discussed above. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes. After the deposition of the spacer material layer, an anisotropic etching process may be performed to trim the deposited spacer material layer, such that portions of the deposited spacer material layer that fill the recesses R23 left by the lateral etching of the sacrificial layers 201 are left. After the trimming process, the remaining portions of the deposited spacer material are denoted as inner spacers 207a in the recesses R23. The inner spacers 207a serve to isolate metal gates from source/drain regions formed in subsequent processing.

Reference is made to FIG. 45. Source/drain regions 208a are formed in the recesses R22 and connected to a lower one of the channel layers 202. The source/drain regions 208a may be formed by performing an epitaxial growth process that provides an epitaxial material on the MEOL layer 130c. During the epitaxial growth process, the dummy gate layer 204, gate spacers 206, and the inner spacers 207a limit the source/drain regions 208a to the substrate 100 and the channel layers 202. In some embodiments, the lattice constants of the source/drain regions 208a are different from the lattice constant of the channel layers 202, so that the channel layers 202 can be strained or stressed by the source/drain regions 208a to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the channel layers 202. In some embodiments, source/drain regions 208a may also be formed on an upper one of the channel layers 202. However, an etching process is performed to remove the source/drain regions 208a on the upper one of the channel layers 202, such that the upper one of the channel layers 202 can be exposed.

In some embodiments, the source/drain regions 208a may include Ge, Si, GaAs, AlGaAs, SiGe, GaAsP, SiP, or other suitable material. The source/drain regions 208a may be in-situ doped during the epitaxial process by introducing doping species including: p-type dopants, such as boron or BF₂; n-type dopants, such as phosphorus or arsenic; and/or other suitable dopants including combinations thereof. If the source/drain regions 208a are not in-situ doped, an implantation process (i.e., a junction implant process) is performed to dope the source/drain regions 208a. In some embodiments, the source/drain regions 208a can be in an n-type transistor and include SiP. In some embodiments, the source/drain regions 208a and the source/drain regions 208a can be made of different materials. For example, the source/drain regions 208a can be made of SiGeB, and the source/drain regions 208a can be made of SiP. In some embodiments, the source/drain regions 208a can be interchangeably referred to as a source/drain pattern, an epitaxial pattern, a source/drain structure, or an epitaxial structure.

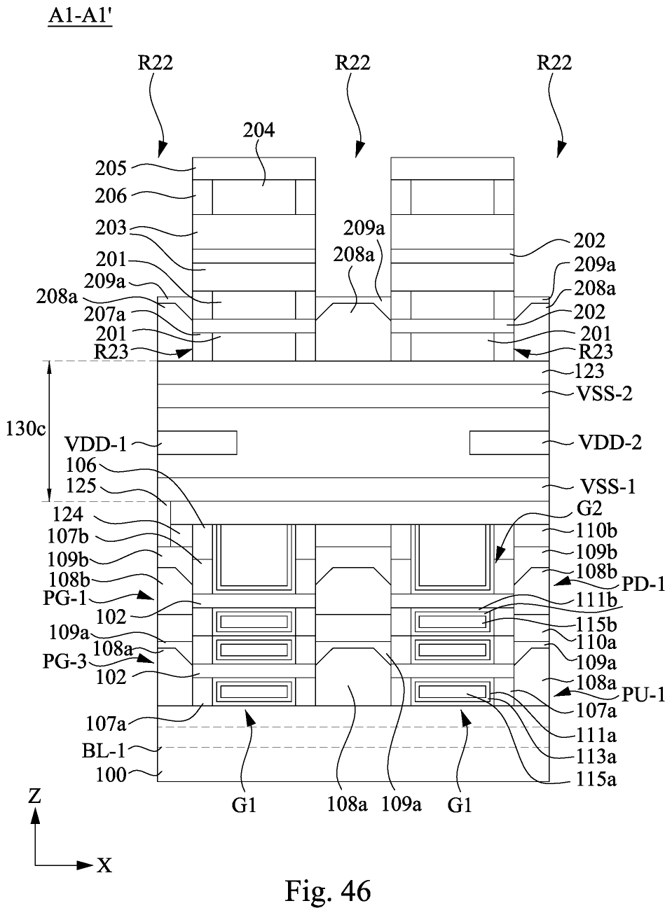

Reference is made to FIG. 46. Source/drain contacts 209a can be formed over the source/drain regions 208a. In some embodiments, the source/drain contacts 209a may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, other suitable materials, or combinations thereof. In some embodiments, the formation of the source/drain contacts 209a can be performed by such as a lift-off process. By way of example and not limitation, a mask layer (not shown) can be formed by depositing a photoresist layer over the substrate 100 by suitable process, such as spin-coating technique, which may include baking the photoresist layer after coating. In some embodiments, the mask layer may include a photoresist material including positive-type or negative-type resist materials. The mask layer can be patterned to form openings exposing the source/drain contacts 209a. Subsequently, a contact material can be deposited over the substrate 100 and formed on the source/drain contacts 209a and on the patterned mask layer. Subsequently, the substrate 100 can be immersed into a tank of appropriate solvent that will react with the patterned mask layer. The patterned mask layer may swell, dissolve, and lift off the contact material formed on the patterned mask layer, portions of the contact material on the source/drain regions 208a are remained to form the source/drain contacts 209a.

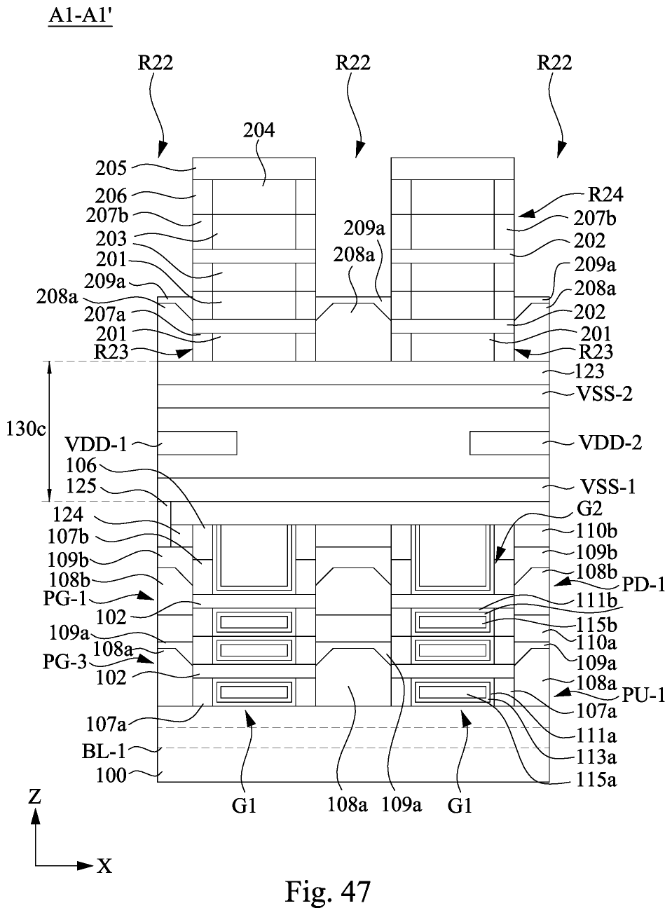

Reference is made to FIG. 47. The sacrificial layers 203 are laterally or horizontally recessed by using suitable etch techniques, resulting in lateral recesses R24 each vertically between corresponding channel layers 202. This operation may be performed by using a selective etching process. By way of example and not limitation, the sacrificial layers 201 can be made of SiGe and the channel layers 202 can be made of silicon allowing for the selective etching of the sacrificial layers 201. In some embodiments, the selective dry etching etches SiGe at a faster etch rate than it etches Si. As a result, the patterned channel layers 202 laterally extend past opposite end surfaces of the patterned sacrificial layers 203.

Subsequently, inner spacers 207b are filled in the recesses R24, respectively. For example, spacer material layers are formed to fill the recesses R24 left by the lateral etching of the sacrificial layers 203 discussed above. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes. After the deposition of the spacer material layer, an anisotropic etching process may be performed to trim the deposited spacer material layer, such that portions of the deposited spacer material layer that fill the recesses R24 left by the lateral etching of the sacrificial layers 203 are left. After the trimming process, the remaining portions of the deposited spacer material are denoted as inner spacers 207b in the recesses R24. The inner spacers 207b serve to isolate metal gates from source/drain regions formed in subsequent processing.

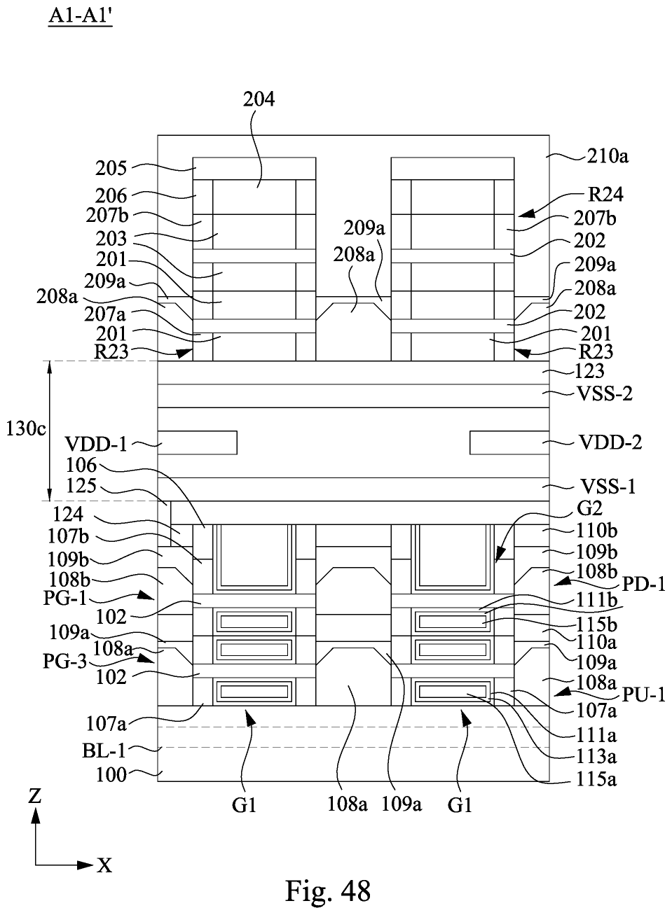

Reference is made to FIG. 48. An interlayer dielectric (ILD) layer 210a is formed over the substrate 100. In some embodiments, the ILD layer 210a includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the ILD layer 210a may be deposited by a plasma-enhanced chemical vapor deposition (PECVD) process or other suitable deposition technique. In some embodiments, after formation of the ILD layer 210a, the substrate 100 may be subject to a high thermal budget process to anneal the ILD layer 210a.

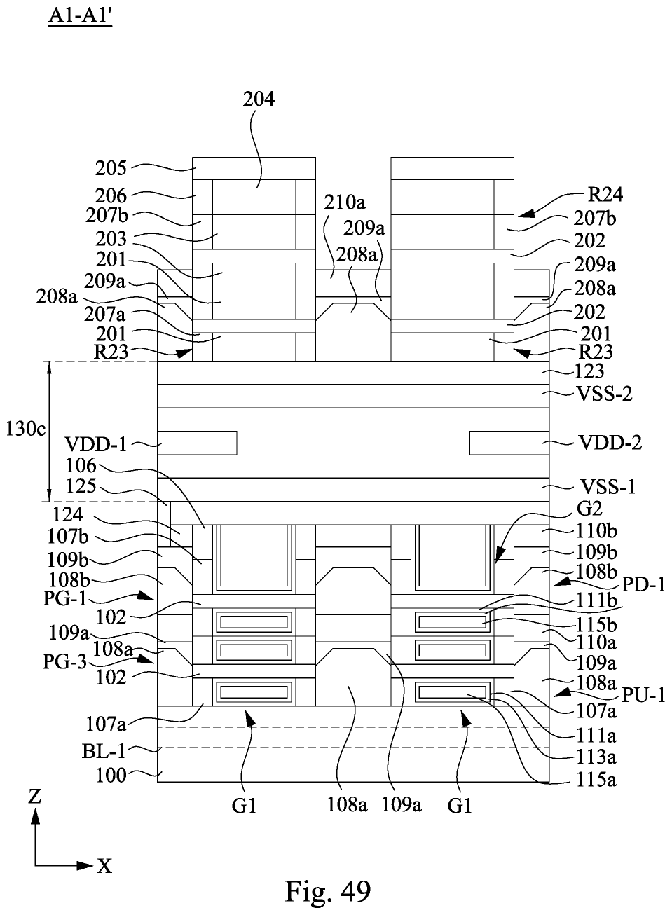

Reference is made to FIG. 49. After depositing of the ILD layer 210a, a planarization process may be performed to remove excessive materials of the ILD layer 210a. For example, a planarization process includes a chemical mechanical planarization (CMP) process which removes portions of the ILD layer 210a overlying the hard mask layer 205. Subsequently, the ILD layer 210a can be recessed, such that the upper portions of the recesses R22 may reappear. The etching may be performed using a dry etching process, wherein NH₃ and NF₃ are used as the etching gases. During the etching process, plasma may be generated. Argon may also be included. In accordance with alternative embodiments of the present disclosure, the recessing of the ILD layer 210a can be performed by using a wet etch process. In some embodiments, the etching chemical may include diluted HF, for example.

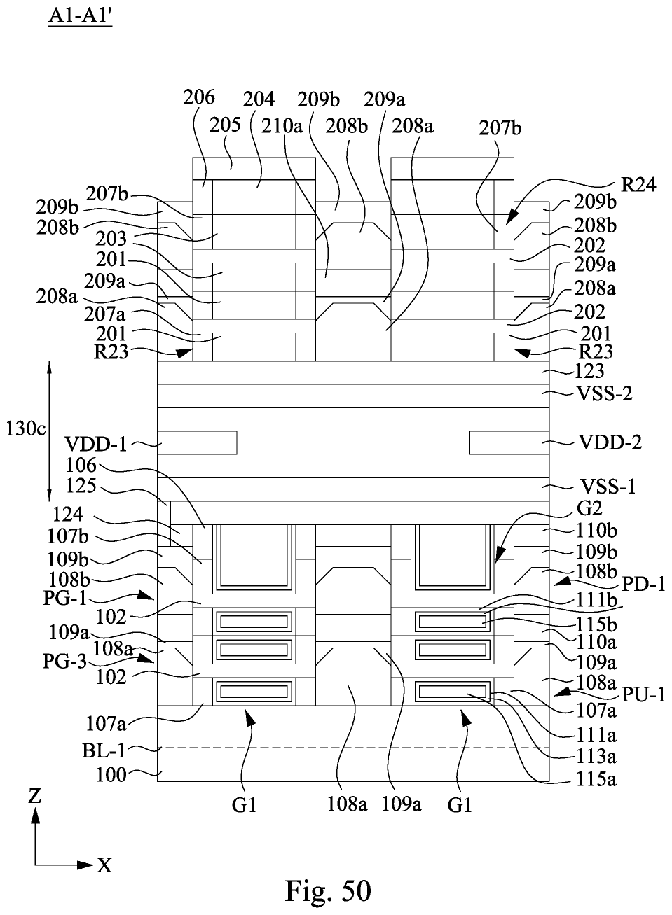

Reference is made to FIG. 50. Source/drain regions 208b are formed over the ILD layer 210a. The source/drain regions 208b may be formed by performing an epitaxial growth process that provides an epitaxial material on the ILD layer 210a. During the epitaxial growth process, the dummy gate layer 204, the gate spacers 206, and the inner spacers 207b limit the source/drain regions 208b to the channel layer 202. In some embodiments, the lattice constants of the source/drain regions 208b are different from the lattice constant of the channel layer 202, so that the channel layer 202 can be strained or stressed by the source/drain regions 208b to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the channel layer 202.

In some embodiments, the source/drain regions 208b may include Ge, Si, GaAs, AlGaAs, SiGe, GaAsP, SiP, or other suitable material. The source/drain regions 208b may be in-situ doped during the epitaxial process by introducing doping species including: p-type dopants, such as boron or BF₂; n-type dopants, such as phosphorus or arsenic; and/or other suitable dopants including combinations thereof. If the source/drain regions 208b are not in-situ doped, an implantation process (i.e., a junction implant process) is performed to dope the source/drain regions 208b. In some exemplary embodiments, the source/drain regions 208b in a p-type include SiGeB and/or GeSnB. In some embodiments, the source/drain regions 208b can be interchangeably referred to as a source/drain pattern, an epitaxial pattern, a source/drain structure, or an epitaxial structure. Each of the ILD layer 210a is between the source/drain regions 208b and 208b to electrically isolate the source/drain region 208b from the source/drain region 208b.

Subsequently, source/drain contacts 209b can be formed over the source/drain regions 208b. In some embodiments, the source/drain contacts 209a may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, other suitable materials, or combinations thereof. In some embodiments, the formation of the source/drain contacts 209a can be performed by such as a lift-off process. By way of example and not limitation, a mask layer (not shown) can be formed by depositing a photoresist layer over the substrate 100 by suitable process, such as spin-coating technique, which may include baking the photoresist layer after coating. In some embodiments, the mask layer may include a photoresist material including positive-type or negative-type resist materials. The mask layer can be patterned to form openings exposing the source/drain contacts 209b. Subsequently, a contact material can be deposited over the substrate 100 and formed on the source/drain contacts 209b and on the patterned mask layer. Subsequently, the substrate 100 can be immersed into a tank of appropriate solvent that will react with the patterned mask layer. The patterned mask layer may swell, dissolve, and lift off the contact material formed on the patterned mask layer, portions of the contact material on the source/drain regions 208b are remained to form the source/drain contacts 209b.

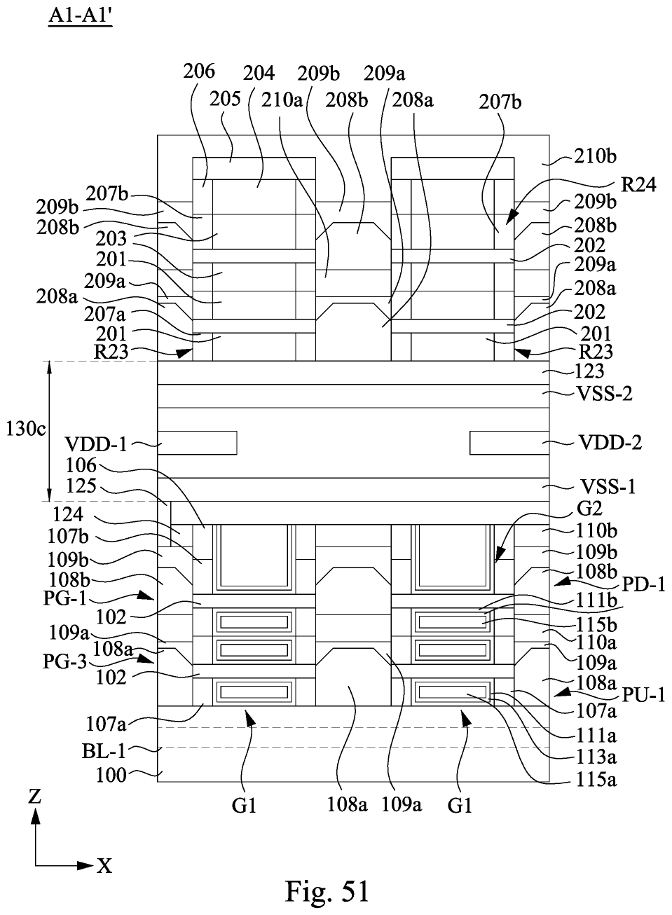

Reference is made to FIG. 51. An ILD layer 210b is formed over the substrate 100. In some embodiments, the ILD layer 210a includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the ILD layer 210b may be deposited by a plasma-enhanced chemical vapor deposition (PECVD) process or other suitable deposition technique. In some embodiments, after formation of the ILD layer 210a, the substrate 100 may be subject to a high thermal budget process to anneal the ILD layer 210b.

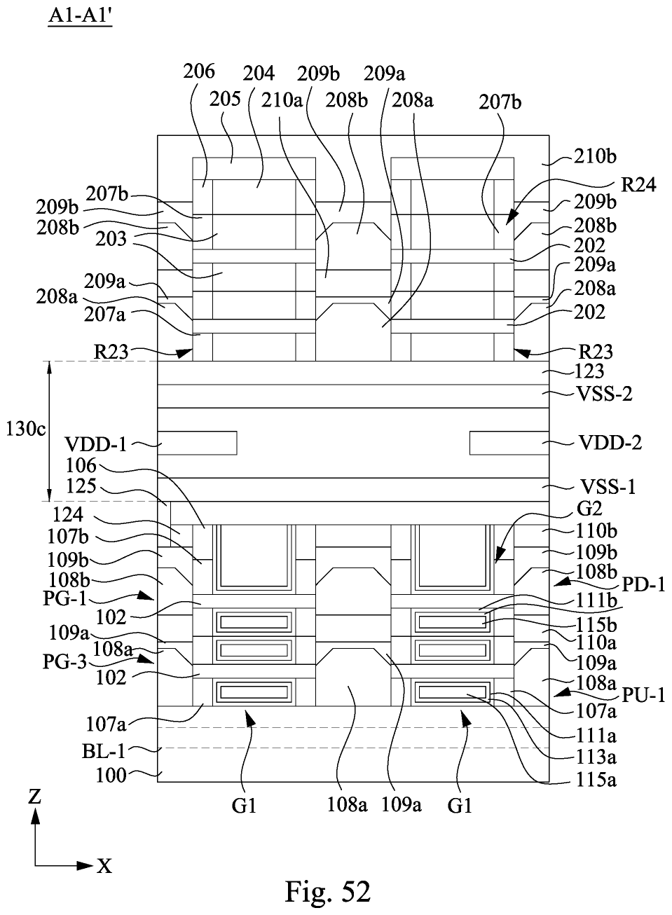

Reference is made to FIG. 52. An opening (not shown) is formed to extend through the ILD layers 210a and 210b to expose a first sidewall of the epitaxial stack, such that the channel layer 202 and the sacrificial layers 201 and 203 can be exposed from the opening. For example, a patterned mask (not shown) may be formed over the ILD layer 210b and used to etch the ILD layers 210a and 210b to form the opening that extends through the ILD layers 210a and 210b by using photolithography and etching techniques to expose a first sidewall of the sacrificial multi-layer stack. The sacrificial layers 201 are removed in one or more etching process through the opening, so that the recesses R26 are formed to inherit the shapes of the sacrificial layers 201. The recesses R26 can expose top and bottom surfaces of the lower one of the channel layers 202. In some embodiments, the sacrificial layers 201 can be removed by an anisotropic dry etch process. For example, the etching process may include a dry etch process using reaction gas(es) that selectively etch the sacrificial layers 201 at faster rates than the sacrificial layers 203. In some embodiments, the sacrificial layers 201 and 203 can be made of silicon germanium, and the sacrificial layers 201 can have a higher germanium atomic concentration than the sacrificial layers 203.

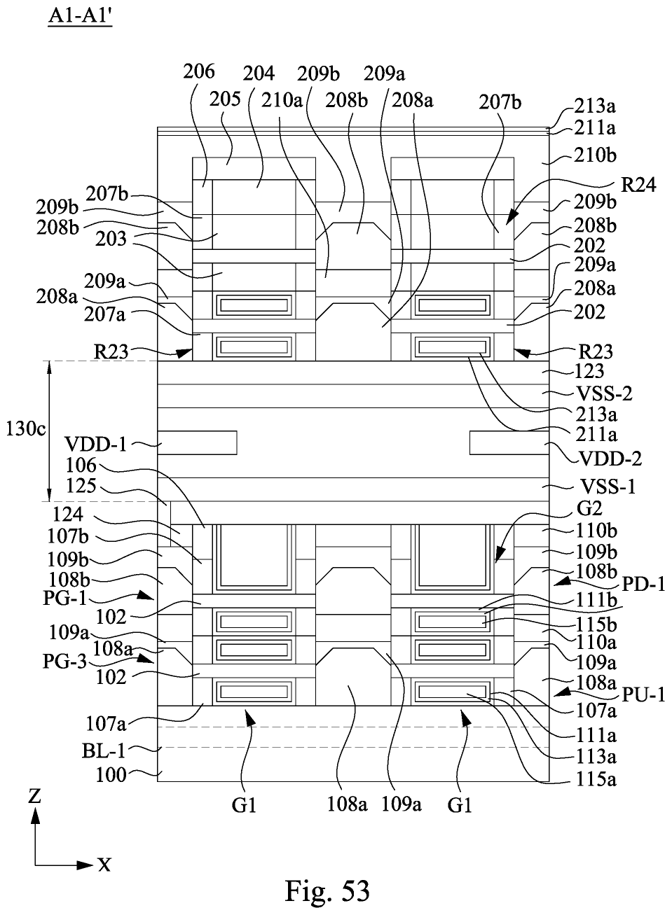

Reference is made to FIG. 53. An interfacial layer 211a and a high-k dielectric layer 213a can be conformally formed over the ILD layers 210a and 210b and in the recesses R26 through the opening as the foregoing description. In some embodiments, the interfacial layer of the gate dielectric layer 211a may include a dielectric material such as silicon oxide (SiO₂), HfSiO, or silicon oxynitride (SiON). In some embodiments, the interfacial layer 211a may be deposited using any suitable method, such as CVD, physical vapor deposition (PVD), ALD, PEALD, PECVD, SACVD, FCVD, spin-on, and/or the like, or a combination thereof.

In some embodiments, the high-k dielectric layer 213a may include high-k dielectric material, such as hafnium oxide (HfO₂). hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. In some embodiments, the high-k dielectric layer 213a may be deposited using any suitable method, such as CVD, physical vapor deposition (PVD), ALD, PEALD, PECVD, SACVD, FCVD, spin-on, and/or the like, or a combination thereof.

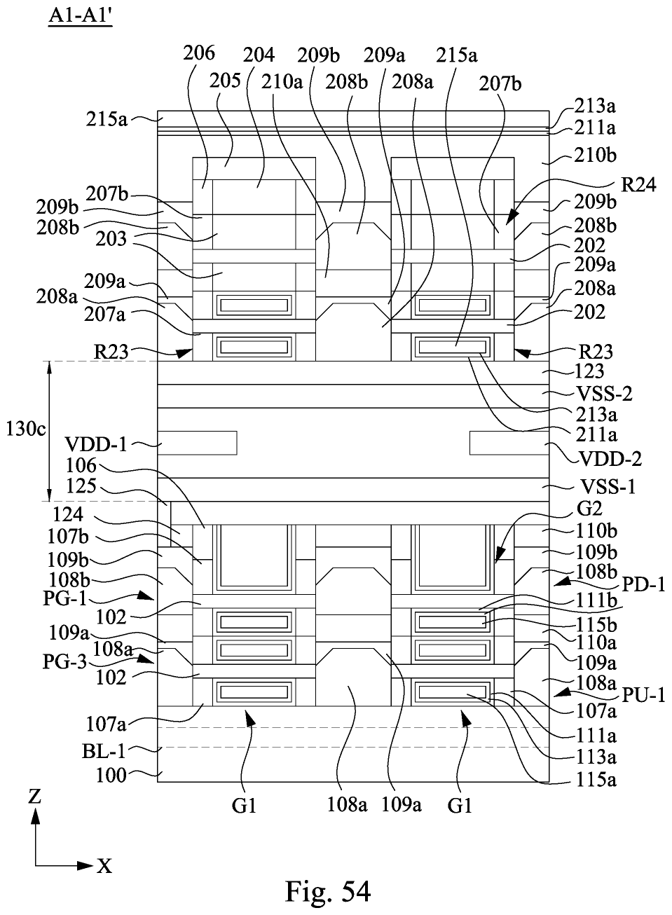

Reference is made to FIG. 54. A gate electrode layer 215a can be conformally formed over the high-k dielectric layer 213a through the opening as the foregoing description. The gate electrode layer 215a may include a work function metal layer and/or a fill metal formed around the work function metal layer. The work function metal layer and/or the fill metal may include a metal, metal alloy, or metal silicide. For an n-type FinFET, the work function metal layer may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials. On the other hand, for a p-type FinFET, the work function metal layer may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

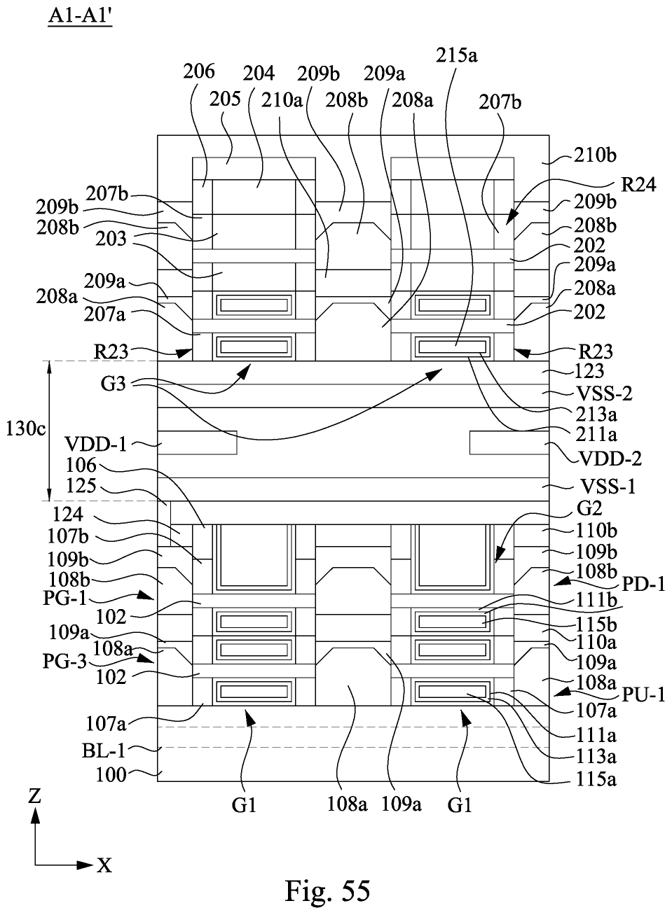

Reference is made to FIG. 55. A planarization process (e.g., CMP) is performed to remove the excessive gate electrode layer 215a, the high-k dielectric layer 213a, and the interfacial layer 211a above the ILD layer 210b. The ILD layer 210b may also act as an etch stop layer for etching the gate electrode layer 215a, the high-k dielectric layer 213a, and the interfacial layer 211a. Therefore, a (metal) gate structure G3 including the gate electrode layer 215a, the high-k dielectric layer 213a, and the interfacial layer 211a can be formed in the recesses R26 to surround each of the lower one of the channel layers 202 suspended in the recesses R26. In some embodiments, the gate structure G3 may be the final gate of a GAA FET.

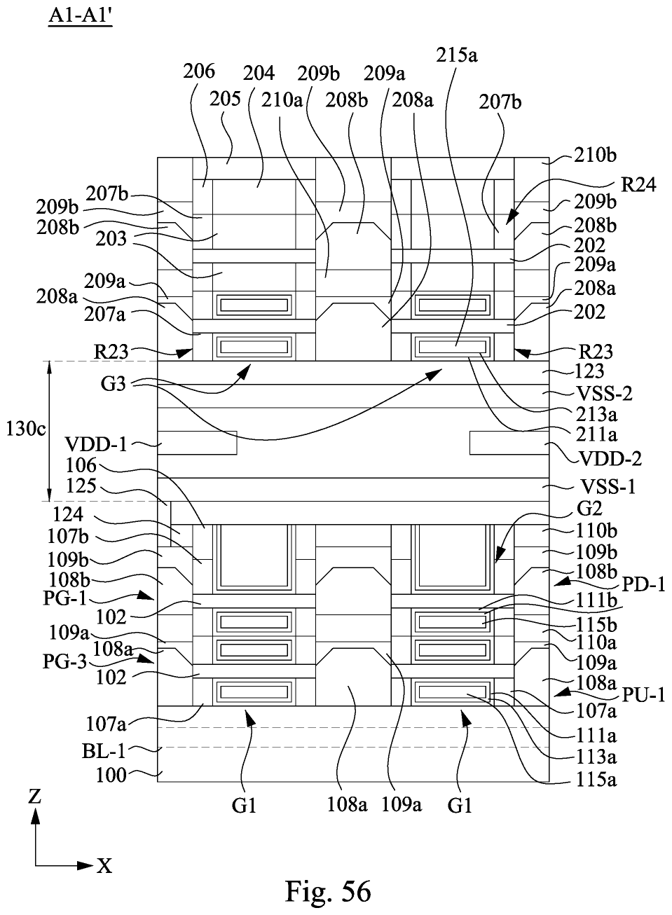

Reference is made to FIG. 56. After the formation of the gate structure G3, a planarization process (e.g., CMP) is performed to remove the excessive ILD layer 210b, the gate electrode layer 215a, the high-k dielectric layer 213a, and the interfacial layer 211a above the hard mask layer 205 until the hard mask layer 205 is exposed. In some embodiments, the hard mask layer 205 may also act as an etch stop layer for etching the ILD layer 210b.

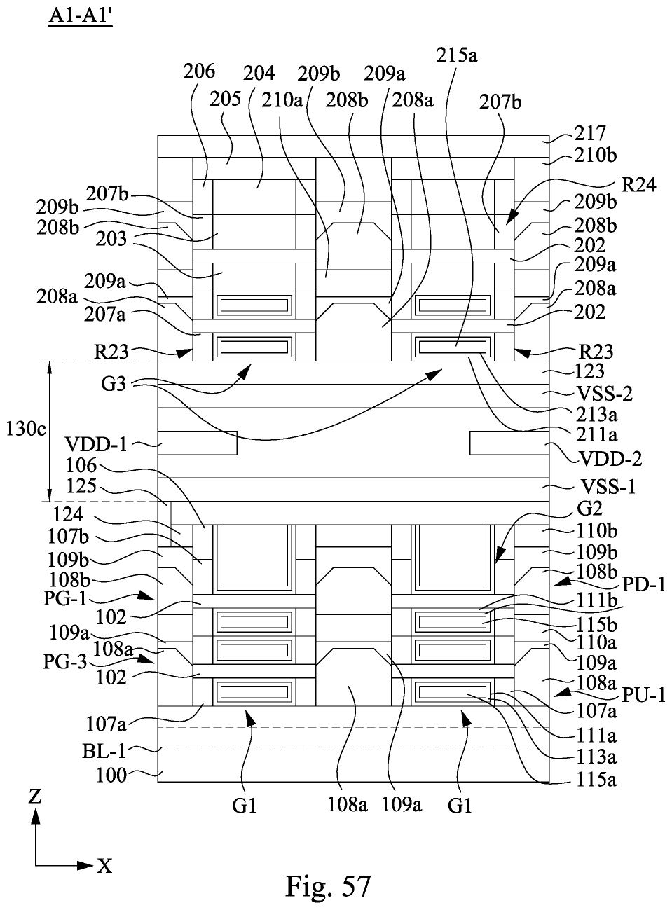

Reference is made to FIG. 57. A hard mask layer 217 may be formed over the ILD layer 210b and the hard mask layer 205. In some embodiments, the hard mask layer 217 may be made of the same material as the ILD layer 210b, thereby resulting in a substantially indistinguishable interface between the hard mask layer 217 and the ILD layer 210b. In some embodiments, the hard mask layer 217 may be made of a different material than the ILD layer 210b. In some embodiments, the hard mask layer 217 may be made of silicon oxide, silicon nitride, silicon oxynitride, silicon carbide, silicon oxycarbide (SiOC), tetraethoxysilane (TEOS), phosphosilicate glass (PSG), borophosphosilicate glass (BPSG), low-k dielectric material, other suitable material, or combinations thereof. Examples of low-k dielectric materials include, but are not limited to, fluorinated silica glass (FSG), carbon doped silicon oxide, amorphous fluorinated carbon, parylene, bis-benzocyclobutenes (BCB), or polyimide. In some embodiments, the formation of the hard mask layer 217 can be performed by using any suitable method, such as CVD, physical vapor deposition (PVD), ALD, PEALD, PECVD, SACVD, FCVD, spin-on, and/or the like, or a combination thereof.

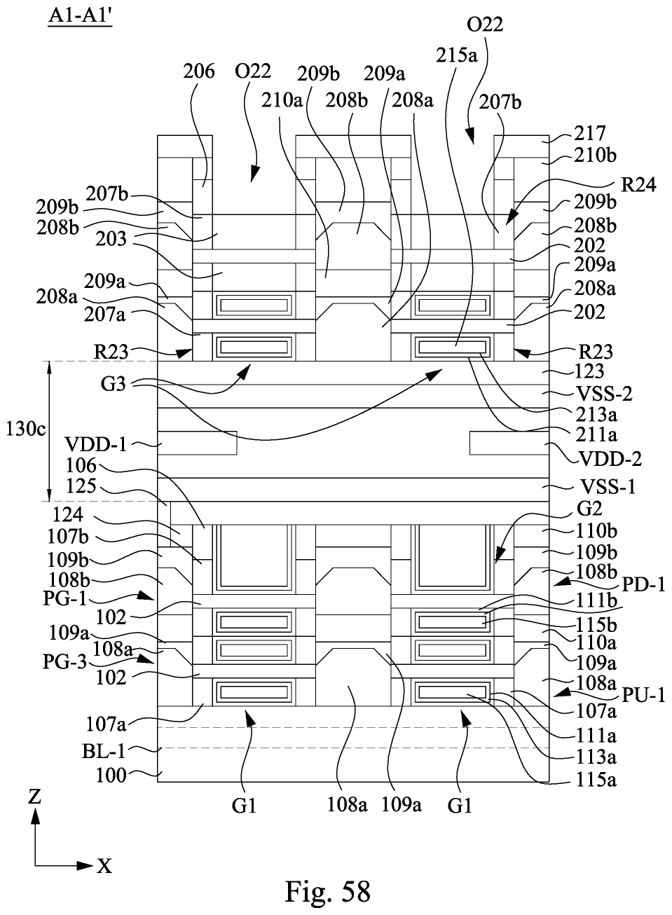

Reference is made to FIG. 58. The hard mask layer 217 may be patterned and then be used to etch the dummy gate layer 204, the hard mask layer 205, and the ILD layers 210a and 210b. The hard mask layer 217 may be patterned by a lithography process including include photoresist (or resist) coating (e.g., spin-on coating), soft baking, mask aligning, exposure, post-exposure baking, developing the photoresist, rinsing, drying (e.g., hard baking), other suitable processes, and/or combinations thereof. The etching process includes dry etching, wet etching, and/or other etching methods (e.g., reactive ion etching).

After the formation of the patterned hard mask layer 217, the dummy gate layer 204, the hard mask layer 205, and the ILD layers 210a and 210b can be etched through the patterned hard mask layer 217 to form an opening O22. The opening O22 can extend through the hard mask layer 217, the dummy gate layer 204, and the ILD layers 210a and 210b to expose a second sidewall of the epitaxial stack, such that the channel layer 202 and the sacrificial layers 201 and 203 can be exposed from the opening O22. The etching process may include dry etching, wet etching, and/or other etching methods (e.g., reactive ion etching).

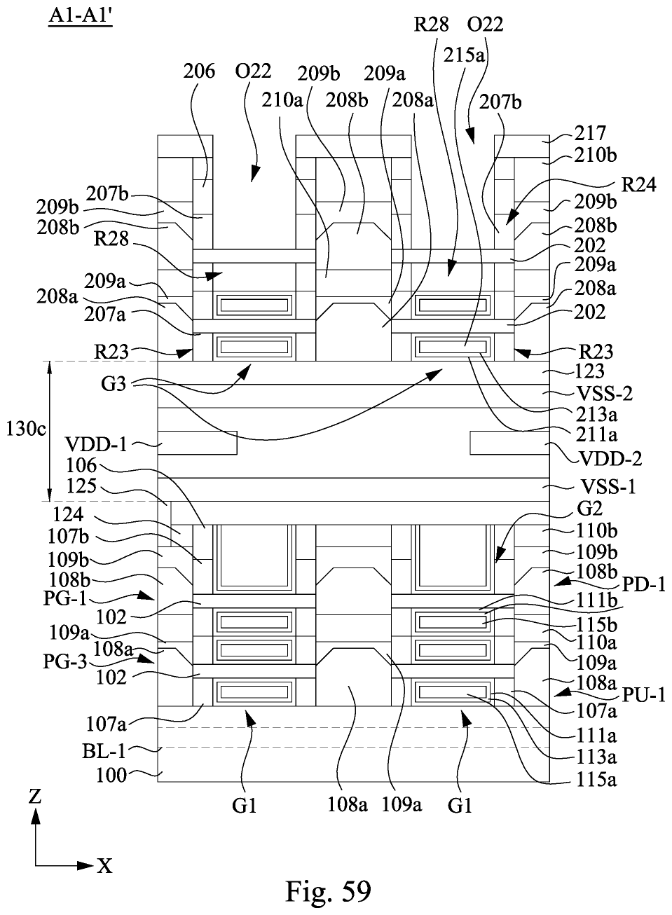

Reference is made to FIG. 59. The sacrificial layers 203 are removed in one or more etching process, so that a recess R28 can be formed to inherit the shape of a lower one of the sacrificial layers 203. The recess R28 can expose a bottom surface of the upper one of the channel layers 202, and the opening O22 can expose a top surface of the upper one of the channel layers 202. In some embodiments, the sacrificial layers 203 can be removed by an anisotropic dry etch process. For example, the etching process may include a dry etch process using reaction gas(es) that selectively etch the sacrificial layers 203 at faster rates than channel layer 202.

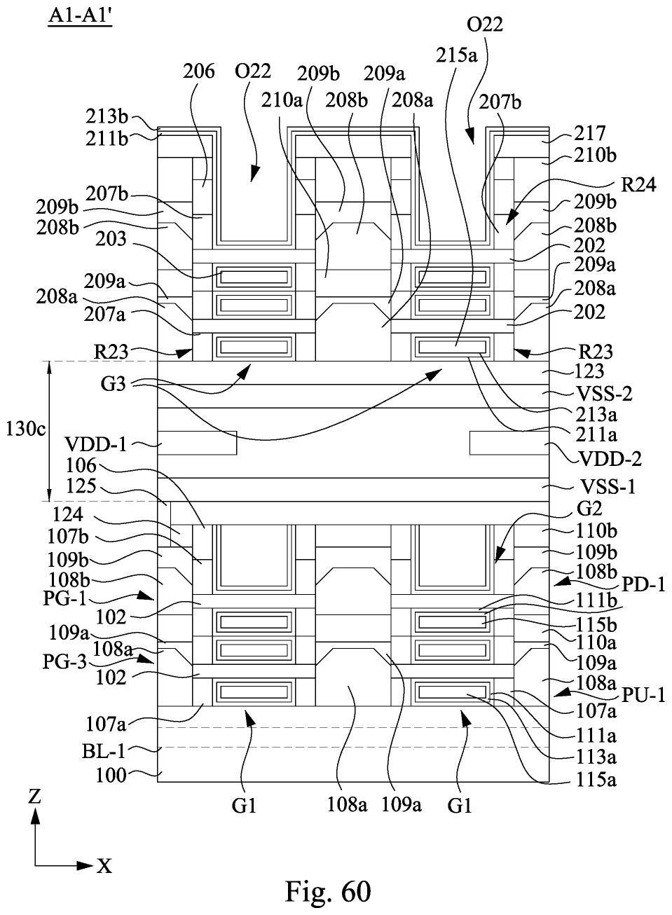

Reference is made to FIG. 60. An interfacial layer 211b and a high-k dielectric layer 213b can be conformally formed over the hard mask layer 217 and in the opening O22 and the recesses R28. In some embodiments, the interfacial layer of the gate dielectric layer 211b may include a dielectric material such as silicon oxide (SiO₂), HfSiO, or silicon oxynitride (SiON). In some embodiments, the interfacial layer 211a may be deposited using any suitable method, such as CVD, physical vapor deposition (PVD), ALD, PEALD, PECVD, SACVD, FCVD, spin-on, and/or the like, or a combination thereof.

In some embodiments, the high-k dielectric layer 213b may include high-k dielectric material, such as hafnium oxide (HfO₂). hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. In some embodiments, the high-k dielectric layer 213b may be deposited using any suitable method, such as CVD, physical vapor deposition (PVD), ALD, PEALD, PECVD, SACVD, FCVD, spin-on, and/or the like, or a combination thereof.

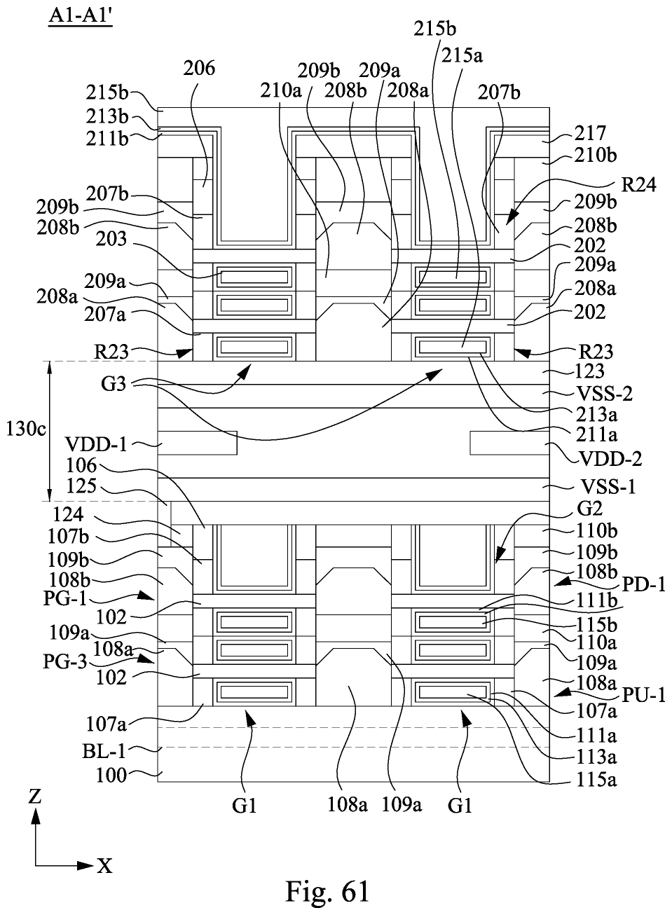

Reference is made to FIG. 61. A gate electrode layer 215b can be conformally formed over the high-k dielectric layer 213b. The gate electrode layer 215b may include a work function metal layer and/or a fill metal formed around the work function metal layer. The work function metal layer and/or the fill metal may include a metal, metal alloy, or metal silicide. For an n-type FinFET, the work function metal layer may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials. On the other hand, for a p-type FinFET, the work function metal layer may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal may exemplarily include, but are not limited to, tungsten, aluminum, copper, nickel, cobalt, titanium, tantalum, titanium nitride, tantalum nitride, nickel silicide, cobalt silicide, TaC. TaSiN, TaCN, TiAl, TiAlN, or other suitable materials. In some embodiments, the gate electrode layer 215b may be made of a different material than the gate electrode layer 215a.

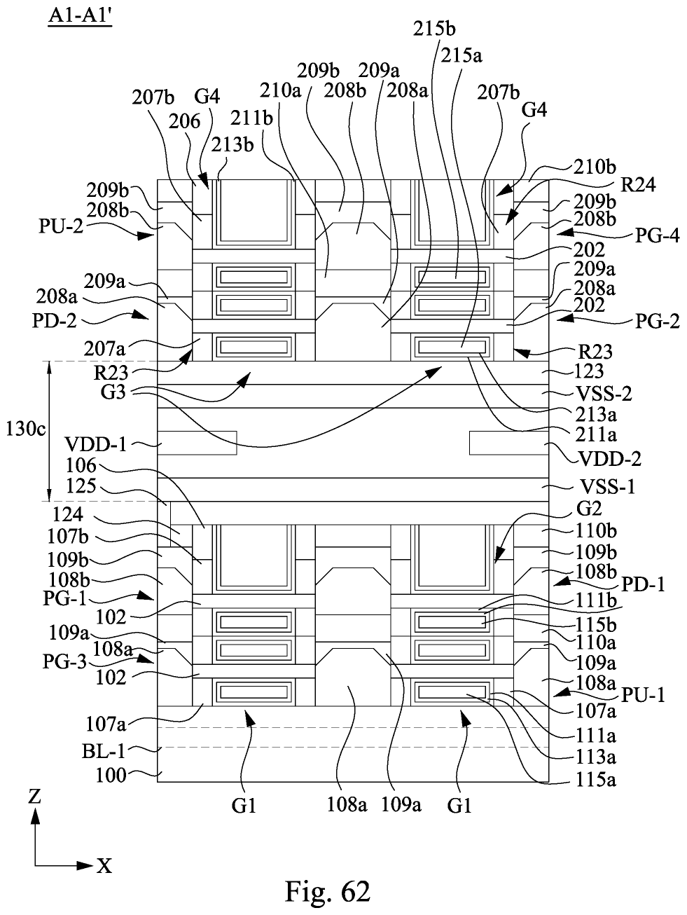

Reference is made to FIG. 62. A planarization process (e.g., CMP) is performed to remove the excessive gate electrode layer 215b, the high-k dielectric layer 213b, the interfacial layer 211b, the hard mask layers 205 and 217 above the gate spacers 206. The gate spacers 106 may also act as an etch stop layer for etching the gate electrode layer 215b, the high-k dielectric layer 213b, the interfacial layer 211b, the hard mask layers 205 and 217. Therefore, a (metal) gate structure G4 including the gate electrode layer 215b, the high-k dielectric layer 213b, and the interfacial layer 211b can be formed in the recesses R28 to surround each of the upper one of the channel layers 202 suspended in the recesses R28. In some embodiments, the gate structure G4 may be the final gate of a GAA FET.

Therefore, the semiconductor structure can include the transistors PG-2, PG-4. PU-2, and PD-2. The transistor PG-4 is over the transistor PG-2, and the transistor PU-2 is over the transistor PD-2. The transistors PG-2 and PU-2 each includes the channel layers 202, the source/drain regions 108a on opposite sides of the channel layer 202 and connected to the channel layer 202, and the gate structure G2 wrapping around the channel layer 202. The transistors PG-4 and PU-2 each includes the channel layers 202, the source/drain regions 208b on opposite sides of the channel layer 202 and connected to the channel layer 202, and the gate structure G4 wrapping around the channel layer 202. In some embodiments, the transistors PG-2, PG-4, PU-2, and PD-2 can be interchangeably referred to as top-tier transistors. In some embodiments, the transistors PG-2 and PD-2 may be n-type transistors, and the transistors PG-4 and PU-2 are p-type transistors. In some embodiments, the transistors PG-2 and PD-2 may be p-type transistors, and the transistors PG-4 and PU-2 are n-type transistors.

Reference is made to FIG. 63. An interconnect structure 222 can be formed over the transistors PG-2, PG-4, PU-2, and PD-2. The interconnect structure 222 may include an inter-metal dielectric 223 (see FIG. 63), the bit lines BL-1 and BL-2 (see FIGS. 2, 4I, and 4J), the word lines WL-11 and WL-21 (see FIGS. 2, 4I, and 4J), and the word lines WL-21 and WL-22 (see FIG. 63) in the inter-metal dielectric 223. The bit lines BL-1 and BL-2 and the word lines WL-11 and WL-21 as shown in FIGS. 2, 4I, and 4J can be formed over the transistors PG-4 and PU-2 at a same level height. The bit line BL-1 can be electrically connected to the underlying source/drain region 208b of the transistor PG-4. The bit line BL-2 can be electrically connected to the underlying source/drain region 208a of the transistor PG-2. The word line WL-11 can be electrically connected to the underlying the gate structures G3 and G1 of the transistors PG-2 and PG-1. The word line WL-21 can be electrically connected to the underlying gate structures G4 and G1 of the transistors PG-4 and PG-3. The word lines WL-21 and WL-22 (see FIG. 63) are formed over the bit lines BL-1 and BL-2 and the word lines WL-11 and WL-21 (see FIGS. 2, 4I, and 4J). The word line WL-21 can be electrically connected to the underlying word line WL-11 (FIG. 4I), and the word line WL-22 can be electrically connected to the underlying word line WL-12 (FIG. 4I).

In some embodiments, the inter-metal dielectric 223 may include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the bit lines BL-1 and BL-2 and the word lines WL-11, WL-21, WL-21, and WL-22 can be made of tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a 4-layer structure for the dual port SRAM bitcell, which incorporates a total of 8 transistors. This approach enables us to achieve the same functionality with a significantly reduced footprint, requiring only 2 transistors. By employing a sequential process or a monolithic process, we stack the transistors in a specific configuration, such as placing pull-down transistor on top of pull-up transistor. To address the routing challenges, we introduce an inter-metal dielectric layer (e.g. middle end of line, MEOL) above the bottom-tier transistors in the dual port SRAM bitcell. This MEOL layer provides a platform for the placement of power lines and cross coupling lines between the bottom-tier transistors and the top tier transistors. Moreover, buried metal lines, including the complementary bit lines, are formed beneath the bottom-tier transistors to mitigate routing congestion. Hence, by reducing the footprint of the dual port SRAM bitcell from 12 transistors to only 2 transistors, we greatly enhance space efficiency and enable more compact designs. This reduction in footprint allows for higher device density, potentially leading to lower production costs. In addition, the introduction of the inter-metal dielectric layer and buried metal lines effectively addresses routing congestion, thereby improving the overall performance and efficiency of the SRAM bitcell.

In some embodiments, a method includes forming a first pull-up transistor and a first pass-gate transistor over a substrate at a first level height, the first pull-up and first pass-gate transistors being of a dual port static random access memory (SRAM) cell; forming a first pull-down transistor and a second pass-gate transistor of the dual port SRAM cell over the substrate at a second level height; forming a second pull-down transistor and a third pass-gate transistor of the dual port SRAM cell over the substrate at a third level height; forming a second pull-up transistor and a fourth pass-gate transistor of the dual port SRAM cell over the substrate at a fourth level height. In some embodiments, the second pass-gate transistor overlaps with the first pass-gate transistor, and the second pull-down transistor overlaps with the second pass-gate transistor. In some embodiments, the second pull-down transistor overlaps with the second pull-down transistor. In some embodiments, the method further includes forming a cross coupling line of the dual port SRAM cell, the cross coupling line laterally extending at a fifth level height higher than the second level height, and lower than the third level height. In some embodiments, the method further includes forming a voltage source line of the dual port SRAM cell, the voltage source line laterally extending at a fifth level height higher than the second level height, and lower than the third level height. In some embodiments, the method further includes forming a first ground line of the dual port SRAM cell, the first ground line laterally extending between the voltage source line and the first pull-down and the second pass-gate transistors. In some embodiments, the method further includes forming a second ground line of the dual port SRAM cell, the second ground line laterally extending between the voltage source line and the second pull-down and third pass-gate transistors. In some embodiments, the method further includes forming a complementary bit line of the dual port SRAM cell, the complementary bit line laterally extending between the substrate and the first pull-up and first pass-gate transistors. In some embodiments, the first and second pull-up transistors, the first and second pull-down transistors, and the first, second, third, and fourth pass-gate transistors are formed in a sequential manner over the substrate at the respective first, second, third, and fourth level heights. In some embodiments, at least one of the first and second pull-up transistors, the first and second pull-down transistors, and the first, second, third, and fourth pass-gate transistors of different level heights is formed separately and then combined through bonding to form the dual port SRAM cell.

In some embodiments, a method includes forming a first semiconductive nanostructure, and a second semiconductive nanostructure vertically arranged with respect to the first semiconductive nanostructure; forming a plurality of first epitaxial structures on opposite sides of the first semiconductive nanostructure, and a plurality of second epitaxial structures on opposite sides of the second semiconductive nanostructure; forming a first gate wrapping around the first semiconductive nanostructure, and a second gate wrapping around the second semiconductive nanostructure; forming a first power line laterally extending over the first and second gates; forming third and fourth semiconductive nanostructures over the first power line, the third semiconductive nanostructure vertically arranged with respect to the second semiconductive nanostructure, and a fourth semiconductive nanostructure vertically arranged with respect to the third semiconductive nanostructure; forming a plurality of third epitaxial structures on opposite sides of the third semiconductive nanostructure, and a plurality of fourth epitaxial structures on opposite sides of the fourth semiconductive nanostructure; forming a third gate wrapping around the third semiconductive nanostructure, and a fourth gate wrapping around the fourth semiconductive nanostructure. In some embodiments, the method further includes forming a cross coupling line of a static random access memory cell over the first and second gates and at a same level height as the first power line. In some embodiments, the method further includes before forming the third and fourth semiconductive nanostructures, forming a second power line laterally extending over the first and second gates. In some embodiments, the second power line is at a different level height than the first power line and extends in a direction perpendicular to a lengthwise direction of first power line. In some embodiments, the second power line is at a different level height than the first power line and extends in a direction in parallel with a lengthwise direction of first power line.

In some embodiments, the semiconductor structure includes first and second transistors over a substrate, third and fourth transistors of the SRAM cell over the first and second transistors, fifth and sixth transistors of the SRAM cell over the third and fourth transistors, and seventh and eighth transistors of the SRAM cell over the fifth and sixth transistors. The first and second transistors are of a static random access memory (SRAM) cell, and of a first conductivity type. The third and fourth transistors are of a second conductivity type opposite to the first conductivity type. The fifth and sixth transistors are of the second conductivity type. The seventh and eighth transistors are of the first conductivity type. In some embodiments, the semiconductor structure further includes a voltage source line of the SRAM cell, the voltage source line laterally extending in a level height higher than a level height of the third transistor and lower than a level height of the fifth transistor. In some embodiments, the semiconductor structure further includes a ground line of the SRAM cell, the ground line laterally extending in a level height higher than a level height of the third transistor and lower than a level height of the fifth transistor. In some embodiments, the semiconductor structure further includes a cross coupling line of the dual port SRAM cell, the cross coupling line laterally extending in the same level height as the ground line. In some embodiments, the semiconductor structure further includes a complementary bit line of the SRAM cell, the complementary bit line laterally extending in a level height below a level height of the first transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first pull-up transistor and a first pass-gate transistor over a substrate at a first level height, the first pull-up and first pass-gate transistors being of a dual port static random access memory (SRAM) cell;
forming a first pull-down transistor and a second pass-gate transistor of the dual port SRAM cell over the substrate at a second level height;
forming a second pull-down transistor and a third pass-gate transistor of the dual port SRAM cell over the substrate at a third level height; and
forming a second pull-up transistor and a fourth pass-gate transistor of the dual port SRAM cell over the substrate at a fourth level height.

2. The method of claim 1, wherein the second pass-gate transistor overlaps with the first pass-gate transistor, and the second pull-down transistor overlaps with the second pass-gate transistor.

3. The method of claim 2, wherein the second pull-down transistor overlaps with the second pull-down transistor.

4. The method of claim 1, further comprising:
forming a cross coupling line of the dual port SRAM cell, the cross coupling line laterally extending at a fifth level height higher than the second level height, and lower than the third level height.

5. The method of claim 1, further comprising:
forming a voltage source line of the dual port SRAM cell, the voltage source line laterally extending at a fifth level height higher than the second level height, and lower than the third level height.

6. The method of claim 5, further comprising:
forming a first ground line of the dual port SRAM cell, the first ground line laterally extending between the voltage source line and the first pull-down and the second pass-gate transistors.

7. The method of claim 6, further comprising:
forming a second ground line of the dual port SRAM cell, the second ground line laterally extending between the voltage source line and the second pull-down and third pass-gate transistors.

8. The method of claim 1, further comprising:
forming a complementary bit line of the dual port SRAM cell, the complementary bit line laterally extending between the substrate and the first pull-up and first pass-gate transistors.

9. The method of claim 1, wherein the first and second pull-up transistors, the first and second pull-down transistors, and the first, second, third, and fourth pass-gate transistors are formed in a sequential manner over the substrate at the respective first, second, third, and fourth level heights.

10. The method of claim 1, wherein at least one of the first and second pull-up transistors, the first and second pull-down transistors, and the first, second, third, and fourth pass-gate transistors of different level heights is formed separately and then combined through bonding to form the dual port SRAM cell.

11. A method, comprising:
forming a first semiconductive nanostructure, and a second semiconductive nanostructure vertically arranged with respect to the first semiconductive nanostructure;
forming a plurality of first epitaxial structures on opposite sides of the first semiconductive nanostructure, and a plurality of second epitaxial structures on opposite sides of the second semiconductive nanostructure;
forming a first gate wrapping around the first semiconductive nanostructure, and a second gate wrapping around the second semiconductive nanostructure;
forming a first power line laterally extending over the first and second gates;
forming third and fourth semiconductive nanostructures over the first power line, the third semiconductive nanostructure vertically arranged with respect to the second semiconductive nanostructure, and a fourth semiconductive nanostructure vertically arranged with respect to the third semiconductive nanostructure;
forming a plurality of third epitaxial structures on opposite sides of the third semiconductive nanostructure, and a plurality of fourth epitaxial structures on opposite sides of the fourth semiconductive nanostructure; and
forming a third gate wrapping around the third semiconductive nanostructure, and a fourth gate wrapping around the fourth semiconductive nanostructure.

12. The method of claim 11, further comprising:
forming a cross coupling line of a static random access memory cell over the first and second gates and at a same level height as the first power line.

13. The method of claim 11, further comprising:
before forming the third and fourth semiconductive nanostructures, forming a second power line laterally extending over the first and second gates.

14. The method of claim 13, wherein the second power line is at a different level height than the first power line and extends in a direction perpendicular to a lengthwise direction of first power line.

15. The method of claim 13, wherein the second power line is at a different level height than the first power line and extends in a direction in parallel with a lengthwise direction of first power line.

16. A semiconductor structure, comprising:
first and second transistors over a substrate, the first and second transistors being of a static random access memory (SRAM) cell, and the first and second transistors being of a first conductivity type;
third and fourth transistors of the SRAM cell over the first and second transistors, the third and fourth transistors being of a second conductivity type opposite to the first conductivity type;
fifth and sixth transistors of the SRAM cell over the third and fourth transistors, the fifth and sixth transistors being of the second conductivity type; and
seventh and eighth transistors of the SRAM cell over the fifth and sixth transistors, the seventh and eighth transistors being of the first conductivity type.

17. The semiconductor structure of claim 16, further comprising:
a voltage source line of the SRAM cell, the voltage source line laterally extending in a level height higher than a level height of the third transistor and lower than a level height of the fifth transistor.

18. The semiconductor structure of claim 16, further comprising:
a ground line of the SRAM cell, the ground line laterally extending in a level height higher than a level height of the third transistor and lower than a level height of the fifth transistor.

19. The semiconductor structure of claim 18, further comprising:
a cross coupling line of the dual port SRAM cell, the cross coupling line laterally extending in the same level height as the ground line.

20. The semiconductor structure of claim 16, further comprising:
a complementary bit line of the SRAM cell, the complementary bit line laterally extending in a level height below a level height of the first transistor.
